(19) United States
(12) Patent Application Publication
(10) Pub. No.: US 2024/0107789 A1
(43) Pub. Date: Mar. 28, 2024

(54) LIGHT EMITTING ELEMENT

(71) Applicant: Samsung Display Co., Ltd., Yongin-si (KR)

(72) Inventors: SANGHEE YU, Yongin-si (KR); GYEONGHEON KIM, Yongin-si (KR); HOI-LIM KIM, Yongin-si (KR); Dongsun YOO, Yongin-si (KR); GYUBONG KIM, Yongin-si (KR); YONGSUB SHIM, Yongin-si (KR)

(21) Appl. No.: 18/342,510

(22) Filed: Jun. 27, 2023

(30) Foreign Application Priority Data
Aug. 19, 2022 (KR) 10-2022-0104324

(51) Int. Cl. H10K 50/11; C09K 11/06; H10K 85/30; H10K 85/60

(52) U.S. Cl. CPC H10K 50/11; C09K 11/06; H10K 85/346; H10K 85/6574; H10K 85/6576; C09K 2211/1092; H10K 2102/351

(57) ABSTRACT

A light emitting element may include: a first electrode; a second electrode facing the first electrode; at least one functional layer disposed between the first electrode and the second electrode; and a capping layer disposed on the second electrode and including a fused compound represented by Formula 1 below. The capping layer possesses high refractive characteristics.

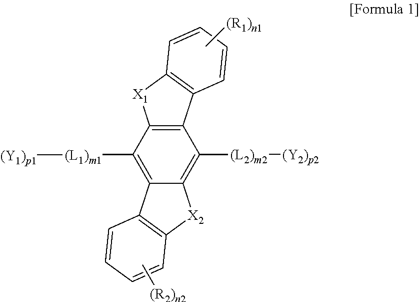

### CROSS-REFERENCE TO RELATED APPLICATIONS

This application claims priority to and the benefit of Korean Patent Application No. 10-2022-0104324, filed on Aug. 19, 2022, in the Korean Intellectual Property Office, the entire content of which is hereby incorporated by reference.

### BACKGROUND

### 1. Field

One or more embodiments of the present disclosure relate to a light emitting element, and for example, to a light emitting element including a high-refractive capping layer.

### 2. Description of the Related Art

As image display devices, organic electroluminescence display devices and/or the like have lately been actively developed and investigated. The organic electroluminescence display devices and/or the like are display devices including so-called self-luminescent light emitting elements in which holes and electrons injected from a first electrode and a second electrode recombine in an emission layer, and thus a luminescent material in the emission layer emits light to accomplish display (e.g., of an image).

For application of light emitting elements to display devices, there is a demand for light emitting elements having a low driving voltage, high luminous efficiency, and a long life, and development of suitable materials, for light emitting elements, capable of stably attaining such characteristics is being continuously required and/or desired.

Specifically, a capping layer may be applied to light emitting elements to increase light extraction efficiency and protect base materials. High-refractive capping layers for increasing light extraction efficiency of light generated from an emission layer are under development and research to obtain highly efficient light emitting elements.

### SUMMARY

One or more aspects of embodiments of the present disclosure are directed toward a highly efficient light emitting element by applying a high-refractive capping layer.

Additional aspects will be set forth in part in the description which follows and, in part, will be apparent from the description, or may be learned by practice of the presented embodiments.

One or more embodiments of the present disclosure provide a light emitting element including: a first electrode; a second electrode facing the first electrode; at least one functional layer between the first electrode and the second electrode; and a capping layer on the second electrode and including a fused compound represented by Formula 1:

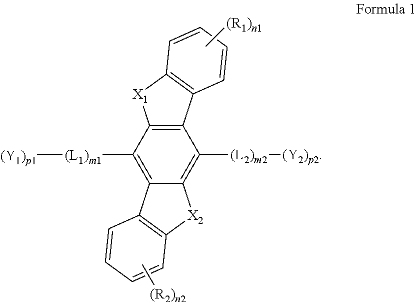

In Formula 1, X₁ and X₂ may each independently be S or O, R₁ and R₂ may each independently be hydrogen or deuterium, n1 and n2 may each independently be an integer of 0 to 4, L₁ and L₂ may each independently be a direct linkage or N, m1 and m2 may each independently be 0 or 1, Y₁ and Y₂ may each independently be a substituted or unsubstituted aryl group having 6 to 20 ring-forming carbon atoms, or a substituted or unsubstituted heteroaryl group having 2 to 20 ring-forming carbon atoms, and p1 and p2 may each independently be 1 or 2.

In one or more embodiments, the fused compound represented by Formula 1 may be represented by any one selected from among Formulas 1-1a to 1-1c:

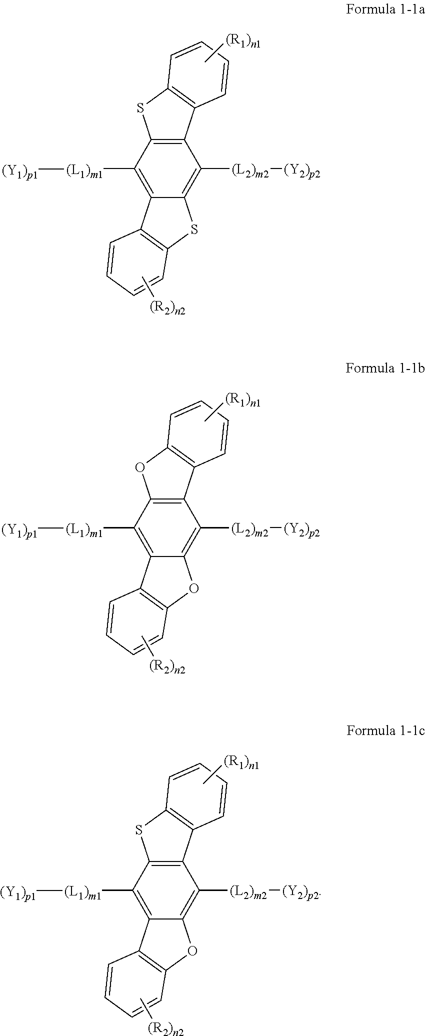

In Formulas 1-1a to 1-1c, R₁, R₂, n1, n2, L₁, L₂, m1, m2, Y₁, Y₂, p1, and p2 may each be the same as defined in Formula 1.

In one or more embodiments, the fused compound represented by Formula 1 may be represented by Formula 1-2a or Formula 1-2b:

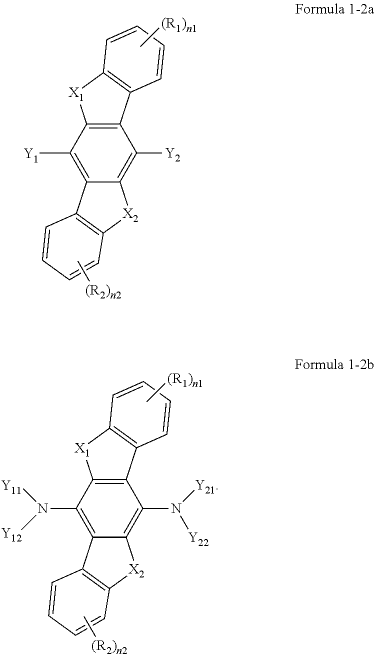

In Formulas 1-2a and 1-2b, Y₁₁, Y₁₂, Y₂₁, and Y₂₂ may each independently be a substituted or unsubstituted aryl group having 6 to 20 ring-forming carbon atoms, or a substituted or unsubstituted heteroaryl group having 2 to 20 ring-forming carbon atoms, and X₁, X₂, R₁, R₂, n1, n2, Y₁, and Y₂ may each be the same as defined in Formula 1.

In one or more embodiments, Y₁ and Y₂ may each independently be a substituted or unsubstituted bicyclic or tricyclic aryl group, or a substituted or unsubstituted bicyclic or tricyclic heteroaryl group.

In one or more embodiments, Y₁ and Y₂ may each independently be represented by any one selected from among Formulas 2-1 to 2-4:

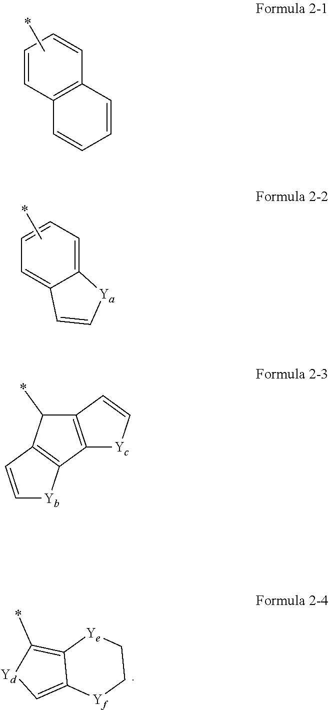

In Formulas 2-1 to 2-4, Yₐ to Y_{f} may each independently be S or O, and “ [symbol] ” may be a site connected to Formula 1 above.

In one or more embodiments, R₁ and R₂ may each be hydrogen.

In one or more embodiments, the fused compound represented by Formula 1 may have a monomolecular refractive index of about 1.7 to about 2.5 with respect to light having a wavelength of about 490 nm to about 570 nm.

In one or more embodiments, the capping layer may have a density of about 1.0 g/cm³ to about 1.3 g/cm³.

In one or more embodiments, the capping layer may have a thickness of about 100 Å to about 1000 Å.

In one or more embodiments, the at least one functional layer may include an emission layer, a hole transport region between the first electrode and the emission layer, and an electron transport region between the emission layer and the second electrode, and the emission layer may include a compound represented by Formula AD:

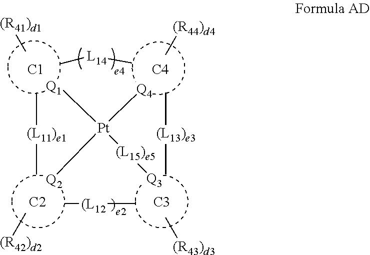

In Formula AD, Q₁ to Q₄ may each independently be C or N, C1 to C4 may each independently be a substituted or unsubstituted aromatic hydrocarbon ring having 5 to 30 ring-forming carbon atoms, or a substituted or unsubstituted aromatic heterocycle having 2 to 30 ring-forming carbon atoms, L₁₁ to L₁₄ may each independently be a direct linkage,

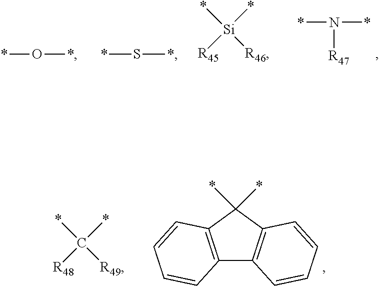

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “ [symbol] ” may be a site connected to C1 to C4, L₁₅ may be a direct linkage or *—O—*, and in L₁₅, “ [symbol] ” may be a site connected to Pt and C3, e1 to e5 may each independently be 0 or 1, R₄₁ to R₄₉ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and d1 to d4 may each independently be an integer of 0 to 4.

In one or more embodiments of the present disclosure, a light emitting element may include: a first electrode; a second electrode facing the first electrode; at least one functional layer between the first electrode and the second electrode; and a capping layer on the second electrode and including a fused compound represented by Formula 3:

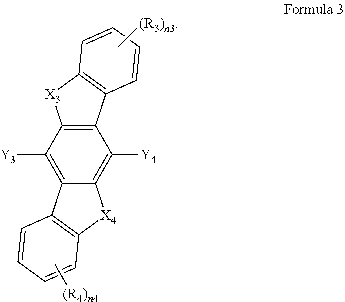

In Formula 3, X₃ and X₄ may each independently be S or O, R₃ and R₄ may each independently be hydrogen or deuterium, n3 and n4 may each independently be an integer of 0 to 4, Y₃ and Y₄ may each independently be *—NR₅R₆, a substituted or unsubstituted aryl group having 6 to 20 ring-forming carbon atoms, or a substituted or unsubstituted heteroaryl group having 2 to 20 ring-forming carbon atoms, and R₅ and R₆ may each independently be a substituted or unsubstituted aryl group having 6 to 20 ring-forming carbon atoms, or a substituted or unsubstituted heteroaryl group having 2 to 20 ring-forming carbon atoms.

In one or more embodiments of the present disclosure, a light emitting element may include: a first electrode; a second electrode facing the first electrode; at least one functional layer between the first electrode and the second electrode; and a capping layer on the second electrode and including a fused compound represented by Formula 3, wherein the at least one functional layer may include an emission layer, a hole transport region between the first electrode and the emission layer, and an electron transport region between the emission layer and the second electrode, and the emission layer may include a compound represented by Formula AD:

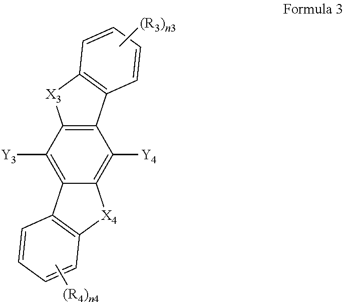

In Formula 3, X₃ and X₄ may each independently be S or O, R₃ and R₄ may each independently be hydrogen or deuterium, n3 and n4 may each independently be an integer of 0 to 4, Y₃ and Y₄ may each independently be *—NR₅R₆, a substituted or unsubstituted aryl group having 6 to 20 ring-forming carbon atoms, or a substituted or unsubstituted heteroaryl group having 2 to 20 ring-forming carbon atoms, and R₅ and R₆ may each independently be a substituted or unsubstituted aryl group having 6 to 20 ring-forming carbon atoms, or a substituted or unsubstituted heteroaryl group having 2 to 20 ring-forming carbon atoms.

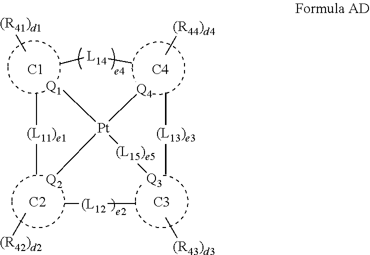

In Formula AD, Q₁ to Q₄ may each independently be C or N, C1 to C4 may each independently be a substituted or unsubstituted aromatic hydrocarbon ring having 5 to 30 ring-forming carbon atoms, or a substituted or unsubstituted aromatic heterocycle having 2 to 30 ring-forming carbon atoms, L₁₁ to L₁₄ may each independently be a direct linkage,

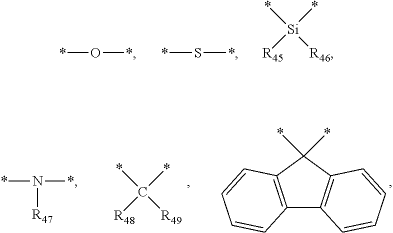

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “ [symbol] ” is a site connected to C1 to C4, L₁₅ is a direct linkage or *—O—*, and in L₁₅, “ [symbol] ” is a site connected to Pt and C3, e1 to e5 may each independently be 0 or 1, R₄₁ to R₄₉ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and d1 to d4 may each independently be an integer of 0 to 4.

### BRIEF DESCRIPTION OF THE DRAWINGS

The accompanying drawings are included to provide a further understanding of the present disclosure, and are incorporated in and constitute a part of this specification. The drawings illustrate embodiments of the present disclosure and, together with the description, serve to explain principles of the present disclosure. Above and/or other aspects of the present disclosure should become apparent and appreciated from the following description of embodiments taken in conjunction with the accompanying drawings. In the drawings:

FIG. 1 is a plan view of a display device according to one or more embodiments of the present disclosure;

FIG. 2 is a cross-sectional view of a display device according to one or more embodiments of the present disclosure;

FIG. 3 is a cross-sectional view schematically showing a light emitting element according to one or more embodiments of the present disclosure;

FIG. 4 is a cross-sectional view schematically showing a light emitting element according to one or more embodiments of the present disclosure;

FIG. 5 is a cross-sectional view schematically showing a light emitting element according to one or more embodiments of the present disclosure;

FIG. 6 is a cross-sectional view of a display device according to one or more embodiments of the present disclosure;

FIG. 7 is a cross-sectional view of a display device according to one or more embodiments of the present disclosure;

FIG. 8 is a cross-sectional view of a display device according to one or more embodiments of the present disclosure; and

FIG. 9 is a cross-sectional view of a display device according to one or more embodiments of the present disclosure.

### DETAILED DESCRIPTION

The present disclosure may be modified in many alternate forms, and thus specific embodiments will be exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In describing the drawings, like reference numerals are utilized for like elements. In the drawings, the sizes of elements may be exaggerated for clarity. It will be understood that, although the terms “first,” “second,” etc. may be utilized herein to describe one or more suitable elements, these elements should not be limited by these terms. These terms are only utilized to distinguish one element from another element. For example, a first element may be referred to as a second element, and similarly, a second element may be referred to as a first element without departing from the teachings of the present disclosure. The singular forms are intended to include the plural forms as well, unless the context clearly indicates otherwise.

In the present disclosure, it should be understood that the terms “comprise(s)/include(s)”, or “have/has” are intended to specify the presence of stated features, integers, steps, operations, elements, components, or combinations thereof in the disclosure, but do not preclude the presence or addition of one or more other features, integers, steps, operations, elements, components, or combinations thereof. As used herein, the terms “and”, “or”, and “and/or” may include any and all combinations of one or more of the associated listed items. Expressions such as “at least one of,” “one of,” and “selected from,” when preceding a list of elements, modify the entire list of elements and do not modify the individual elements of the list. For example, “at least one of a, b or c”, “at least one selected from a, b, and c”, “at least one selected from among a to c”, etc., may indicate only a, only b, only c, both (e.g., simultaneously) a and b, both (e.g., simultaneously) a and c, both (e.g., simultaneously) b and c, all of a, b, and c, or variations thereof. The “/” utilized below may be interpreted as “and” or as “or” depending on the situation.

In the present disclosure, it should be understood that when an element such as a layer, a film, a region, or a substrate is referred to as being “on” or “above” another element, it may be “directly on” the other element or intervening elements may also be present. In contrast, it should be understood that when an element such as a layer, a film, a region, or a substrate is referred to as being “beneath” or “under” another element, it may be “directly under” the other element or intervening elements may also be present. In some embodiments, in the present description, it should be understood that when an element is referred to as being “on”, it may be as being “above” or “under” the other element.

In the present disclosure, the term “substituted or unsubstituted” may indicate that one is substituted or unsubstituted with at least one substituent selected from the group consisting of deuterium, a halogen, a cyano group, a nitro group, an amino group, a silyl group, oxy group, thio group, sulfinyl group, sulfonyl group, carbonyl group, a boron group, a phosphine oxide group, a phosphine sulfide group, an alkyl group, an alkenyl group, an alkynyl group, a hydrocarbon ring group, an aryl group, and a heterocyclic group. In some embodiments, each of the substituents exemplified above may be substituted or unsubstituted. For example, a biphenyl group may be interpreted as an aryl group or as a phenyl group substituted with a phenyl group.

In the present disclosure, the term “bonded to an adjacent group to form a ring” may indicate that one is bonded to an adjacent group to form a substituted or unsubstituted hydrocarbon ring, or a substituted or unsubstituted heterocycle. The hydrocarbon ring may include an aliphatic hydrocarbon ring and an aromatic hydrocarbon ring. The heterocycle may include an aliphatic heterocycle and an aromatic heterocycle. The hydrocarbon ring and the heterocycle may be monocyclic or polycyclic. In some embodiments, the rings formed by being linked to each other may be connected to another ring to form a spiro structure.

In the present disclosure, the term “an adjacent group” may refer to a substituent substituted for an atom which is directly connected to an atom substituted with a corresponding substituent, another substituent substituted for an atom which is substituted with a corresponding substituent, or a substituent sterically positioned at the nearest position to a corresponding substituent. For example, two methyl groups in 1,2-dimethylbenzene may be interpreted as mutually “adjacent groups” and two ethyl groups in 1,1-diethylcyclopentane may be interpreted as mutually “adjacent groups”. In some embodiments, two methyl groups in 4,5-dimethylphenanthrene may be interpreted as mutually “adjacent groups”.

In the present disclosure, examples of a halogen may include fluorine, chlorine, bromine, and iodine.

In the present disclosure, an alkyl group may be a linear, branched, or cyclic type or kind. The number of carbon atoms in the alkyl group may be 1 to 50, 1 to 30, 1 to 20, 1 to 10, or 1 to 6. Examples of the alkyl group may include a methyl group, an ethyl group, an n-propyl group, an isopropyl group, an n-butyl group, a s-butyl group, a t-butyl group, an i-butyl group, a 2-ethylbutyl group, a 3,3-a dimethylbutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, an n-decyl group, an adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, etc., but embodiments of the present disclosure are not limited thereto.

In the present disclosure, an alkenyl group may refer to a hydrocarbon group including at least one carbon-carbon double bond in the middle or end of an alkyl group having 2 or more carbon atoms. The alkenyl group may be linear or branched. The number of carbon atoms of the alkenyl group is not particularly limited, but may be 2 to 30, 2 to 20, or 2 to 10. Examples of the alkenyl group may include a vinyl group, a 1-butenyl group, a 1-pentenyl group, a 1,3-butadienyl aryl group, a styrenyl group, a styryl vinyl group, etc., but embodiments of the present disclosure are not limited thereto.

In the present disclosure, an alkynyl group may refer to a hydrocarbon group including at least one carbon-carbon triple bond in the middle or end of an alkyl group having 2 or more carbon atoms. The alkynyl group may be linear or branched. The number of carbon atoms of the alkynyl group is not particularly limited, but may be 2 to 30, 2 to 20, or 2 to 10. Examples of the alkynyl group may include an ethynyl group, a propynyl group, etc., but embodiments of the present disclosure are not limited thereto.

In the present disclosure, a hydrocarbon ring group may refer to any functional group or substituent derived from an aliphatic hydrocarbon ring. The hydrocarbon ring group may be a saturated hydrocarbon ring group having 5 to 20 ring-forming carbon atoms.

In the present disclosure, an aryl group may refer to any functional group or substituent derived from an aromatic hydrocarbon ring. The aryl group may be a monocyclic aryl group or a polycyclic aryl group. The number of ring-forming carbon atoms in the aryl group may be 6 to 60, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but embodiments of the present disclosure are not limited thereto.

In the present disclosure, a fluorenyl group may be substituted, and two substituents may be bonded to each other to form a spiro structure. Examples that the fluorenyl group is substituted may be as follows. However, embodiments of the present disclosure are not limited thereto.

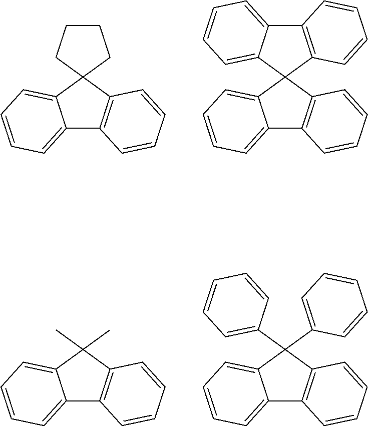

In the present disclosure, a heterocyclic group may refer to any functional group or substituent derived from a ring including (e.g., containing) at least one of B, 0, N, P, Si, or S, as a hetero atom. The heterocyclic group may include an aliphatic heterocyclic group and/or an aromatic heterocyclic group. The aromatic heterocyclic group may be a heteroaryl group. The aliphatic heterocycle and the aromatic heterocycle may be monocyclic or polycyclic. When the heterocyclic group includes (e.g., contains) two or more hetero atoms, the two or more hetero atoms may be the same as or different from each other.

In the present disclosure, the aliphatic heterocyclic group may include (e.g., contain) at least one of B, O, N, P, Si, or S, as a hetero atom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but embodiments of the present disclosure are not limited to thereto

In the present disclosure, a heteroaryl group may include at least one of B, O, N, P, Si, or S, as a hetero atom. When the heteroaryl group includes (e.g., contains) two or more hetero atoms, the two or more hetero atoms may be the same as or different from each other. The heteroaryl group may be a monocyclic heterocyclic group or a polycyclic heterocyclic group. The number of ring-forming carbon atoms in the heteroaryl group may be 2 to 60, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but embodiments of the present disclosure are not limited thereto.

In the present disclosure, the above description of the aryl group may be applied to an arylene group, except that the arylene group is a divalent group. The above description of the heteroaryl group may be applied to a heteroarylene group, except that the heteroarylene group is a divalent group.

In the present disclosure, a silyl group may include an alkyl silyl group and an aryl silyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but embodiments of the present disclosure are not limited thereto.

In the present disclosure, the number of carbon atoms in an amino group is not particularly limited, but may be 1 to 30. The amino group may include an alkyl amino group, an aryl amino group, or a heteroaryl amino group. Examples of the amino group may include a methylamino group, a dimethylamino group, a phenylamino group, a diphenylamino group, a naphthylamino group, a 9-methyl-anthracenylamino group, a triphenylamino group, etc., but embodiments of the present disclosure are not limited thereto.

In the present disclosure, the number of carbon atoms in a carbonyl group is not particularly limited, but may be 1 to 40, 1 to 30, or 1 to 20. For example, the carbonyl group may have the following structure, but embodiments of the present disclosure are not limited thereto.

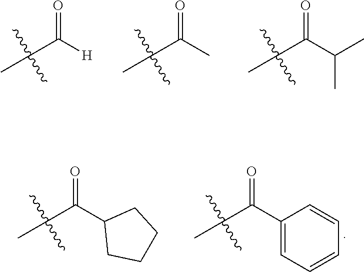

In the present disclosure, the number of carbon atoms in a sulfinyl group or a sulfonyl group is not particularly limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the present disclosure, a thio group may include an alkyl thio group and/or an aryl thio group. The thio group may indicate the one that a sulfur atom is bonded to an alkyl group or an aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, etc., but embodiments of the present disclosure are not limited to thereto.

In the present disclosure, an oxy group may indicate the one that an oxygen atom is bonded to an alkyl group or aryl group as defined above. The oxy group may include an alkoxy group and/or an aryl oxy group. The alkoxy group may be linear, branched, or cyclic. The number of carbon atoms in the alkoxy group is not particularly limited, but may be, for example, 1 to 20, or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but embodiments of the present disclosure are not limited thereto.

In the present disclosure, a boron group may refer to one that a boron atom is bonded to an alkyl group or aryl group as defined above. The boron group may include an alkyl boron group and/or an aryl boron group. Examples of the boron group may include a dimethyl boron group, a diethyl boron group, a t-butylmethyl boron group, a diphenyl boron group, a phenyl boron group, etc., but embodiments of the present disclosure are not limited thereto.

In the present disclosure, the number of carbon atoms in an amine group is not particularly limited, but may be 1 to 30. The amine group may include an alkyl amine group and/or an aryl amine group. Examples of the amine group may include a methylamine group, a dimethylamine group, a phenylamine group, a diphenylamine group, a naphthylamine group, a 9-methyl-anthracenylamine group, a triphenylamine group, etc., but embodiments of the present disclosure are not limited thereto.

In the present disclosure, non-limiting examples of the alkyl group may include an alkylthio group, an alkyl sulfoxy group, an alkylaryl group, an alkylamino group, an alkyl boron group, an alkyl silyl group, and an alkyl amine group.

In the present disclosure, non-limiting examples of the aryl group may include an aryloxy group, an arylthio group, an aryl sulfoxy group, an arylamino group, an aryl boron group, an aryl silyl group, and an aryl amine group.

In the present disclosure, a direct linkage may refer to a single bond.

In the present disclosure, “

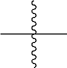

” and “ [symbol] ” may refer to a site to be connected.

Hereinafter, embodiments of the present disclosure will be described in more detail with reference to the accompanying drawings.

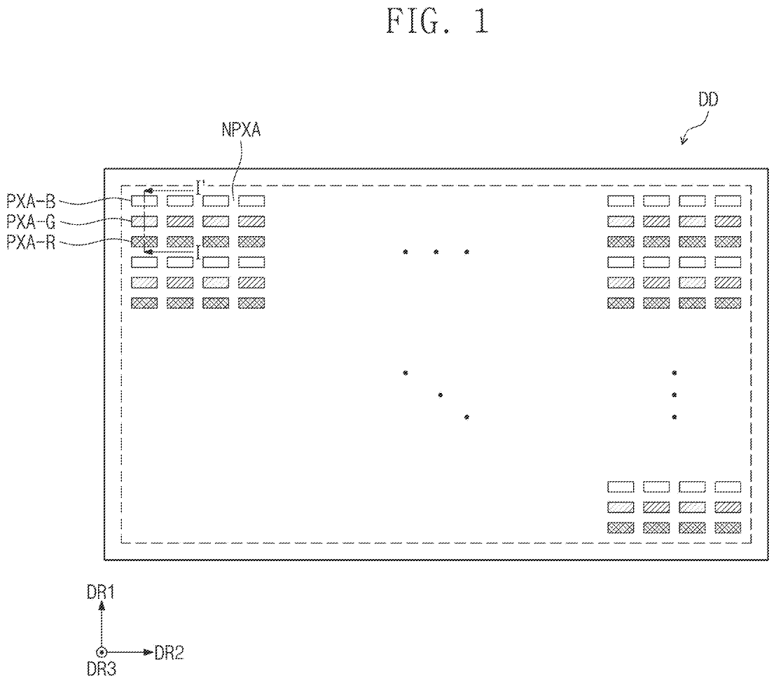

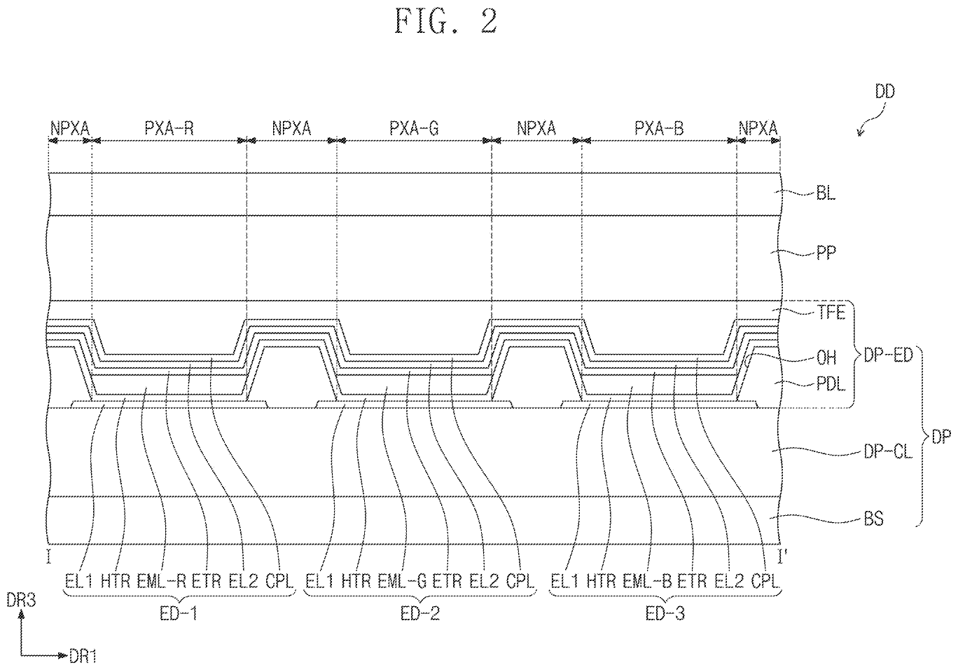

FIG. 1 is a plan view of a display device DD according to one or more embodiments of the present disclosure. FIG. 2 is a cross-sectional view of the display device DD according to one or more embodiments of the present disclosure. FIG. 2 is a cross-sectional view showing a portion corresponding to line I-I′ of FIG. 1.

The display device DD may include a display panel DP and an optical layer PP disposed on the display panel DP. The display panel DP may include light emitting elements ED-1, ED-2, and ED-3. The display device DD may include a plurality of light emitting elements ED-1, ED-2, and ED-3. The optical layer PP may be disposed on the display panel DP to control reflected light in the display panel DP due to external light. The optical layer PP may include, for example, a polarizing layer or a color filter layer. In some embodiments, unlike what is shown in the drawings, the optical layer PP may not be provided in the display device DD.

A base substrate BL may be disposed on the optical layer PP. The base substrate BL may be a member providing a base surface on which the optical layer PP is disposed. The base substrate BL may be a glass substrate, a metal substrate, a plastic substrate, etc. However, embodiments of the present disclosure are not limited thereto, and the base substrate BL may be an inorganic layer, an organic layer, or a composite material layer. In some embodiments, the base substrate BL may not be provided.

The display device DD according to one or more embodiments may further include a filling layer. The filling layer may be disposed between a display element layer DP-ED and the base substrate BL. The filling layer may be an organic material layer. The filling layer may include at least one selected from among an acrylic resin, a silicone-based resin, and an epoxy-based resin.

The display panel DP may include a base layer BS, a circuit layer DP-CL provided on the base layer BS, and a display element layer DP-ED. The display element layer DP-ED may include pixel defining films PDL, a plurality of light emitting elements ED-1, ED-2, and ED-3 disposed between the pixel defining films PDL, and an encapsulation layer TFE disposed on the plurality of light emitting elements ED-1, ED-2, and ED-3.

The base layer BS may be a member providing a base surface on which the display element layer DP-ED is disposed. The base layer BS may be a glass substrate, a metal substrate, a plastic substrate, etc. However, embodiments of the present disclosure are not limited thereto, and the base layer BS may be an inorganic layer, an organic layer, or a composite material layer.

In one or more embodiments, the circuit layer DP-CL may be disposed on the base layer BS, and the circuit layer DP-CL may include a plurality of transistors. The transistors may each include a control electrode, an input electrode, and an output electrode. For example, in some embodiments, the circuit layer DP-CL may include a switching transistor and a driving transistor for driving the plurality of light emitting elements ED-1, ED-2 and ED-3 of the display element layer DP-ED.

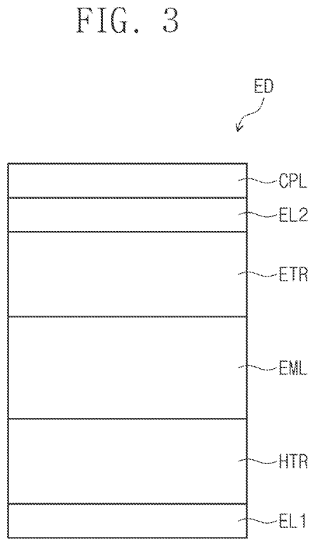

In one or more embodiments, the light emitting elements ED-1, ED-2, and ED-3 may each have a structure of a light emitting element ED according to FIGS. 3 to 6, which will be described later. The light emitting elements ED-1, ED-2, and ED-3 may each include a first electrode EL1, a hole transport region HTR, a respective or at least one selected from emission layers EML-R, EML-G, and EML-B, an electron transport region ETR, a second electrode EL2, and a capping layer CPL.

FIG. 2 shows an embodiment in which the emission layers EML-R, EML-G, and EML-B of the light emitting elements ED-1, ED-2, and ED-3, respectively, are disposed in openings OH defined in the pixel defining films PDL, and the hole transport region HTR, the electron transport region ETR, and the second electrode EL2, and the capping layer CPL are provided as a common layer throughout the light emitting elements ED-1, ED-2, and ED-3. However, embodiments of the present disclosure are not limited thereto, and unlike what is shown in FIG. 2, in one or more embodiments, the hole transport region HTR, the electron transport region ETR, and the capping layer CPL may be provided to be patterned inside the openings OH defined in the pixel defining films PDL. For example, in one or more embodiments, the hole transport region HTR, the respective emission layers EML-R, EML-G, and EML-B, the electron transport region ETR, the capping layer CPL, and/or the like of the light emitting elements ED-1, ED-2, and ED-3 may be provided to be patterned through an inkjet printing method.

The encapsulation layer TFE may cover the light emitting elements ED-1, ED-2, and ED-3. The encapsulation layer TFE may seal the display element layer DP-ED. The encapsulation layer TFE may be a thin film encapsulation layer. The encapsulation layer TFE may be a single layer or a stacked layer of a plurality of layers. The encapsulation layer TFE may include at least one insulating layer. The encapsulation layer TFE according to one or more embodiments may include at least one inorganic film (hereinafter, an encapsulation inorganic film). In some embodiments, the encapsulation layer TFE may include at least one organic film (hereinafter, an encapsulation organic film) and at least one encapsulation inorganic film.

The encapsulation inorganic film protects the display element layer DP-ED from moisture/oxygen, and the encapsulation organic film protects the display element layer DP-ED from foreign substances such as dust particles. The encapsulation inorganic film may include silicon nitride, silicon oxy nitride, silicon oxide, titanium oxide, aluminum oxide, etc., but embodiments of the present disclosure are not particularly limited thereto. The encapsulation organic layer may include an acrylic compound, an epoxy-based compound, etc. The encapsulation organic layer may include a photopolymerizable organic material, but embodiments of the present disclosure are not particularly limited thereto.

The encapsulation layer TFE may be disposed on the capping layer CPL, and may be disposed to fill the openings OH.

Referring to FIGS. 1 and 2, the display device DD may include non-light emitting regions NPXA and light emitting regions PXA-R, PXA-G, and PXA-B. The light emitting regions PXA-R, PXA-G, and PXA-B may each be a region emitting light generated from each of the light emitting elements ED-1, ED-2, and ED-3, respectively. The light emitting regions PXA-R, PXA-G, and PXA-B may be spaced apart from each other when viewed on a plane.

The light emitting regions PXA-R, PXA-G, and PXA-B may each be a region separated by the pixel defining films PDL. The non-light emitting regions NPXA may be regions between neighboring light emitting regions PXA-R, PXA-G, and PXA-B, and may correspond to the pixel defining films PDL. In some embodiments of the present disclosure, the light emitting regions PXA-R, PXA-G, and PXA-B may each correspond to a pixel. The pixel defining films PDL may separate the light emitting elements ED-1, ED-2, and ED-3. The emission layers EML-R, EML-G, and EML-B of the light emitting elements ED-1, ED-2, and ED-3 may be disposed and separated in the openings OH defined by the pixel defining films PDL.

The light emitting regions PXA-R, PXA-G, and PXA-B may be divided into a plurality of groups according to the color of light generated from the light emitting elements ED-1, ED-2, and ED-3. In the display device DD shown in FIGS. 1 and 2, three light emitting regions PXA-R, PXA-G, and PXA-B which emit red light, green light, and blue light, respectively, are shown as an example. For example, the display device DD of one or more embodiments may include a red light emitting region PXA-R, a green light emitting region PXA-G, and a blue light emitting region PXA-B, which are distinct from one another.

In the display device DD according to one or more embodiments, the plurality of light emitting elements ED-1, ED-2, and ED-3 may be to emit light having different wavelength ranges. For example, in one or more embodiments, the display device DD may include a first light emitting element ED-1 emitting red light, a second light emitting element ED-2 emitting green light, and a third light emitting element ED-3 emitting blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, embodiments of the present disclosure are not limited thereto, and the first to third light emitting elements ED-1, ED-2 and ED-3 may be to emit light in substantially the same wavelength range or emit light in at least one different wavelength range. For example, in some embodiments, the first to third light emitting elements ED-1, ED-2, and ED-3 may all be to emit blue light.

The light emitting regions PXA-R, PXA-G, and PXA-B in the display device DD according to one or more embodiments may be arranged in the form of a stripe. Referring to FIG. 1, in some embodiments, a plurality of red light emitting regions PXA-R may be arranged with each other along a second direction axis DR2, a plurality of green light emitting regions PXA-G may be arranged with each other along the second direction axis DR2, and a plurality of blue light emitting regions PXA-B may be arranged with each other along the second direction DR2. In some embodiments, the red light emitting region PXA-R, the green light emitting region PXA-G, and the blue light emitting region PXA-B may be alternately arranged in turn along a first direction DR1.

FIGS. 1 and 2 show that the light emitting regions PXA-R, PXA-G, and PXA-B are all similar in size, but embodiments of the present disclosure are not limited thereto, and the light emitting regions PXA-R, PXA-G, and PXA-B may be different in size from each other according to wavelength range of emitted light. In some embodiments, the areas of the light emitting regions PXA-R, PXA-G, and PXA-B may refer to areas when viewed on a plane defined by the first direction DR1 and the second direction DR2.

In some embodiments, the arrangement of the light emitting regions PXA-R, PXA-G, and PXA-B is not limited to what is shown in FIG. 1, and the order in which the red light emitting region PXA-R, the green light emitting region PXA-G, and the blue light emitting region PXA-B are arranged comes with varied combination according to display quality characteristics required for the display device DD. For example, the light emitting regions PXA-R, PXA-G, and PXA-B may be arranged in the form of a pentile (PENTILE®) (for example, an RGBG matrix, an RGBG structure, or an RGBG matrix structure) or a diamond (Diamond Pixel™) (e.g., a display (e.g., an OLED display) containing red, blue, and green (RGB) light-emitting regions arranged in the shape of diamonds). PENTILE® is a duly registered trademark of Samsung Display Co., Ltd. Diamond Pixel™ is a trademark of Samsung Display Co., Ltd.

In some embodiments, areas of each of the light emitting regions PXA-R, PXA-G, and PXA-B may be different in size from one another. For example, in one or more embodiments, the green light emitting region PXA-G may be smaller than the blue light emitting region PXA-B in size, but embodiments of the present disclosure are not limited thereto.

In the display device DD according to one or more embodiments, which is shown in FIG. 2, at least one selected from among the first to third light emitting elements ED-1, ED-2, and ED-3 may include a fused compound according to one or more embodiments of the present disclosure, which will be described later.

Hereinafter, FIGS. 3 to 5 are cross-sectional views schematically showing a light emitting element according to one or more embodiments. The light emitting element ED according to one or more embodiments may include a first electrode EL1, a second electrode EL2 facing the first electrode EL1, and at least one functional layer disposed between the first electrode EL1 and the second electrode EL2, and a capping layer CPL disposed on the second electrode EL2. The light emitting element ED according to one or more embodiments may include a fused compound according to one or more embodiments of the present disclosure, which will be described later, in the capping layer CPL.

The light emitting element ED may include a hole transport region HTR, an emission layer EML, and an electron transport region ETR, which are sequentially stacked, as the at least one functional layer. Referring to FIG. 3, the light emitting element ED according to one or more embodiments may include a first electrode EL1, a hole transport region HTR, an emission layer EML, an electron transport region ETR, a second electrode EL2, and a capping layer CPL. In some embodiments, the light emitting element ED according to one or more embodiments may include a fused compound according to one or more embodiments of present disclosure, which will be described later, in the capping layer CPL.

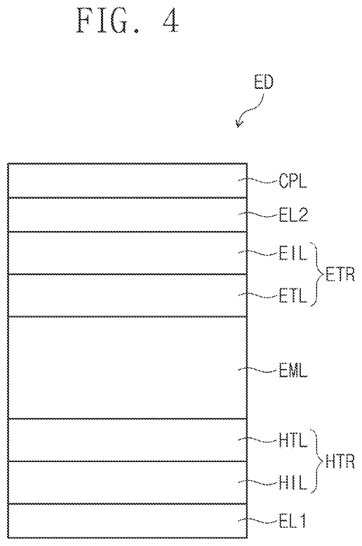

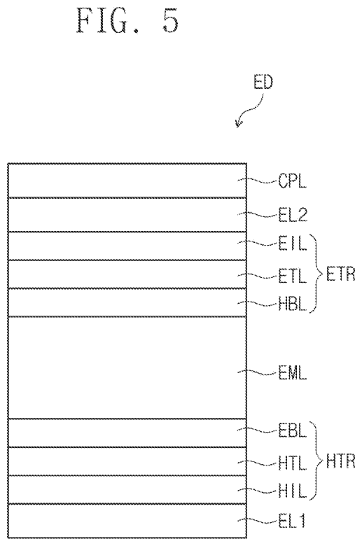

FIG. 4 shows, compared with FIG. 3, a cross-sectional view of a light emitting element ED of one or more embodiments in which the hole transport region HTR may include a hole injection layer HIL and a hole transport layer HTL, and the electron transport region ETR may include an electron injection layer EIL and an electron transport layer ETL. In some embodiments, FIG. 5 shows, compared with FIG. 3, a cross-sectional view of a light emitting element ED of one or more embodiments in which the hole transport region HTR may include a hole injection layer HIL, a hole transport layer HTL, and an electron blocking layer EBL, and the electron transport region ETR may include an electron injection layer EIL, an electron transport layer ETL, and a hole blocking layer HBL.

The first electrode EL1 has conductivity (e.g., is a conductor). The first electrode EL1 may be formed of a metal material, a metal alloy, or a conductive compound. The first electrode EL1 may be an anode or a cathode. However, embodiments of the present disclosure are not limited thereto. In some embodiments, the first electrode EL1 may be a pixel electrode. The first electrode EL1 may be a transmissive electrode, a transflective electrode, or a reflective electrode. The first electrode may include at least one selected from among (silver) Ag, (magnesium) Mg, (copper) Cu, aluminum (Al), platinum (Pt), palladium (Pd), gold (Au), nickel (Ni), neodymium (Nd), iridium (Ir), chromium (Cr), lithium (Li), calcium (Ca), lithium fluoride (LiF), molybdenum (Mo), titanium (Ti), tungsten (W), indium (In), tin (Sn), and zinc (Zn), two or more compounds selected therefrom, two or more mixtures selected therefrom, and/or an oxide thereof.

When the first electrode EL1 is a transmissive electrode, the first electrode EL1 may include a transparent metal oxide such as indium tin oxide (ITO), indium zinc oxide (IZO), zinc oxide (ZnO), and indium tin zinc oxide (ITZO). When the first electrode EL1 is a transflective electrode or a reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound thereof, or a mixture thereof (e.g., a mixture of Ag and Mg). In some embodiments, the first electrode EL1 may have a multilayer structure including a reflective film or a transflective film formed of the above-described materials, and a transparent conductive film formed of indium tin oxide (ITO), indium zinc oxide (IZO), zinc oxide (ZnO), indium tin zinc oxide (ITZO), etc. For example, in some embodiments, the first electrode EL1 may have a three-layer structure of ITO/Ag/ITO, but embodiments of the present disclosure are not limited thereto. In some embodiments, the first electrode EL1 may include the above-described metal materials, a combination of two or more metal materials selected from the above-described metal materials, or oxides of the above-described metal materials. The first electrode EL1 may have a thickness of about 700 Å to about 10000 Å. For example, in one or more embodiments, the first electrode EL1 may have a thickness of 1000 Å to about 3000 Å.

The hole transport region HTR may be provided on the first electrode EL1. The hole transport region HTR may include at least one selected from among a hole injection layer HIL, a hole transport layer HTL, a buffer layer, a light emitting auxiliary layer, and an electron blocking layer EBL. The hole transport region HTR may have, for example, a thickness of about 50 Å to about 15000 Å.

The hole transport region HTR may have a single layer formed of a single material, a single layer formed of a plurality of different materials, or a multilayer structure having a plurality of layers formed of a plurality of different materials.

For example, in some embodiments, the hole transport region HTR may have a single-layer structure formed of the hole injection layer HIL or the hole transport layer HTL, or a single-layer structure formed of a hole injection material or a hole transport material. For example, in some embodiments, the hole transport region HTR may have a single-layer structure formed of a plurality of different materials, or a structure in which a hole injection layer HIL/hole transport layer HTL, a hole injection layer HIL/hole transport layer HTL/buffer layer, a hole injection layer HIL/buffer layer, a hole transport layer HTL/buffer layer, or a hole injection layer HIL/hole transport layer HTL/electron blocking layer EBL are stacked in order (in the stated order) from the first electrode EL1, but embodiments of the present disclosure are not limited thereto.

The hole transport region HTR may be formed utilizing one or more suitable methods such as a vacuum deposition method, a spin coating method, a casting method, a Langmuir-Blodgett (LB) method, an inkjet printing method, a laser printing method, and/or a laser induced thermal imaging (LITI) method.

The hole transport region HTR may include a compound represented by Formula H-1.

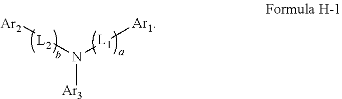

In Formula H-1, L₁ and L₂ may each independently be a direct linkage, a substituted or unsubstituted arylene group having 6 to 30 ring-forming carbon atoms, or a substituted or unsubstituted heteroarylene group having 2 to 30 ring-forming carbon atoms. A and b may each independently be an integer of 0 to 10. In some embodiments, when a or b is an integer of 2 or greater, a plurality of L₁'s and L₂'s may each independently be a substituted or unsubstituted arylene group having 6 to 30 ring-forming carbon atoms, or a substituted or unsubstituted heteroarylene group having 2 to 30 ring-forming carbon atoms.

In Formula H-1, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. In some embodiments, in Formula H-1, Ar₃ may be a substituted or unsubstituted aryl group having 6 to 30 ring-forming carbon atoms.

The compound represented by Formula H-1 may be a monoamine compound. In some embodiments, the compound represented by Formula H-1 may be a diamine compound in which at least one selected from among Ar₁ to Ar₃ may include an amine group as a substituent. In some embodiments, the compound represented by Formula H-1 may be a carbazole-based compound including a substituted or unsubstituted carbazole group in at least one of Ar₁ or Ar₂, or a substituted or unsubstituted fluorene-based group in at least one of Ar₁ or Ar₂.

The compound represented by Formula H-1 may be represented by any one selected from among compounds in Compound Group H-1. However, the compounds listed in Compound Group H-1 are presented as a mere example, and the compound represented by Formula H-1 is not limited to those listed in Compound Group H-1.

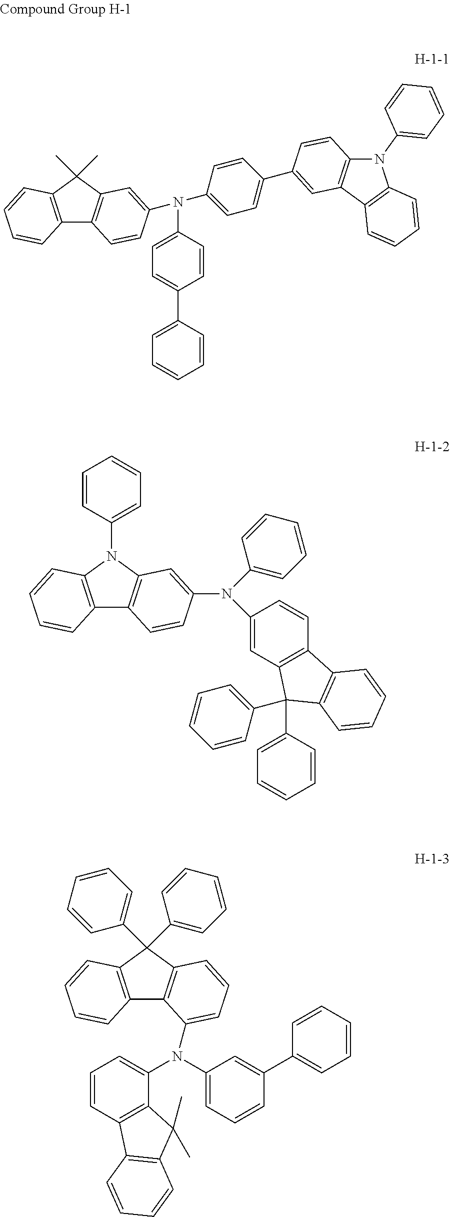

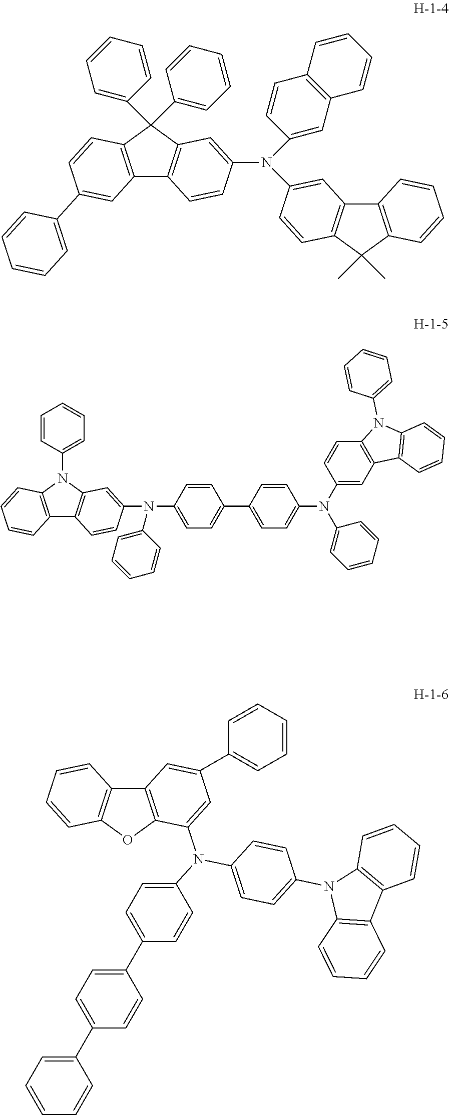

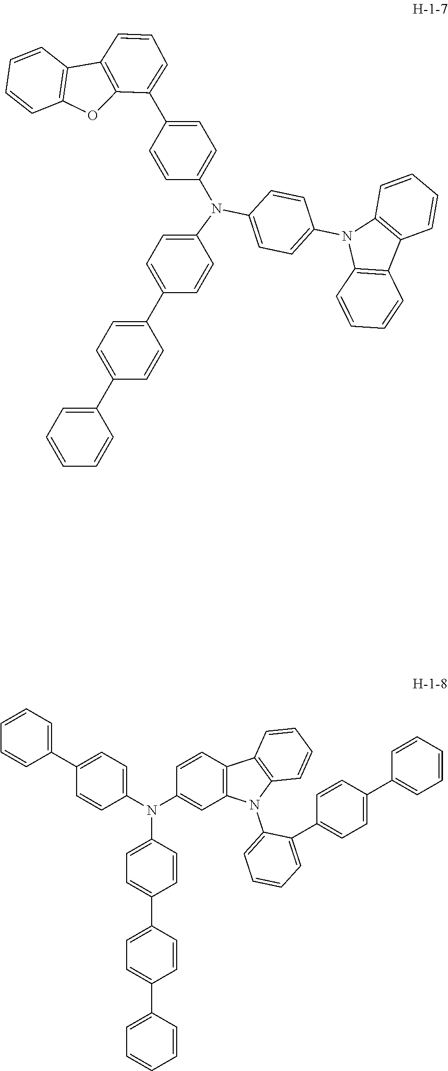 [SMILES: c1ccc(-c2ccc(-c3ccc(N(c4ccc(-c5cccc6c5oc5ccccc56)cc4)c4ccc(-n5c6ccccc6c6ccccc65)cc4)cc3)cc2)cc1 ; c1ccc(-c2ccc(-c3ccc(N(c4ccc(-c5ccccc5)cc4)c4ccc5c6ccccc6n(-c6ccccc6-c6ccc(-c7ccccc7)cc6)c5c4)cc3)cc2)cc1]

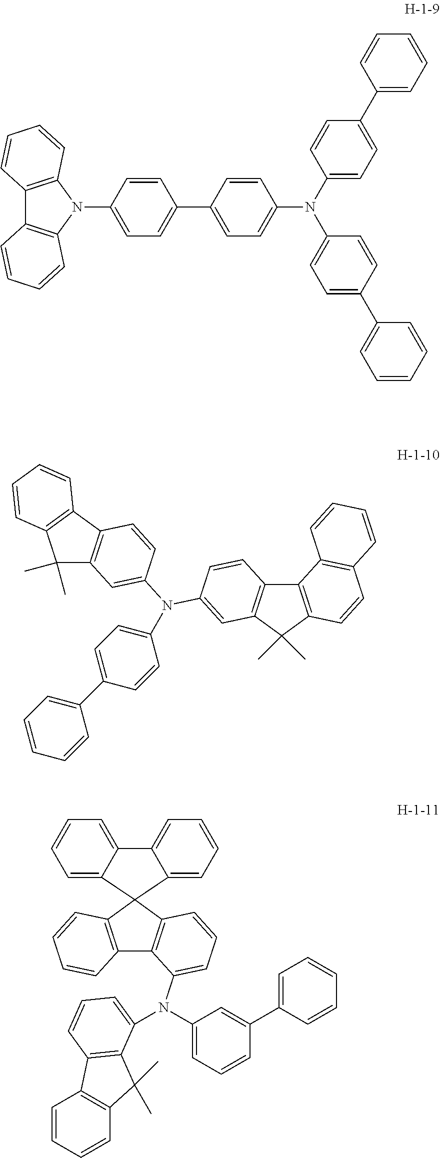 [SMILES: c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2ccccc2-c2ccc(N(c3ccc(-c4ccccc4)cc3)c3ccc4c(c3)C(C)(C)c3ccc5ccccc5c3-4)cc21 ; CC1(C)c2ccccc2-c2cccc(N(c3cccc(-c4ccccc4)c3)c3cccc4c3-c3ccccc3C43c4ccccc4-c4ccccc43)c21]

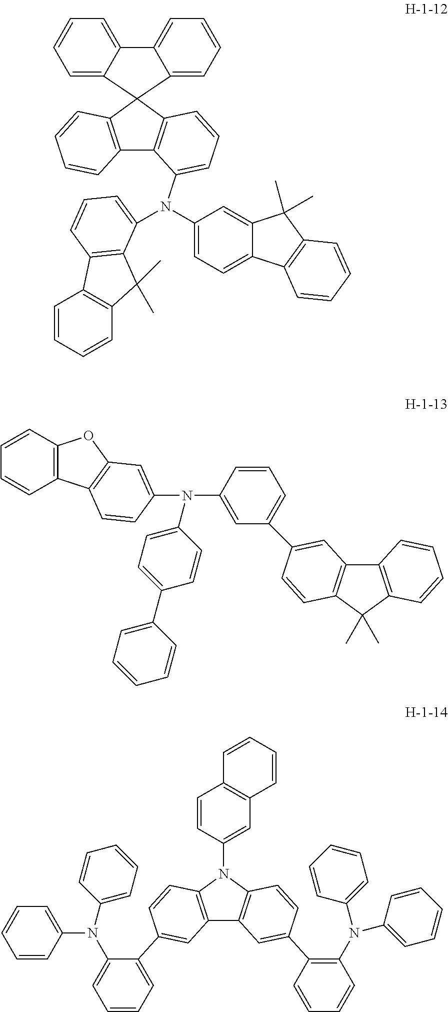 [SMILES: CC1(C)c2ccccc2-c2ccc(N(c3cccc4c3-c3ccccc3C43c4ccccc4-c4ccccc43)c3cccc4c3C(C)(C)c3ccccc3-4)cc21 ; CC1(C)c2ccccc2-c2cc(-c3cccc(N(c4ccc(-c5ccccc5)cc4)c4ccc5c(c4)oc4ccccc45)c3)ccc21 ; c1ccc(N(c2ccccc2)c2ccccc2-c2ccc3c(c2)c2cc(-c4ccccc4N(c4ccccc4)c4ccccc4)ccc2n3-c2ccc3ccccc3c2)cc1]

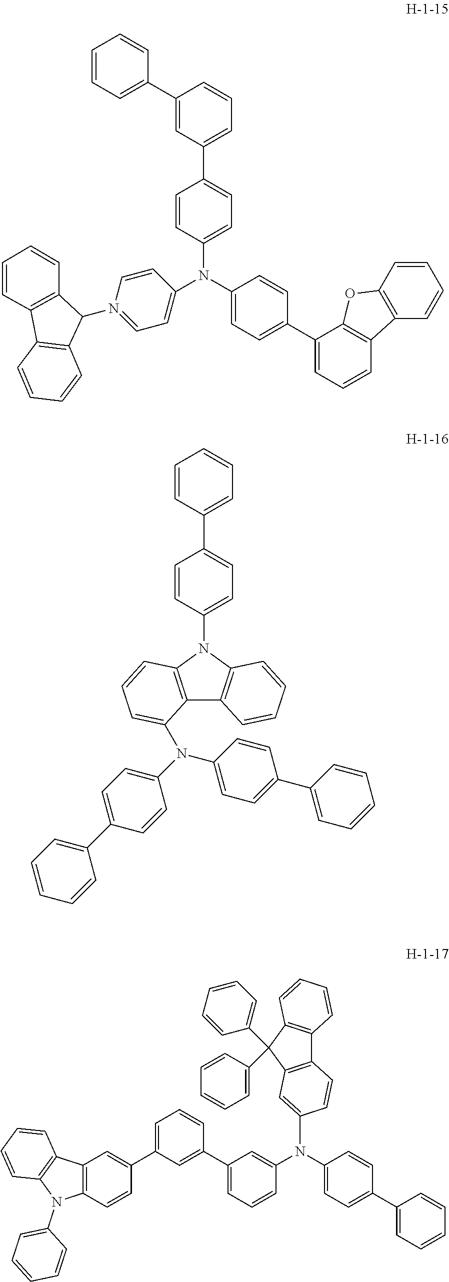

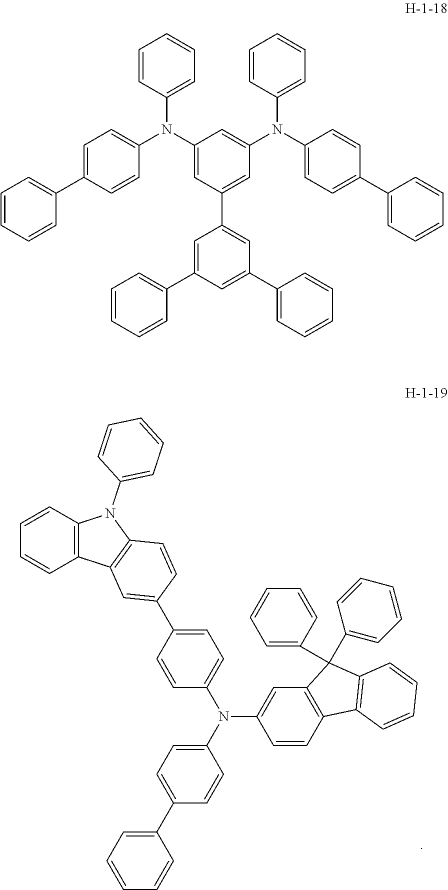 [SMILES: c1ccc(-c2ccc(N(c3ccccc3)c3cc(-c4cc(-c5ccccc5)cc(-c5ccccc5)c4)cc(N(c4ccccc4)c4ccc(-c5ccccc5)cc4)c3)cc2)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1]

The hole transport region HTR may include a phthalocyanine compound such as copper phthalocyanine, N,N′-diphenyl-N,N′-bis-[4-(phenyl-m-tolyl-amino)-phenyl]-biphenyl-4,4′-diamine (DNTPD), 4,4′,4″-[tris(3-methylphenyl)phenylamino]triphenylamine] (m-MTDATA), 4,4′,4″-tris(N,N-diphenylamino)triphenylamine (TDATA), 4,4′,4″-tris[N-(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium tetrakis(pentafluorophenyl)borate, dipyrazino[2,3-f: 2′,3′-h]quinoxaline-2,3,6,7,10,11-hexacarbonitrile (HAT-CN), etc.

The hole transport region HTR may include carbazole-based derivatives such as N-phenyl carbazole and polyvinyl carbazole, fluorene-based derivatives, N,N′-bis(3-methylphenyl)-N,N′-diphenyl-[1,1′-biphenyl]-4,4′-diamine (TPD), triphenylamine-based derivatives such as 4,4′,4″-tris(N-carbazolyl)triphenylamine (TCTA), N,N′-di(1-naphtalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In some embodiments, the hole transport region HTR may include 9-(4-tert-Butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the compounds of the hole transport region described above in at least one selected from among the hole injection layer HIL, the hole transport layer HTL, and the electron blocking layer EBL.

The hole transport region HTR may have a thickness of about 100 Å to about 10000 Å, for example, about 100 Å to about 5000 Å. When the hole transport region HTR includes the hole injection layer HIL, the hole injection layer HIL may have a thickness of, for example, about 30 Å to about 1000 Å. When the hole transport region HTR includes the hole transport layer HTL, the hole transport layer HTL may have a thickness of about 30 Å to about 1000 Å. When the hole transport region HTR includes the electron blocking layer EBL, the electron blocking layer EBL may have a thickness of, for example, about 10 Å to about 1000 Å. When the thicknesses of the hole transport region HTR, the hole injection layer HIL, the hole transport layer HTL, and the electron blocking layer EBL satisfy the above-described ranges, satisfactory hole transport properties may be obtained without a substantial increase in driving voltage.

The hole transport region HTR may further include, in addition to the above-described materials, a charge generation material to increase conductivity. The charge generation material may be uniformly or non-uniformly dispersed in the hole transport region HTR. The charge generation material may be, for example, a p-dopant. The p-dopant may include at least one of halogenated metal compounds, quinone derivatives, metal oxides, or cyano group-containing compounds, but embodiments of the present disclosure are not limited thereto. For example, in some embodiments, the p-dopant may include one or more of halogenated metal compounds such as CuI and/or RbI, quinone derivatives such as tetracyanoquinodimethane (TCNQ) and/or 2,3,5,6-tetrafluoro-7,7,8,8-tetracyanoquinodimethane (F4-TCNQ), metal oxides such as tungsten oxides and/or molybdenum oxides, cyano group-containing compounds such as dipyrazino[2,3-f: 2′,3′-h] quinoxaline-2,3,6,7,10,11-hexacarbonitrile (HATCN) and 4[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but embodiments of the present disclosure are not limited thereto.

As described above, the hole transport region HTR may further include at least one of a buffer layer or an electron blocking layer EBL in addition to the hole injection layer HIL and the hole transport layer HTL. The buffer layer may compensate a resonance distance according to wavelengths of light emitted from an emission layer EML, and may thus increase light emitting efficiency. Materials which may be included in the hole transport region HTR may be utilized as materials included in the buffer layer. The electron blocking layer EBL is a layer that serves to prevent or reduce electrons from being injected from the electron transport region ETR to the hole transport region HTR.

The emission layer EML is provided on the hole transport region HTR. The emission layer EML may have, for example, a thickness of about 100 Å to about 1000 Å or about 100 Å to about 300 Å. The emission layer EML may include a single layer formed of a single material, a single layer formed of a plurality of different materials, or a multilayer structure having a plurality of layers formed of a plurality of different materials.

In one or more embodiments, in the light emitting element ED, the emission layer EML may be to emit blue light. The light emitting element ED may include the amine compound of an embodiment described above in the hole transport region HTR, and may thus exhibit high efficiency and long lifespan characteristics in the blue light emitting region. However, embodiments of the present disclosure are not limited thereto.

In the light emitting element ED of one or more embodiments, the emission layer EML may include an anthracene derivative, a pyrene derivative, a fluoranthene derivative, a chrysene derivative, a dihydrobenzanthracene derivative, and/or a triphenylene derivative. In some embodiments, the emission layer EML may include an anthracene derivative and/or a pyrene derivative.

In the light emitting element ED of the embodiments shown in FIGS. 3 to 5, the emission layer EML may include a host and a dopant, and the emission layer EML may include a compound represented by Formula E-1. The compound represented by Formula E-1 may be utilized as a fluorescent host material.

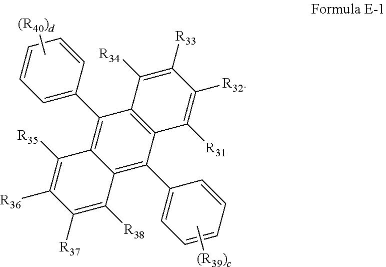

In Formula E-1, R₃₁ to R₄₀ may each independently be hydrogen, deuterium, a halogen, a substituted or unsubstituted silyl group, a substituted or unsubstituted thio group, a substituted or unsubstituted oxy group, a substituted or unsubstituted alkyl group having 1 to 10 carbon atoms, a substituted or unsubstituted alkenyl group having 2 to 10 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In some embodiments, R₃₁ to R₄₀ may be bonded to an adjacent group to form a saturated hydrocarbon ring, an unsaturated hydrocarbon ring, a saturated heterocycle, or an unsaturated heterocycle.

In Formula E-1, c and d may each independently be an integer of 0 to 5.

The compound represented by Formula E-1 may be any one selected from among compounds E1 to E19.

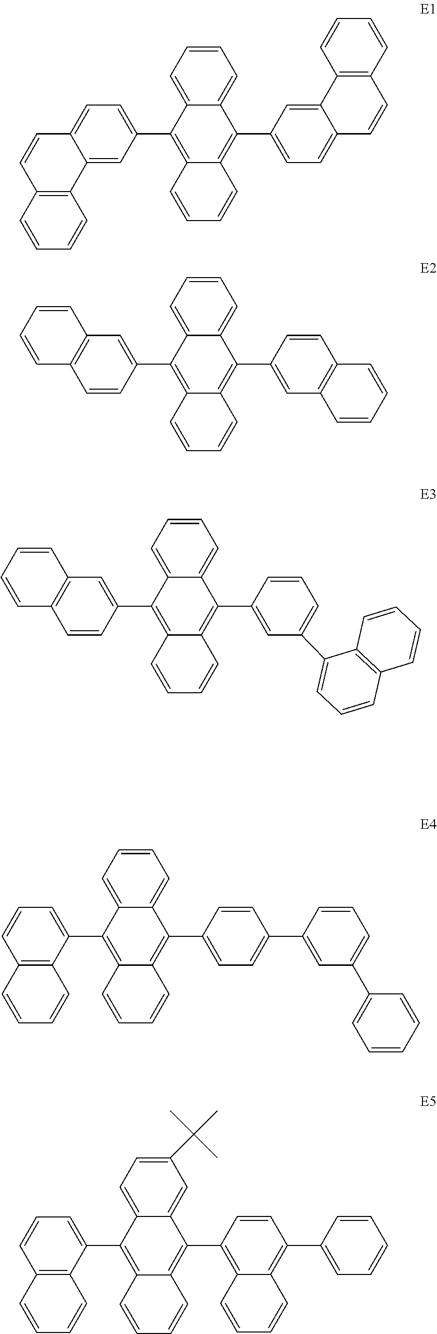

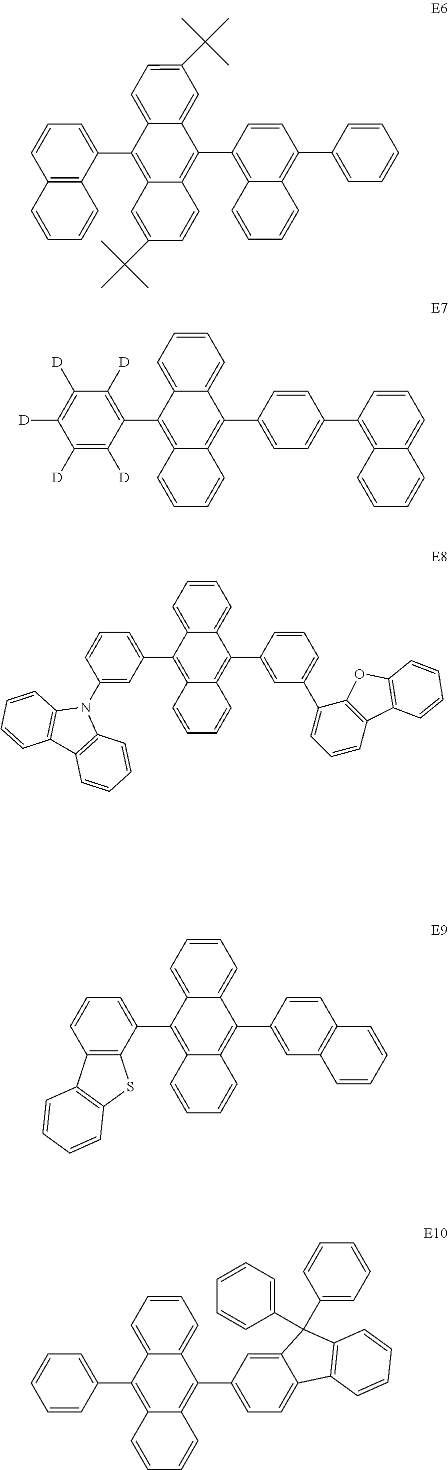

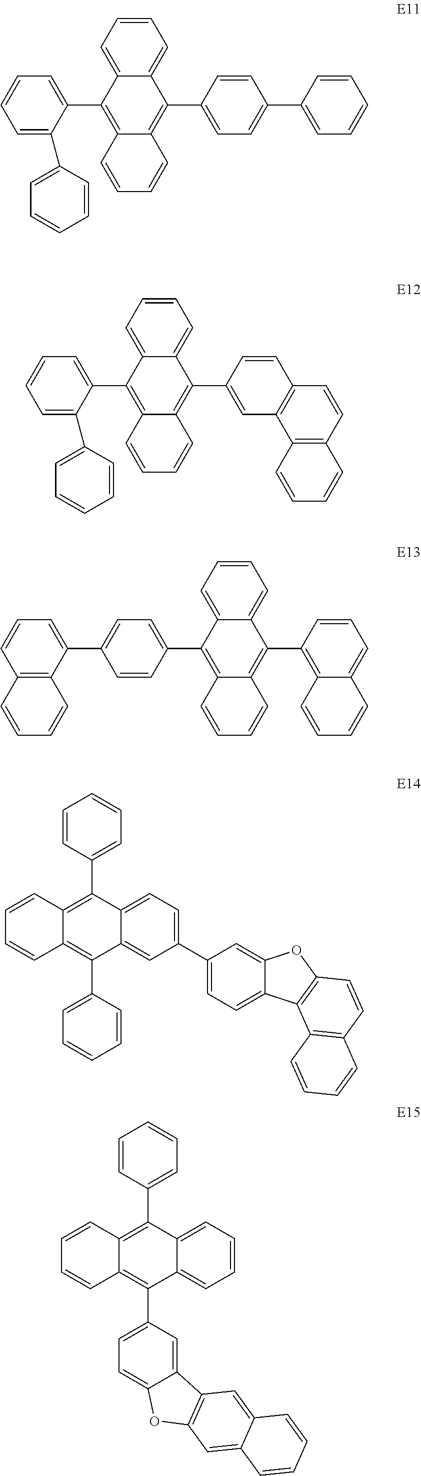

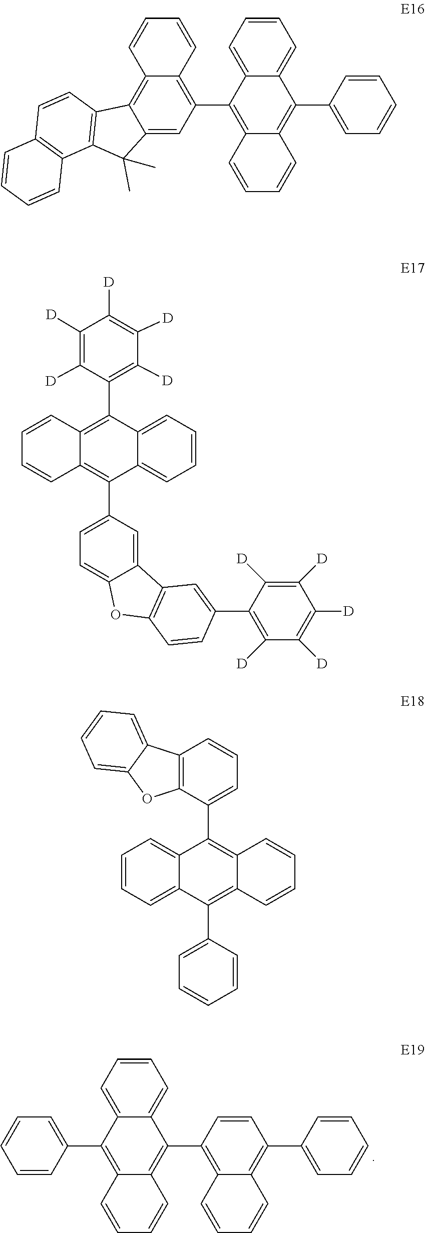

In one or more embodiments, the emission layer EML may include a compound represented by Formula HT. For example, in some embodiments, a compound represented by Formula HT may be utilized as a hole transporting host material.

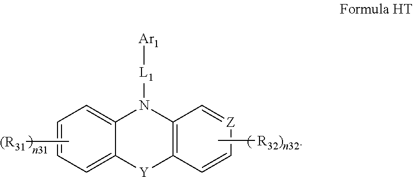

In Formula HT, L₁ may be a direct linkage, a substituted or unsubstituted arylene group having 6 to 30 ring-forming carbon atoms, or a substituted or unsubstituted heteroarylene group having 2 to 30 ring-forming carbon atoms. For example, in some embodiments, L₁ may be a direct linkage, a substituted or unsubstituted phenylene group, a substituted or unsubstituted divalent biphenyl group, a substituted or unsubstituted divalent carbazole group, and/or the like, but embodiments of the present disclosure are not limited thereto.

Ar₁ may be a substituted or unsubstituted aryl group having 6 to 30 ring-forming carbon atoms, or a substituted or unsubstituted heteroaryl group having 2 to ring-forming carbon atoms. For example, in some embodiments, Ar₁ may be a substituted or unsubstituted carbazole group, a substituted or unsubstituted dibenzofuran group, a substituted or unsubstituted dibenzothiophene group, a substituted or unsubstituted biphenyl group, and/or the like, but embodiments of the present disclosure are not limited thereto.

Y may be a direct linkage, CR_{y1}R_{y2}, or SiR_{y3}R_{y4}. For example, two benzene rings connected to nitrogen atoms of Formula HT may be connected through a direct linkage,

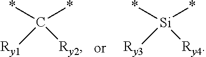

For example, when Y is a direct linkage, a compound represented by Formula HT may include a carbazole unit.

Z is CRz or N.

R_{y1} to R_{y4}, R₃₁, R₃₂, and R_{z} may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, in some embodiments, R_{y1} to R_{y4} may each independently be a methyl group or a phenyl group. For example, in some embodiments, R₃₁ and R₃₂ may each independently be hydrogen or deuterium.

n31 is an integer of 0 to 4. When n31 is 0, the fused polycyclic compound represented by Formula HT according to one or more embodiments may not be substituted with R₃₁. When n31 is 4, and R₃₁ is hydrogen, the embodiment may be the same as when n31 is 0. When n31 is an integer of 2 or greater, two or more R₃₁'s may be the same as or different from each other.

n32 is independently an integer of 0 to 3. When n32 is 0, the fused polycyclic compound represented by Formula HT according to one or more embodiments may not be substituted with R₃₂. When n32 is 3, and R₃₂ is hydrogen, the embodiment may be the same as when n32 is 0. When n32 is an integer of 2 or greater, two or more R₃₂'s may be the same as or different from each other.

In one or more embodiments, the compound represented by Formula HT may be any one selected from among the compounds of Compound Group HT. The emission layer EML may include at least one selected from among the compounds shown in Compound Group HT, as a hole transporting host material. In Compound Group HT, “D” is deuterium, and “Ph” is a substituted or unsubstituted phenyl group.

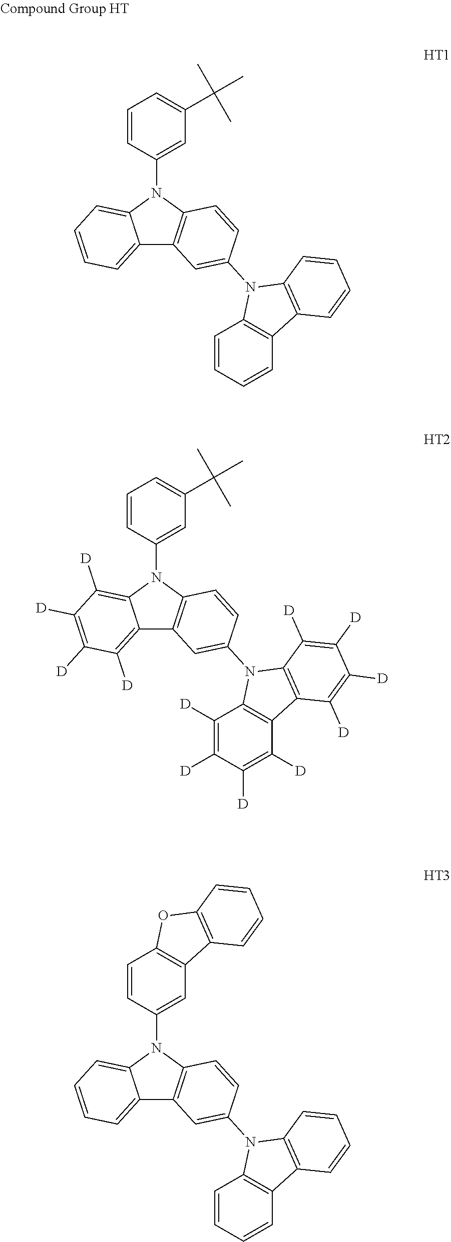 [SMILES: CC(C)(C)c1cccc(-n2c3ccccc3c3cc(-n4c5ccccc5c5ccccc54)ccc32)c1 ; [2H]c1c([2H])c([2H])c2c(c1[2H])c1cc(-n3c4c([2H])c([2H])c([2H])c([2H])c4c4c([2H])c([2H])c([2H])c([2H])c43)ccc1n2-c1cccc(C(C)(C)C)c1 ; c1ccc2c(c1)oc1ccc(-n3c4ccccc4c4cc(-n5c6ccccc6c6ccccc65)ccc43)cc12]

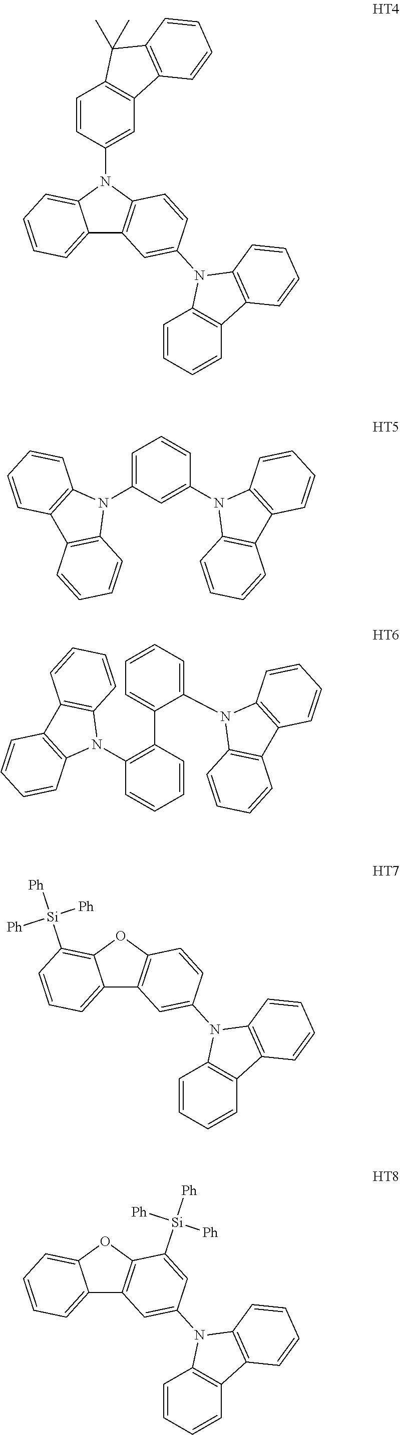 [SMILES: CC1(C)c2ccccc2-c2cc(-n3c4ccccc4c4cc(-n5c6ccccc6c6ccccc65)ccc43)ccc21 ; c1cc(-n2c3ccccc3c3ccccc32)cc(-n2c3ccccc3c3ccccc32)c1 ; c1ccc(-n2c3ccccc3c3ccccc32)c(-c2ccccc2-n2c3ccccc3c3ccccc32)c1 ; c1ccc([Si](c2ccccc2)(c2ccccc2)c2cccc3c2oc2ccc(-n4c5ccccc5c5ccccc54)cc23)cc1 ; c1ccc([Si](c2ccccc2)(c2ccccc2)c2cc(-n3c4ccccc4c4ccccc43)cc3c2oc2ccccc23)cc1]

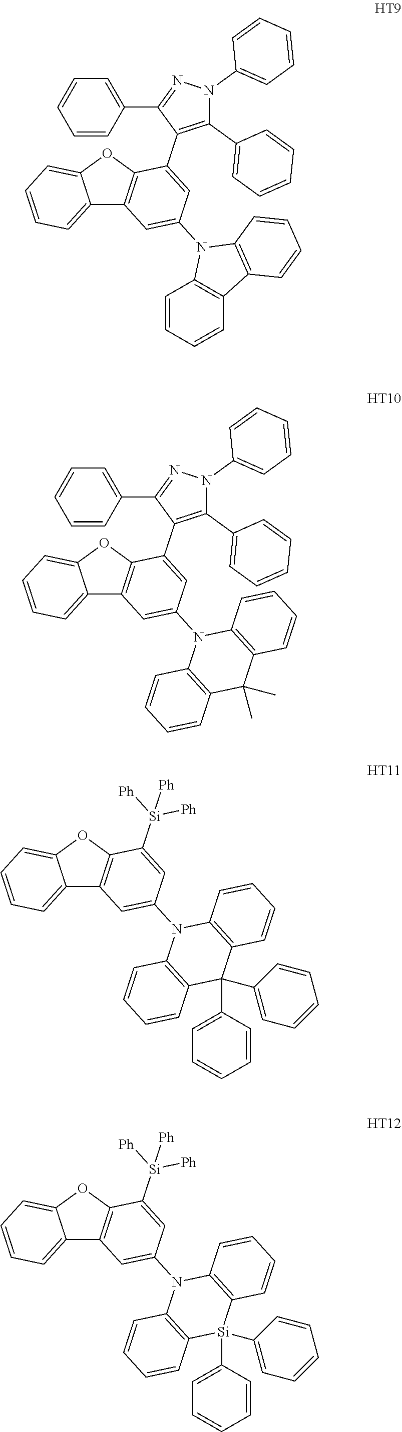 [SMILES: c1ccc(-c2nn(-c3ccccc3)c(-c3ccccc3)c2-c2cc(-n3c4ccccc4c4ccccc43)cc3c2oc2ccccc23)cc1 ; CC1(C)c2ccccc2N(c2cc(-c3c(-c4ccccc4)nn(-c4ccccc4)c3-c3ccccc3)c3oc4ccccc4c3c2)c2ccccc21 ; c1ccc(C2(c3ccccc3)c3ccccc3N(c3cc([Si](c4ccccc4)(c4ccccc4)c4ccccc4)c4oc5ccccc5c4c3)c3ccccc32)cc1 ; c1ccc([Si]2(c3ccccc3)c3ccccc3N(c3cc([Si](c4ccccc4)(c4ccccc4)c4ccccc4)c4oc5ccccc5c4c3)c3ccccc32)cc1]

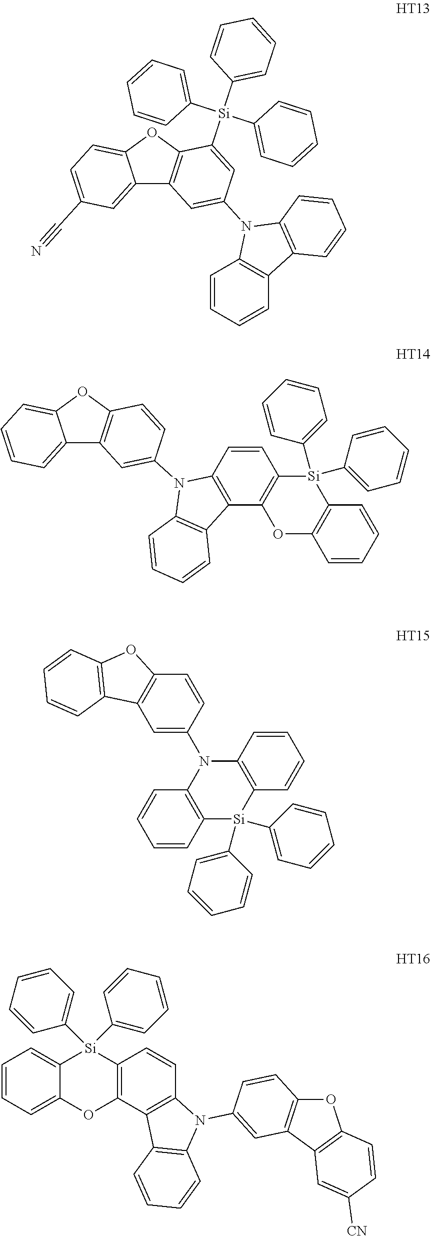 [SMILES: N#Cc1ccc2oc3c([Si](c4ccccc4)(c4ccccc4)c4ccccc4)cc(-n4c5ccccc5c5ccccc54)cc3c2c1 ; c1ccc([Si]2(c3ccccc3)c3ccccc3Oc3c2ccc2c3c3ccccc3n2-c2ccc3oc4ccccc4c3c2)cc1 ; c1ccc([Si]2(c3ccccc3)c3ccccc3N(c3ccc4oc5ccccc5c4c3)c3ccccc32)cc1 ; N#Cc1ccc2oc3ccc(-n4c5ccccc5c5c6c(ccc54)[Si](c4ccccc4)(c4ccccc4)c4ccccc4O6)cc3c2c1]

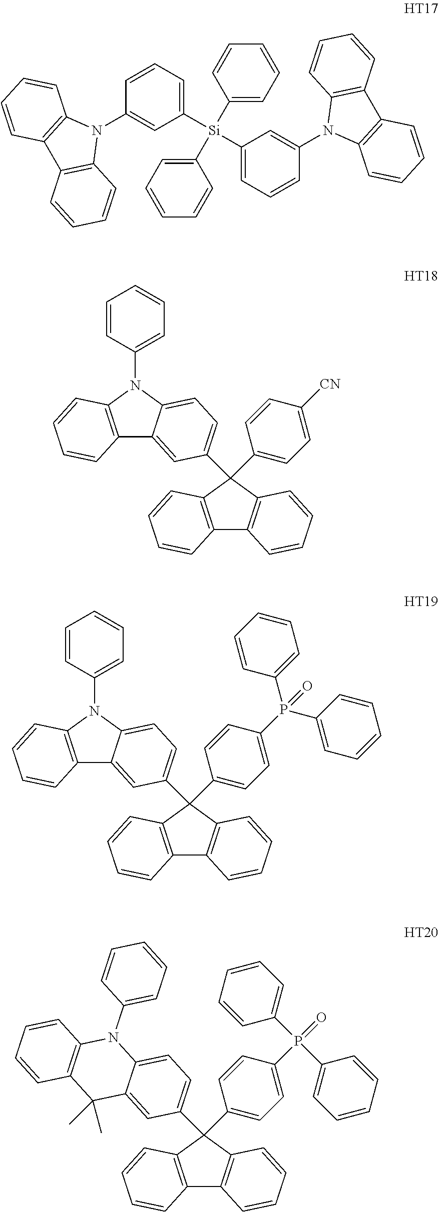 [SMILES: c1ccc([Si](c2ccccc2)(c2cccc(-n3c4ccccc4c4ccccc43)c2)c2cccc(-n3c4ccccc4c4ccccc43)c2)cc1 ; N#Cc1ccc(C2(c3ccc4c(c3)c3ccccc3n4-c3ccccc3)c3ccccc3-c3ccccc32)cc1 ; O=P(c1ccccc1)(c1ccccc1)c1ccc(C2(c3ccc4c(c3)c3ccccc3n4-c3ccccc3)c3ccccc3-c3ccccc32)cc1 ; CC1(C)c2ccccc2N(c2ccccc2)c2ccc(C3(c4ccc(P(=O)(c5ccccc5)c5ccccc5)cc4)c4ccccc4-c4ccccc43)cc21]

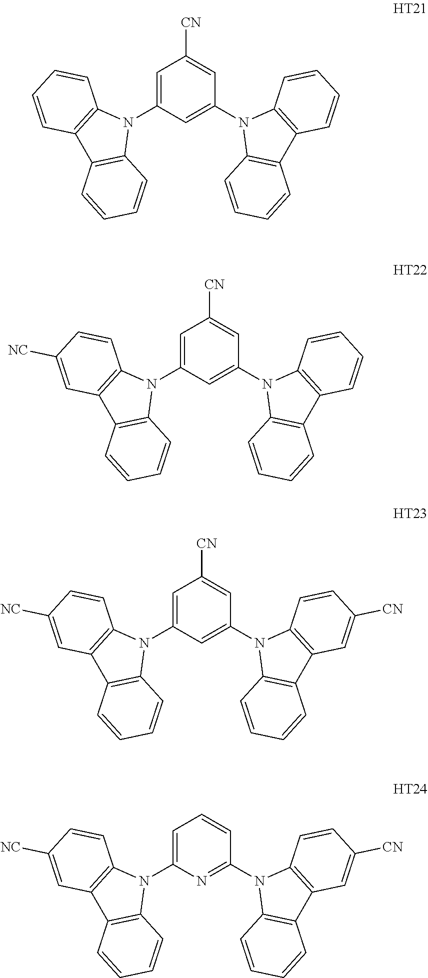 [SMILES: N#Cc1cc(-n2c3ccccc3c3ccccc32)cc(-n2c3ccccc3c3ccccc32)c1 ; N#Cc1cc(-n2c3ccccc3c3ccccc32)cc(-n2c3ccccc3c3cc(C#N)ccc32)c1 ; N#Cc1cc(-n2c3ccccc3c3cc(C#N)ccc32)cc(-n2c3ccccc3c3cc(C#N)ccc32)c1 ; N#Cc1ccc2c(c1)c1ccccc1n2-c1cccc(-n2c3ccccc3c3cc(C#N)ccc32)n1]

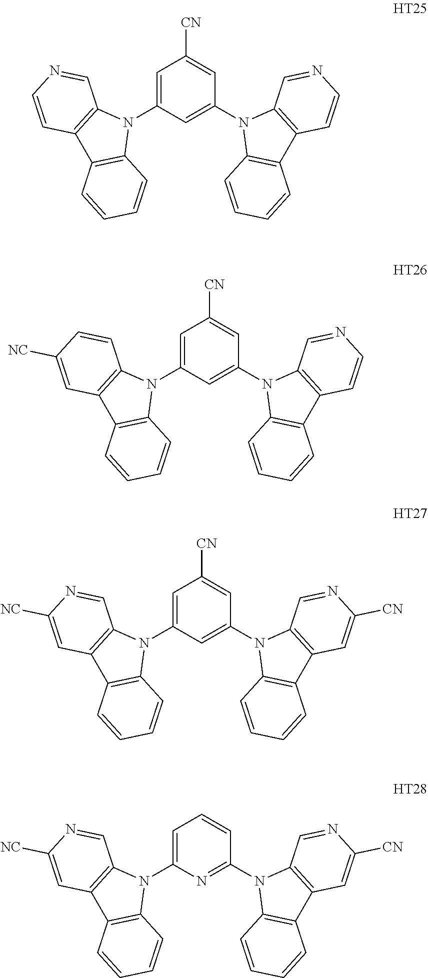 [SMILES: N#Cc1cc(-n2c3ccccc3c3ccncc32)cc(-n2c3ccccc3c3ccncc32)c1 ; N#Cc1cc(-n2c3ccccc3c3cc(C#N)ccc32)cc(-n2c3ccccc3c3ccncc32)c1 ; N#Cc1cc(-n2c3ccccc3c3cc(C#N)ncc32)cc(-n2c3ccccc3c3cc(C#N)ncc32)c1 ; N#Cc1cc2c3ccccc3n(-c3cccc(-n4c5ccccc5c5cc(C#N)ncc54)n3)c2cn1]

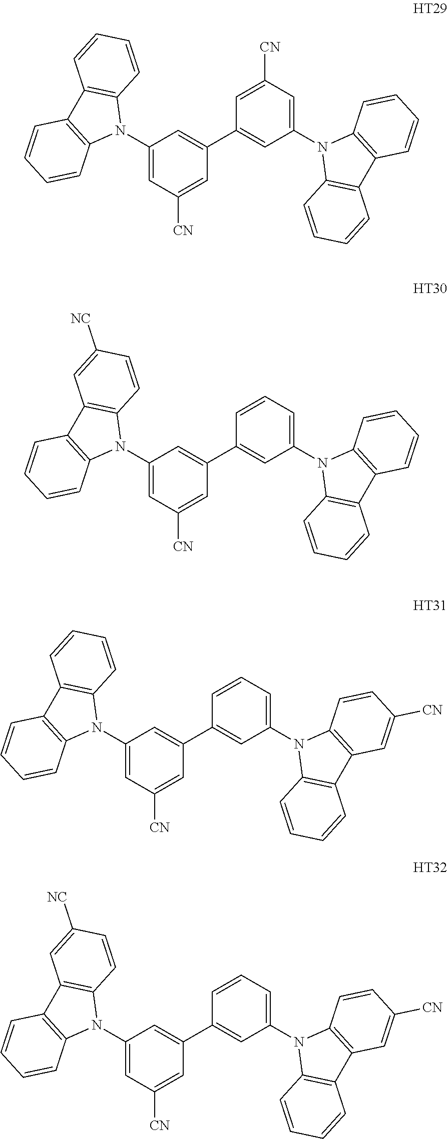 [SMILES: N#Cc1cc(-c2cc(C#N)cc(-n3c4ccccc4c4ccccc43)c2)cc(-n2c3ccccc3c3ccccc32)c1 ; N#Cc1cc(-c2cccc(-n3c4ccccc4c4ccccc43)c2)cc(-n2c3ccccc3c3cc(C#N)ccc32)c1 ; N#Cc1cc(-c2cccc(-n3c4ccccc4c4cc(C#N)ccc43)c2)cc(-n2c3ccccc3c3ccccc32)c1 ; N#Cc1cc(-c2cccc(-n3c4ccccc4c4cc(C#N)ccc43)c2)cc(-n2c3ccccc3c3cc(C#N)ccc32)c1]

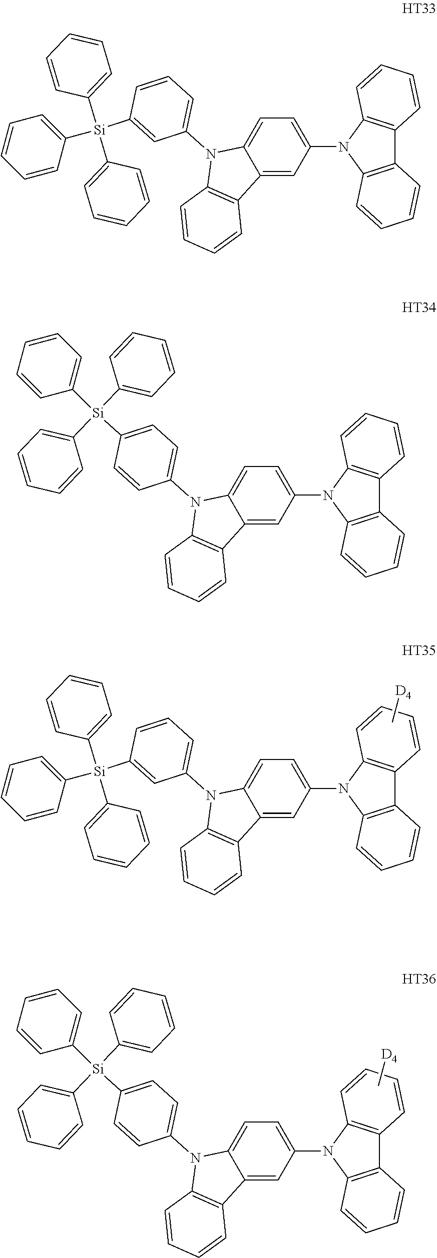

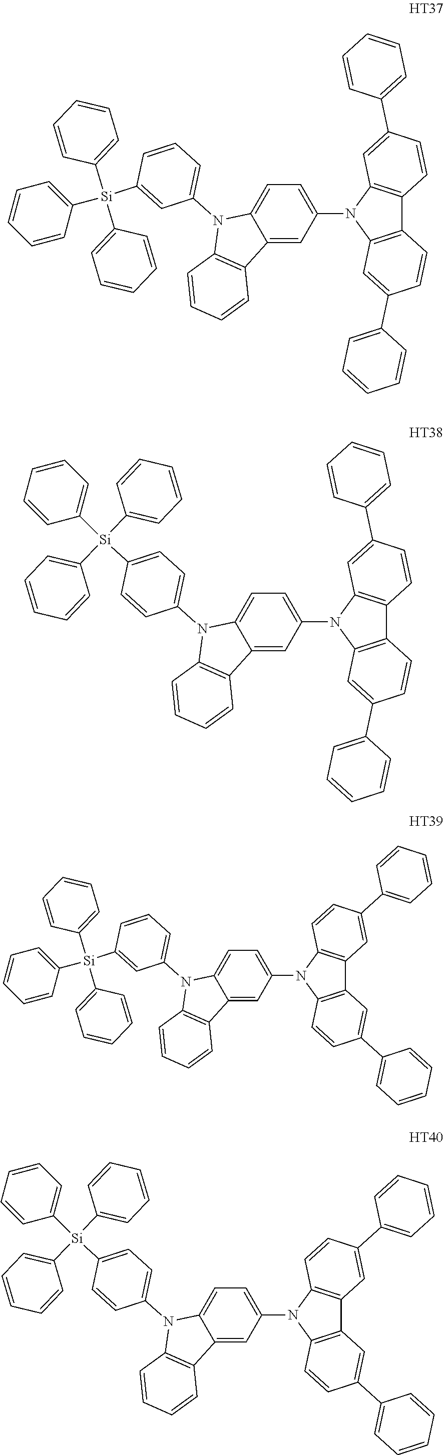 [SMILES: c1ccc(-c2ccc3c4ccc(-c5ccccc5)cc4n(-c4ccc5c(c4)c4ccccc4n5-c4cccc([Si](c5ccccc5)(c5ccccc5)c5ccccc5)c4)c3c2)cc1 ; c1ccc(-c2ccc3c4ccc(-c5ccccc5)cc4n(-c4ccc5c(c4)c4ccccc4n5-c4ccc([Si](c5ccccc5)(c5ccccc5)c5ccccc5)cc4)c3c2)cc1 ; c1ccc(-c2ccc3c(c2)c2cc(-c4ccccc4)ccc2n3-c2ccc3c(c2)c2ccccc2n3-c2cccc([Si](c3ccccc3)(c3ccccc3)c3ccccc3)c2)cc1 ; c1ccc(-c2ccc3c(c2)c2cc(-c4ccccc4)ccc2n3-c2ccc3c(c2)c2ccccc2n3-c2ccc([Si](c3ccccc3)(c3ccccc3)c3ccccc3)cc2)cc1]

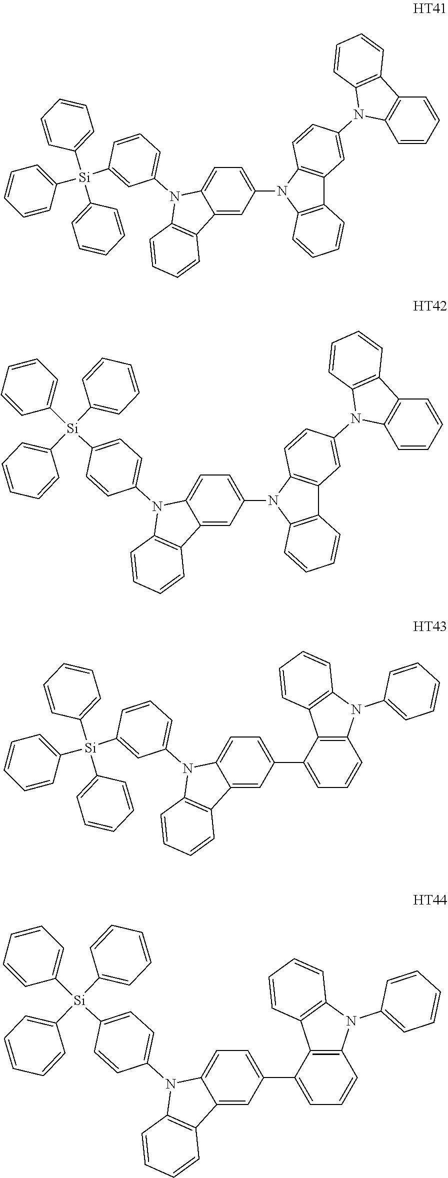 [SMILES: c1ccc([Si](c2ccccc2)(c2ccccc2)c2cccc(-n3c4ccccc4c4cc(-n5c6ccccc6c6cc(-n7c8ccccc8c8ccccc87)ccc65)ccc43)c2)cc1 ; c1ccc([Si](c2ccccc2)(c2ccccc2)c2ccc(-n3c4ccccc4c4cc(-n5c6ccccc6c6cc(-n7c8ccccc8c8ccccc87)ccc65)ccc43)cc2)cc1 ; c1ccc(-n2c3ccccc3c3c(-c4ccc5c(c4)c4ccccc4n5-c4cccc([Si](c5ccccc5)(c5ccccc5)c5ccccc5)c4)cccc32)cc1 ; c1ccc(-n2c3ccccc3c3c(-c4ccc5c(c4)c4ccccc4n5-c4ccc([Si](c5ccccc5)(c5ccccc5)c5ccccc5)cc4)cccc32)cc1]

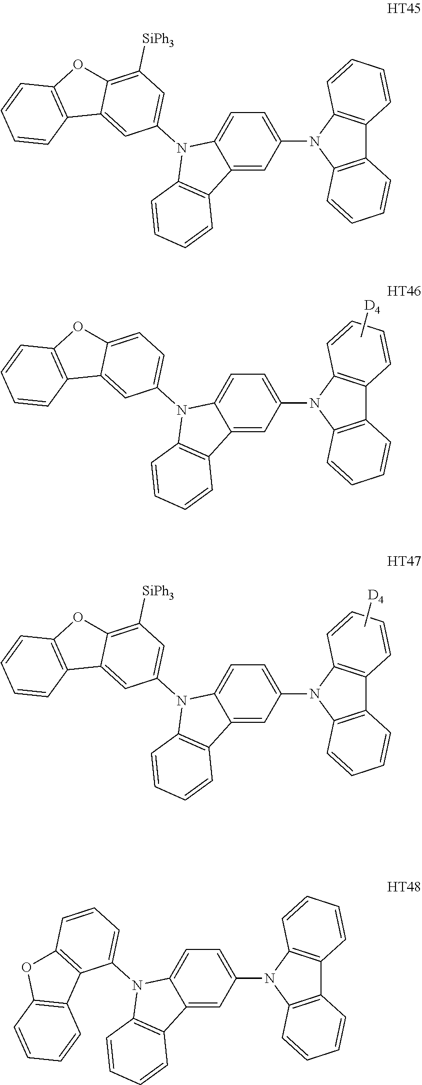

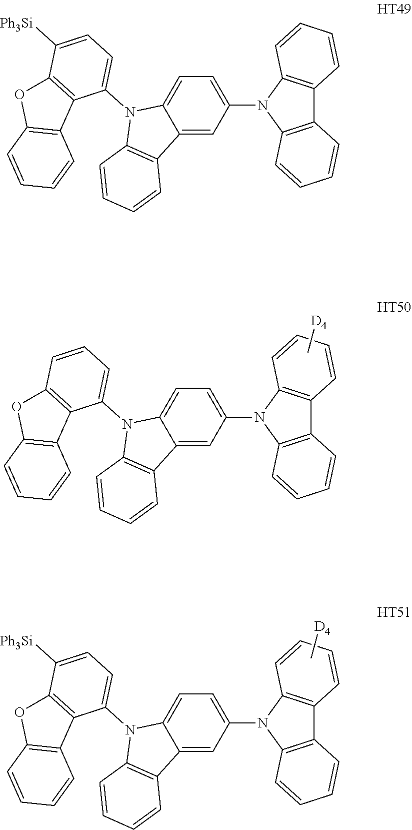

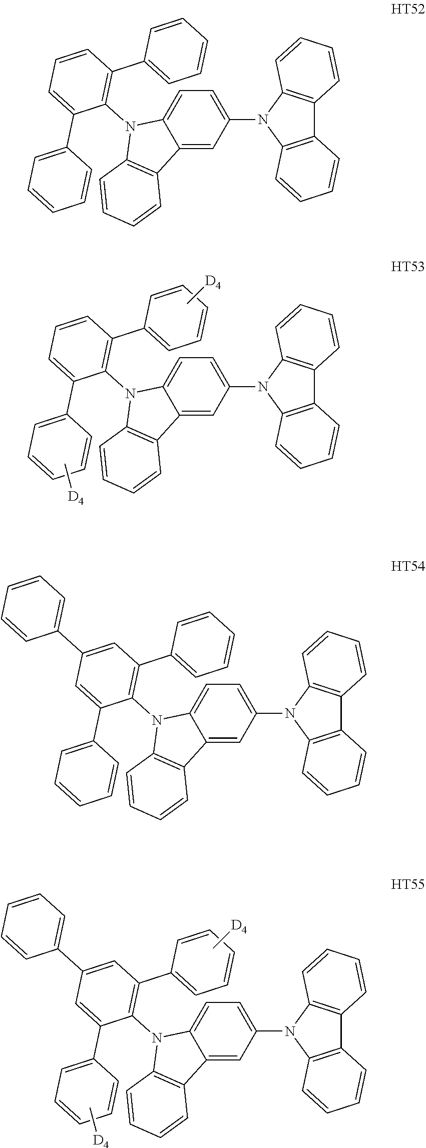

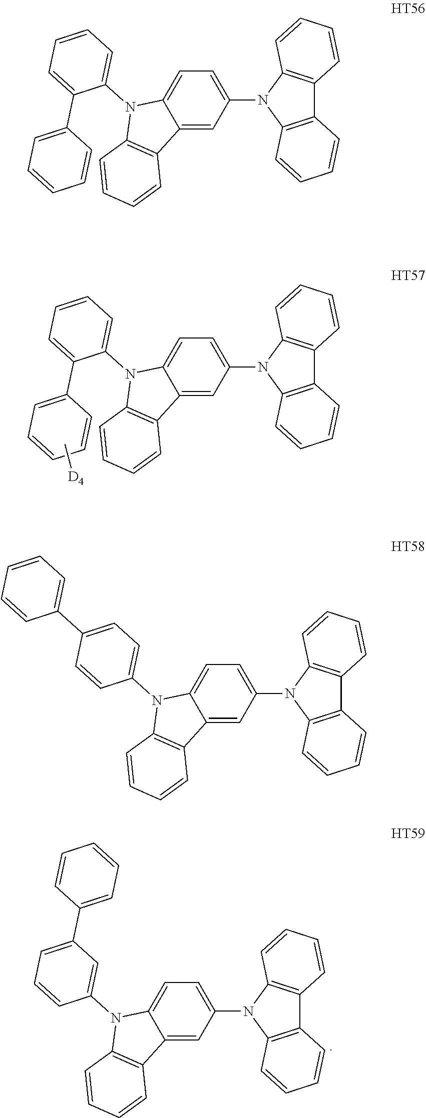

In one or more embodiments, the emission layer EML may include a compound represented by Formula ET. For example, in some embodiments, the compound represented by Formula ET may be utilized as an electron transporting host material of the emission layer EML.

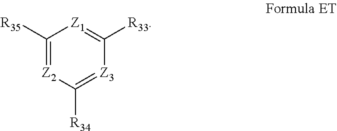

In Formula ET, Z₁ to Z₃ may each independently be N or CR₃₆, and at least one selected from among Z₁ to Z₃ may be N. For example, in some embodiments, Z₁ to Z₃ may all be N. In some embodiments, Z₁ and Z₂ may be N, Z₃ may be CR₃₆; Z₁ may be CR₃₆, Z₂ and Z₃ may be N; or Z₁ and Z₃ may be N, and Z₂ may be CR₃₆. In some embodiments, Z₁ may be N, Z₂ and Z₃ may be CR₃₆, Z₂ may be N, Z₁ and Z₃ may be CR₃₆; or Z₃ may be N, and Z₁ and Z₂ may be CR₃₆.

R₃₃ to R₃₆ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, in some embodiments, R₃₃ to R₃₆ may each independently be a substituted or unsubstituted phenyl group, a substituted or unsubstituted carbazole group, and/or the like, but embodiments of the present disclosure are not limited thereto.

In one or more embodiments, a compound represented by Formula ET may be any one selected from among the compounds of Compound Group ET. The emission layer EML may include at least one selected from among the compounds shown in Compound Group ET, as an electron transporting host material. In Compound Group ET, “D” is deuterium, and “Ph” is a substituted or unsubstituted phenyl group.

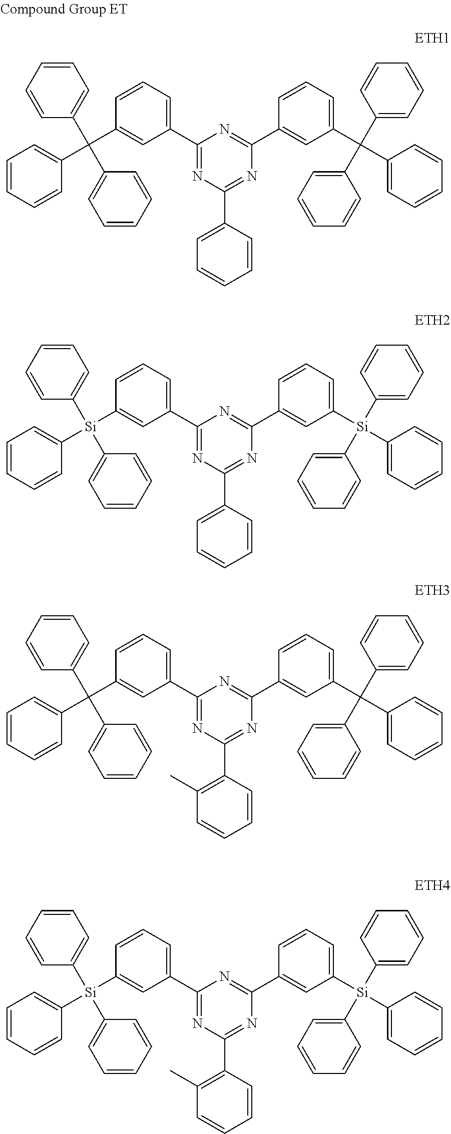 [SMILES: c1ccc(-c2nc(-c3cccc(C(c4ccccc4)(c4ccccc4)c4ccccc4)c3)nc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)nc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)nc(-c2cccc([Si](c3ccccc3)(c3ccccc3)c3ccccc3)c2)n1]

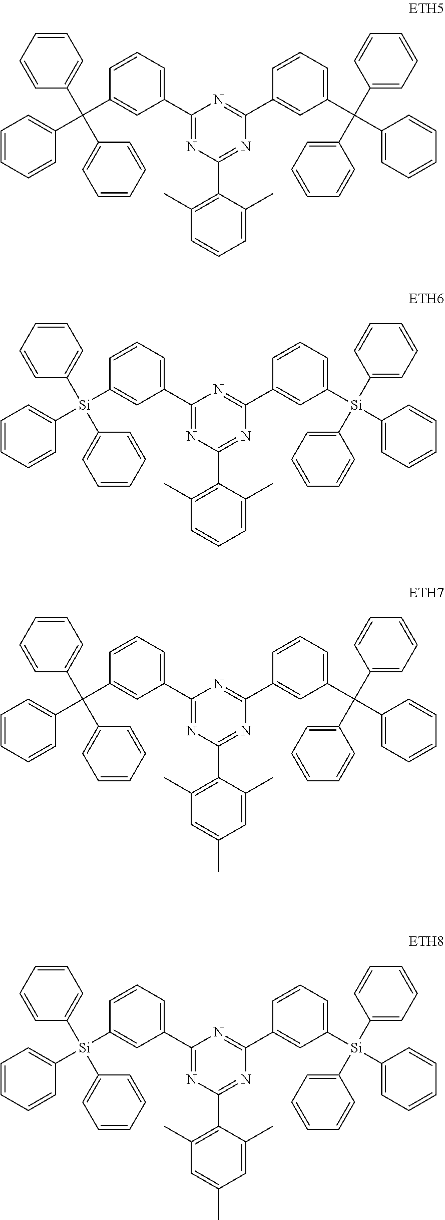 [SMILES: Cc1cccc(C)c1-c1nc(-c2cccc(C(c3ccccc3)(c3ccccc3)c3ccccc3)c2)nc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)nc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)nc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)nc(-c3cccc([Si](c4ccccc4)(c4ccccc4)c4ccccc4)c3)n2)c(C)c1]

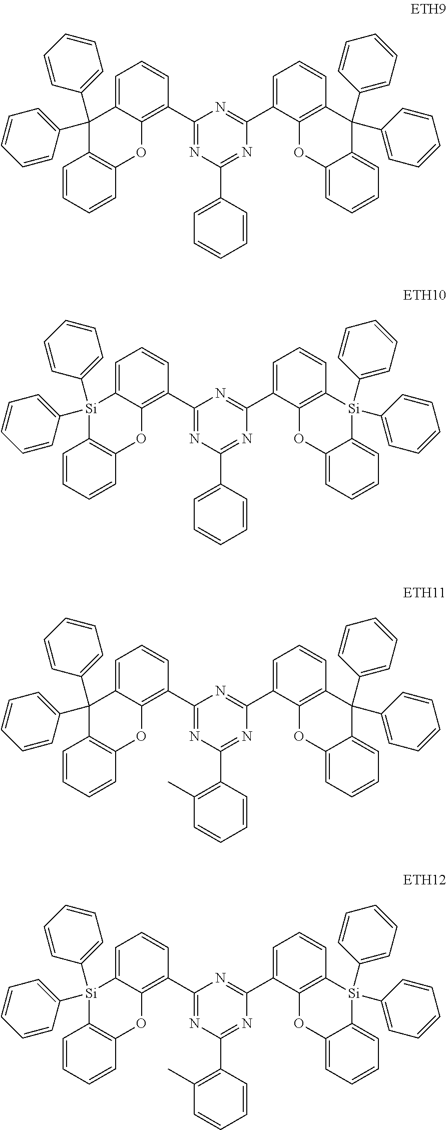 [SMILES: c1ccc(-c2nc(-c3cccc4c3Oc3ccccc3C4(c3ccccc3)c3ccccc3)nc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1]

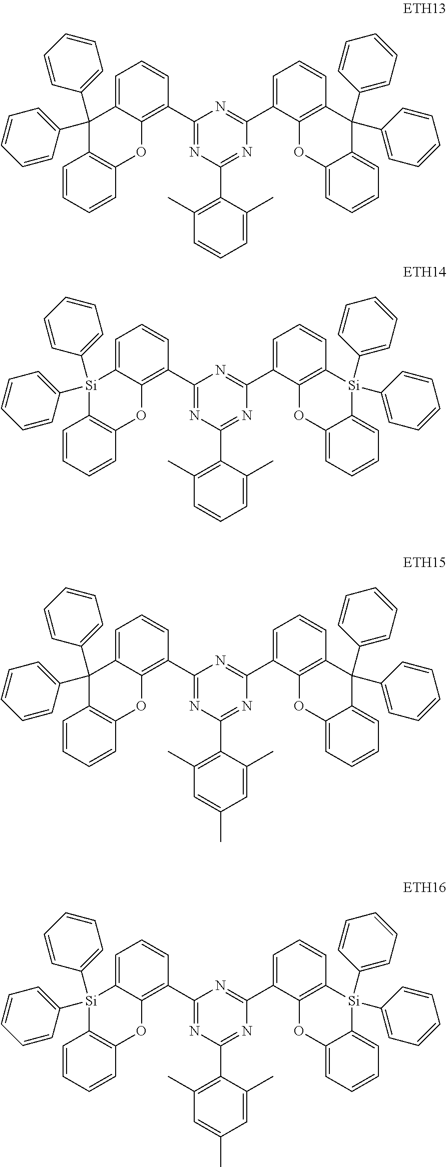 [SMILES: Cc1cccc(C)c1-c1nc(-c2cccc3c2Oc2ccccc2C3(c2ccccc2)c2ccccc2)nc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)nc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)nc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)nc(-c3cccc4c3Oc3ccccc3[Si]4(c3ccccc3)c3ccccc3)n2)c(C)c1]

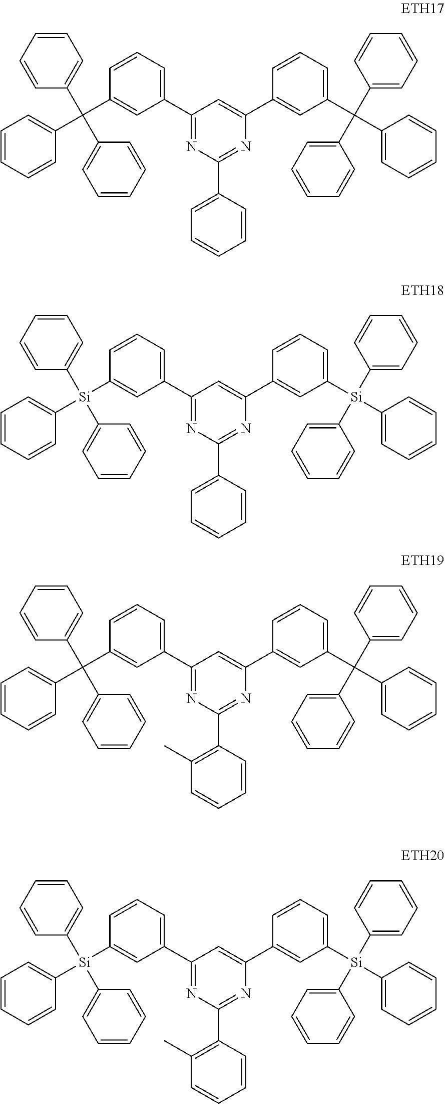 [SMILES: c1ccc(-c2nc(-c3cccc(C(c4ccccc4)(c4ccccc4)c4ccccc4)c3)cc(-c3cccc(C(c4ccccc4)(c4ccccc4)c4ccccc4)c3)n2)cc1 ; c1ccc(-c2nc(-c3cccc([Si](c4ccccc4)(c4ccccc4)c4ccccc4)c3)cc(-c3cccc([Si](c4ccccc4)(c4ccccc4)c4ccccc4)c3)n2)cc1 ; Cc1ccccc1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1ccccc1-c1nc(-c2cccc([Si](c3ccccc3)(c3ccccc3)c3ccccc3)c2)cc(-c2cccc([Si](c3ccccc3)(c3ccccc3)c3ccccc3)c2)n1]

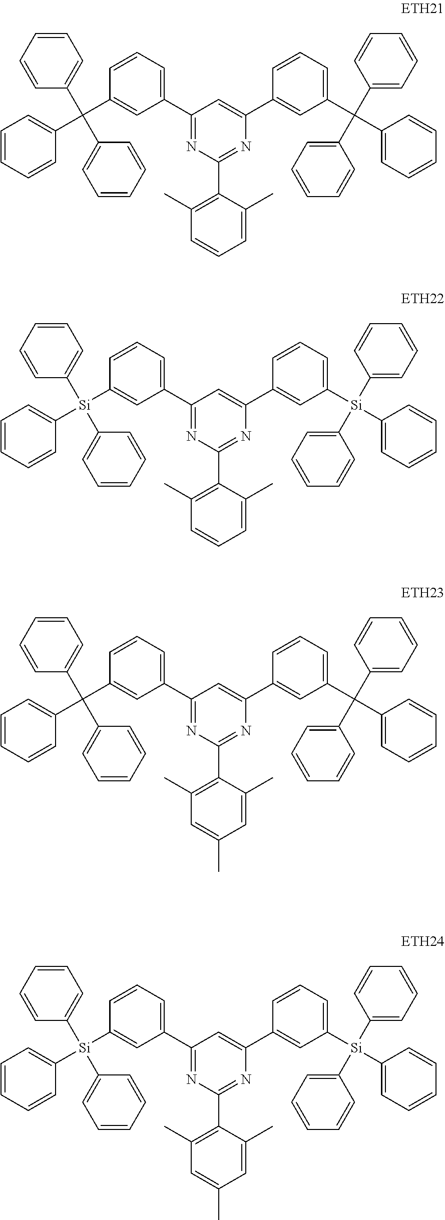 [SMILES: Cc1cccc(C)c1-c1nc(-c2cccc(C(c3ccccc3)(c3ccccc3)c3ccccc3)c2)cc(-c2cccc(C(c3ccccc3)(c3ccccc3)c3ccccc3)c2)n1 ; Cc1cccc(C)c1-c1nc(-c2cccc([Si](c3ccccc3)(c3ccccc3)c3ccccc3)c2)cc(-c2cccc([Si](c3ccccc3)(c3ccccc3)c3ccccc3)c2)n1 ; Cc1cc(C)c(-c2nc(-c3cccc(C(c4ccccc4)(c4ccccc4)c4ccccc4)c3)cc(-c3cccc(C(c4ccccc4)(c4ccccc4)c4ccccc4)c3)n2)c(C)c1 ; Cc1cc(C)c(-c2nc(-c3cccc([Si](c4ccccc4)(c4ccccc4)c4ccccc4)c3)cc(-c3cccc([Si](c4ccccc4)(c4ccccc4)c4ccccc4)c3)n2)c(C)c1]

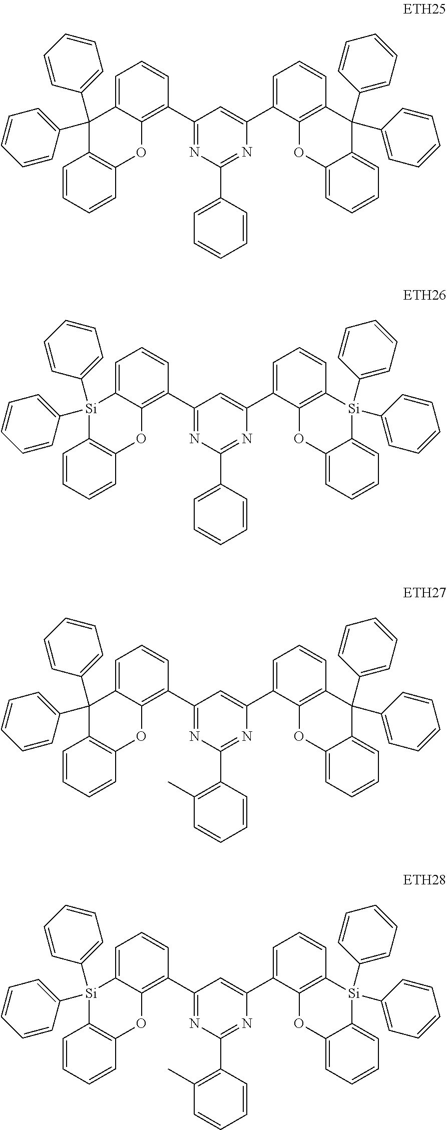 [SMILES: c1ccc(-c2nc(-c3cccc4c3Oc3ccccc3C4(c3ccccc3)c3ccccc3)cc(-c3cccc4c3Oc3ccccc3C4(c3ccccc3)c3ccccc3)n2)cc1 ; c1ccc(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)cc1 ; Cc1ccccc1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1ccccc1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1]

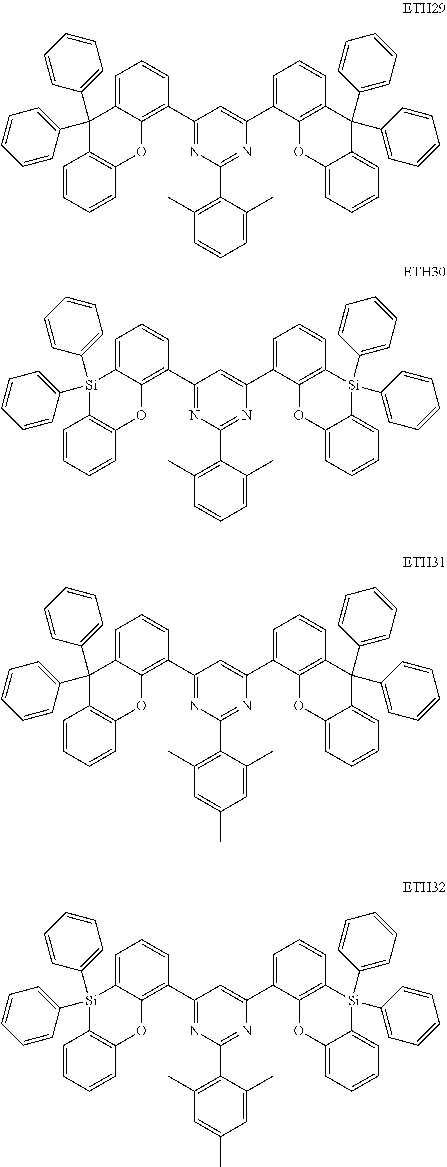 [SMILES: Cc1cccc(C)c1-c1nc(-c2cccc3c2Oc2ccccc2C3(c2ccccc2)c2ccccc2)cc(-c2cccc3c2Oc2ccccc2C3(c2ccccc2)c2ccccc2)n1 ; Cc1cccc(C)c1-c1nc(-c2cccc3c2Oc2ccccc2[Si]3(c2ccccc2)c2ccccc2)cc(-c2cccc3c2Oc2ccccc2[Si]3(c2ccccc2)c2ccccc2)n1 ; Cc1cc(C)c(-c2nc(-c3cccc4c3Oc3ccccc3C4(c3ccccc3)c3ccccc3)cc(-c3cccc4c3Oc3ccccc3C4(c3ccccc3)c3ccccc3)n2)c(C)c1 ; Cc1cc(C)c(-c2nc(-c3cccc4c3Oc3ccccc3[Si]4(c3ccccc3)c3ccccc3)cc(-c3cccc4c3Oc3ccccc3[Si]4(c3ccccc3)c3ccccc3)n2)c(C)c1]

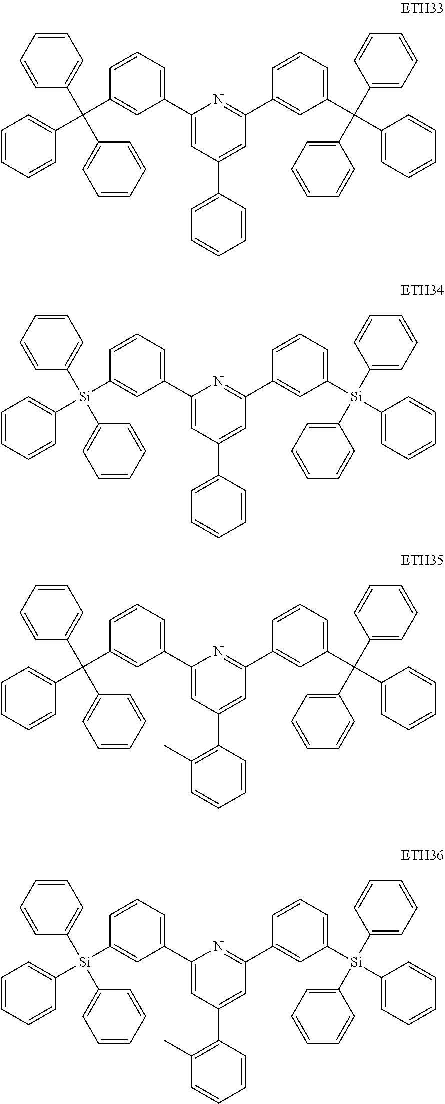 [SMILES: c1ccc(-c2cc(-c3cccc(C(c4ccccc4)(c4ccccc4)c4ccccc4)c3)nc(-c3cccc(C(c4ccccc4)(c4ccccc4)c4ccccc4)c3)c2)cc1 ; c1ccc(-c2cc(-c3cccc([Si](c4ccccc4)(c4ccccc4)c4ccccc4)c3)nc(-c3cccc([Si](c4ccccc4)(c4ccccc4)c4ccccc4)c3)c2)cc1 ; Cc1ccccc1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1ccccc1-c1cc(-c2cccc([Si](c3ccccc3)(c3ccccc3)c3ccccc3)c2)nc(-c2cccc([Si](c3ccccc3)(c3ccccc3)c3ccccc3)c2)c1]

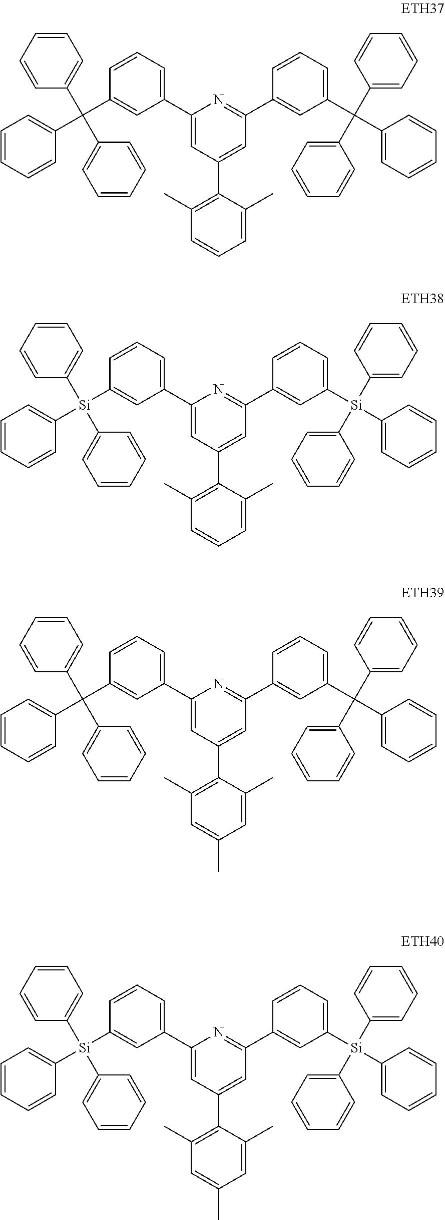 [SMILES: Cc1cccc(C)c1-c1cc(-c2cccc(C(c3ccccc3)(c3ccccc3)c3ccccc3)c2)nc(-c2cccc(C(c3ccccc3)(c3ccccc3)c3ccccc3)c2)c1 ; Cc1cccc(C)c1-c1cc(-c2cccc([Si](c3ccccc3)(c3ccccc3)c3ccccc3)c2)nc(-c2cccc([Si](c3ccccc3)(c3ccccc3)c3ccccc3)c2)c1 ; Cc1cc(C)c(-c2cc(-c3cccc(C(c4ccccc4)(c4ccccc4)c4ccccc4)c3)nc(-c3cccc(C(c4ccccc4)(c4ccccc4)c4ccccc4)c3)c2)c(C)c1 ; Cc1cc(C)c(-c2cc(-c3cccc([Si](c4ccccc4)(c4ccccc4)c4ccccc4)c3)nc(-c3cccc([Si](c4ccccc4)(c4ccccc4)c4ccccc4)c3)c2)c(C)c1]

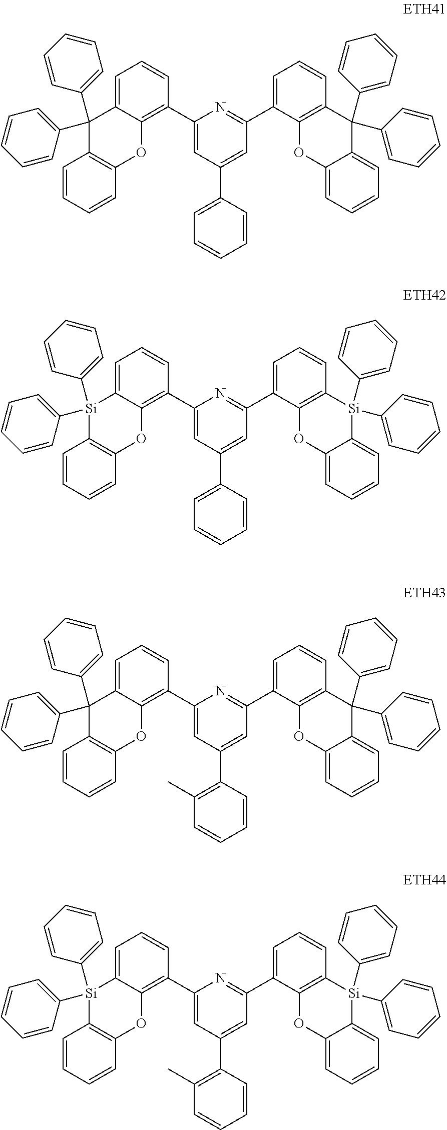 [SMILES: c1ccc(-c2cc(-c3cccc4c3Oc3ccccc3C4(c3ccccc3)c3ccccc3)nc(-c3cccc4c3Oc3ccccc3C4(c3ccccc3)c3ccccc3)c2)cc1 ; c1ccc(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)cc1 ; Cc1ccccc1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1ccccc1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1]

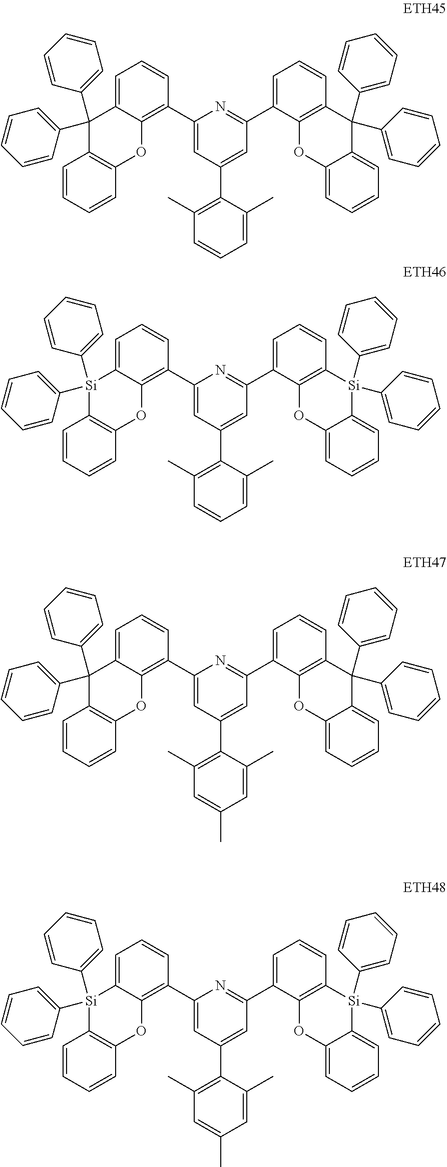 [SMILES: Cc1cccc(C)c1-c1cc(-c2cccc3c2Oc2ccccc2C3(c2ccccc2)c2ccccc2)nc(-c2cccc3c2Oc2ccccc2C3(c2ccccc2)c2ccccc2)c1 ; Cc1cccc(C)c1-c1cc(-c2cccc3c2Oc2ccccc2[Si]3(c2ccccc2)c2ccccc2)nc(-c2cccc3c2Oc2ccccc2[Si]3(c2ccccc2)c2ccccc2)c1 ; Cc1cc(C)c(-c2cc(-c3cccc4c3Oc3ccccc3C4(c3ccccc3)c3ccccc3)nc(-c3cccc4c3Oc3ccccc3C4(c3ccccc3)c3ccccc3)c2)c(C)c1 ; Cc1cc(C)c(-c2cc(-c3cccc4c3Oc3ccccc3[Si]4(c3ccccc3)c3ccccc3)nc(-c3cccc4c3Oc3ccccc3[Si]4(c3ccccc3)c3ccccc3)c2)c(C)c1]

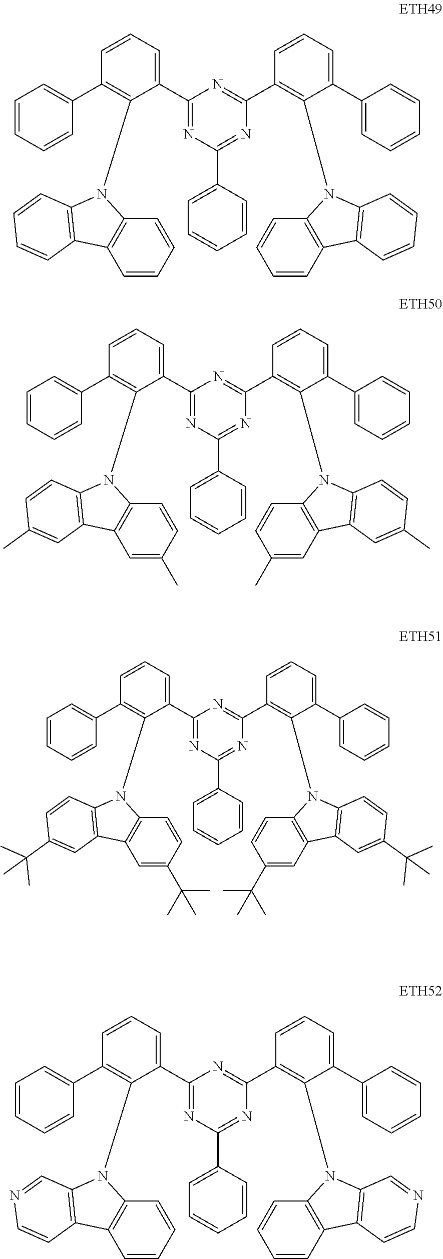

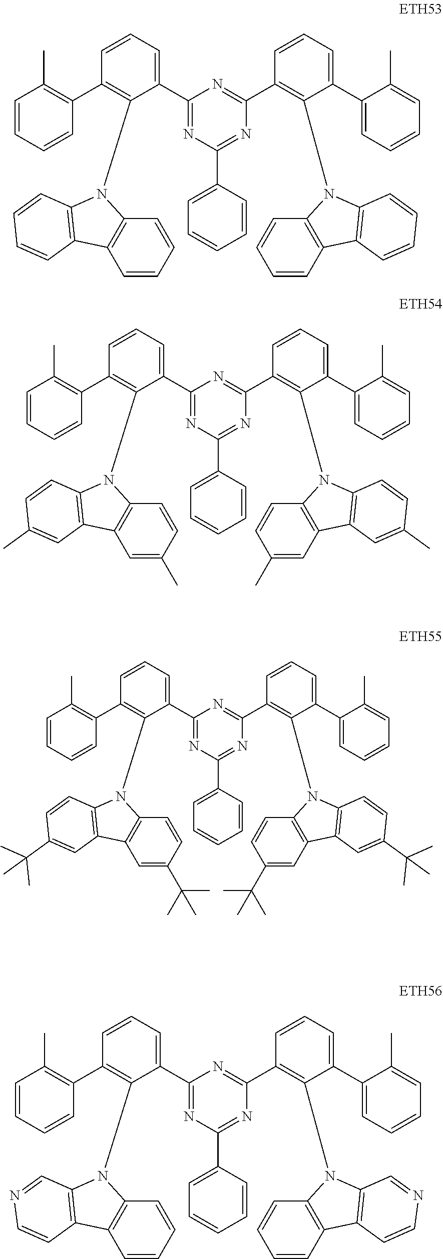

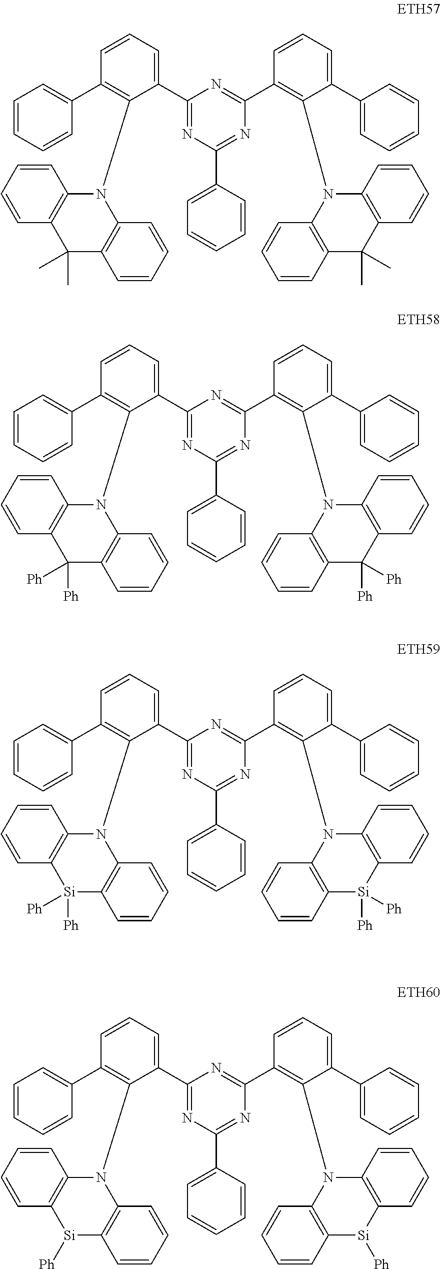

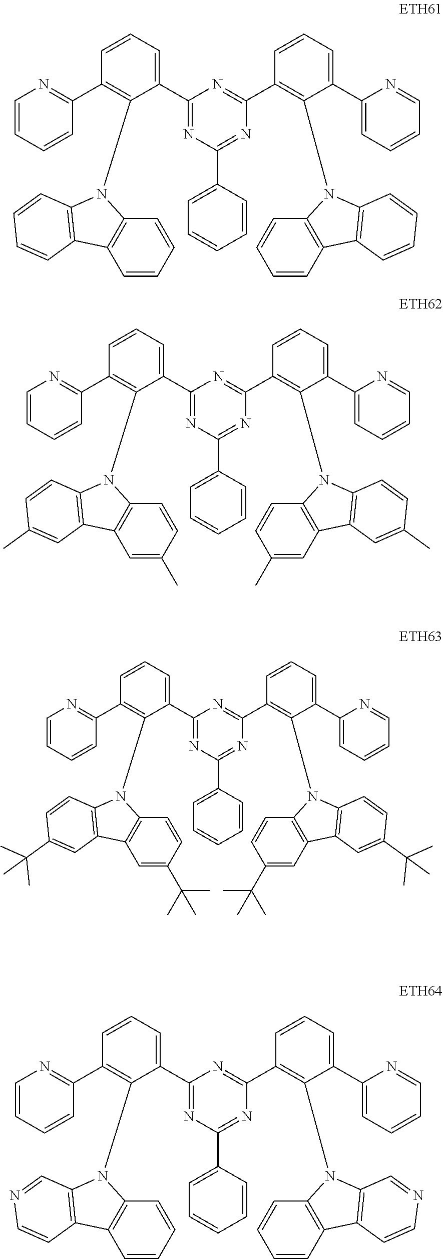

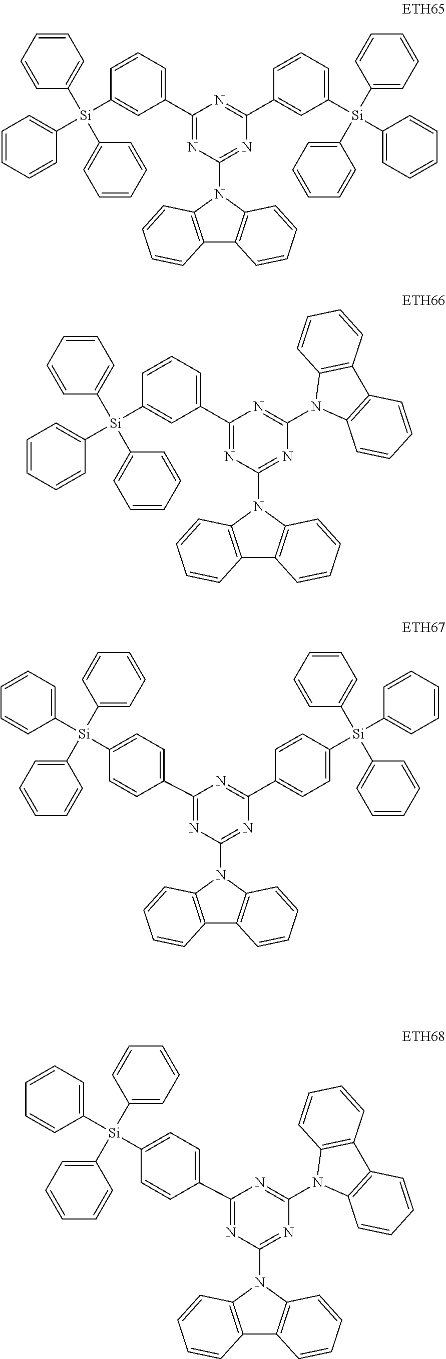 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5ccccc54)n3)c2)cc1 ; c1ccc([Si](c2ccccc2)(c2ccccc2)c2cccc(-c3nc(-n4c5ccccc5c5ccccc54)nc(-n4c5ccccc5c5ccccc54)n3)c2)cc1 ; c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5ccccc54)n3)cc2)cc1 ; c1ccc([Si](c2ccccc2)(c2ccccc2)c2ccc(-c3nc(-n4c5ccccc5c5ccccc54)nc(-n4c5ccccc5c5ccccc54)n3)cc2)cc1]

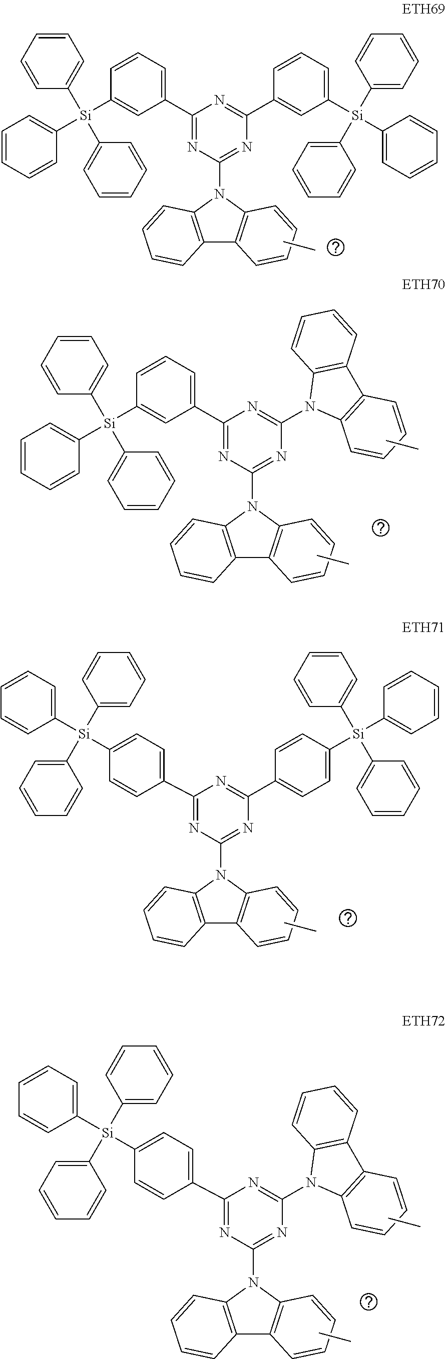

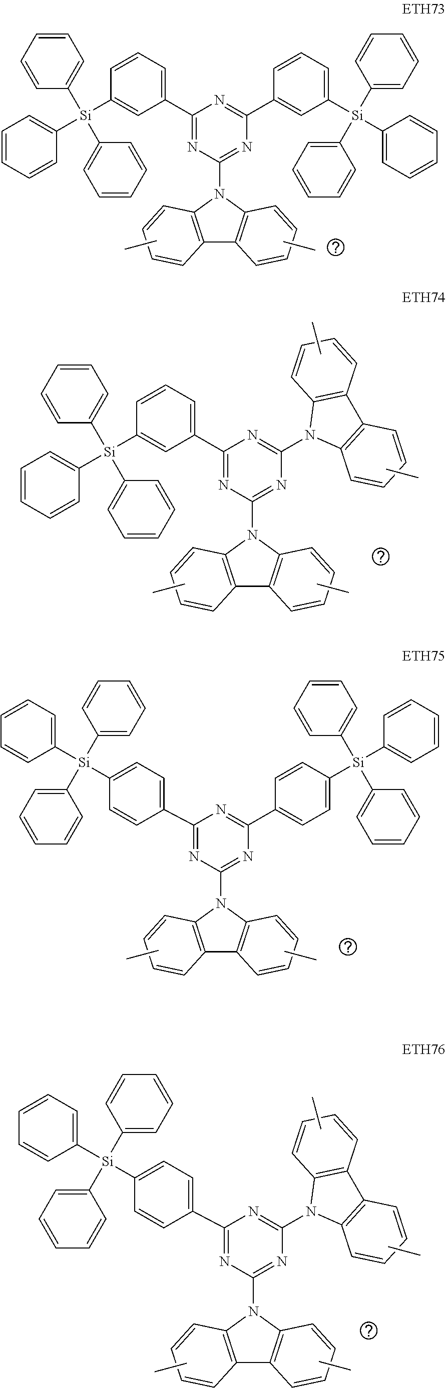

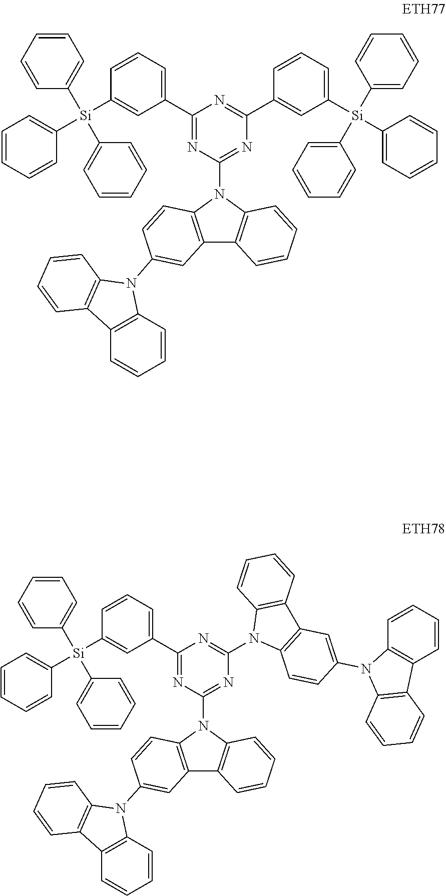 [SMILES: c1ccc([Si](c2ccccc2)(c2ccccc2)c2cccc(-c3nc(-c4cccc([Si](c5ccccc5)(c5ccccc5)c5ccccc5)c4)nc(-n4c5ccccc5c5cc(-n6c7ccccc7c7ccccc76)ccc54)n3)c2)cc1 ; c1ccc([Si](c2ccccc2)(c2ccccc2)c2cccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)c2)cc1]

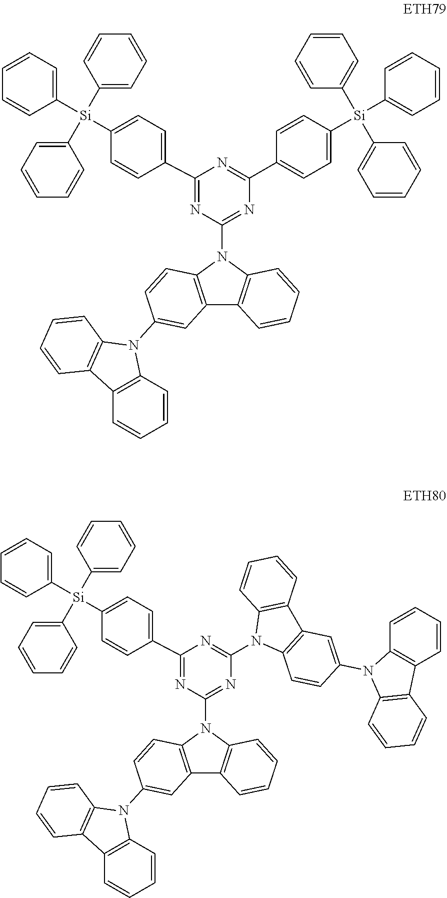 [SMILES: c1ccc([Si](c2ccccc2)(c2ccccc2)c2ccc(-c3nc(-c4ccc([Si](c5ccccc5)(c5ccccc5)c5ccccc5)cc4)nc(-n4c5ccccc5c5cc(-n6c7ccccc7c7ccccc76)ccc54)n3)cc2)cc1 ; c1ccc([Si](c2ccccc2)(c2ccccc2)c2ccc(-c3nc(-n4c5ccccc5c5cc(-n6c7ccccc7c7ccccc76)ccc54)nc(-n4c5ccccc5c5cc(-n6c7ccccc7c7ccccc76)ccc54)n3)cc2)cc1]

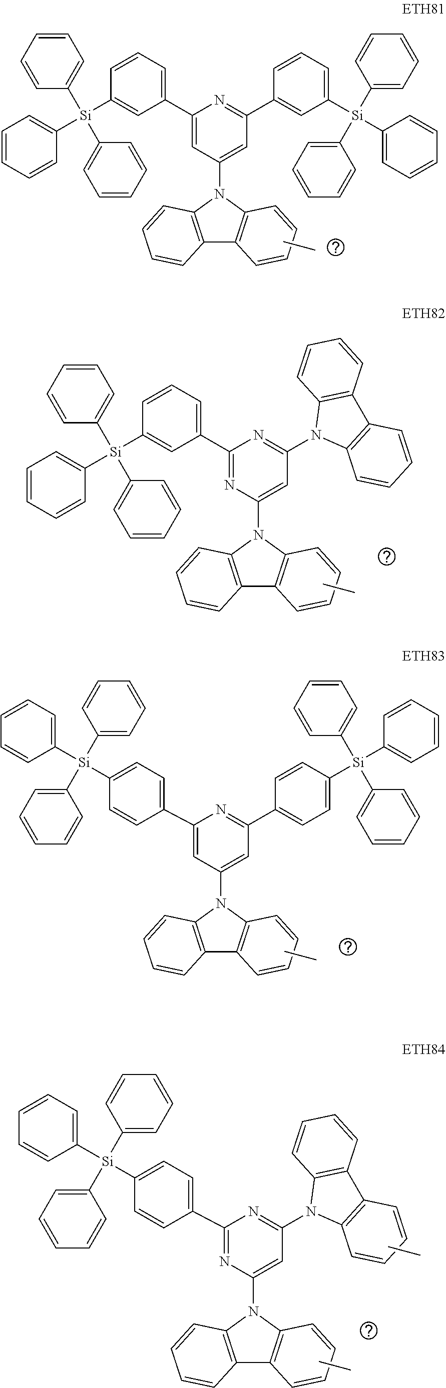

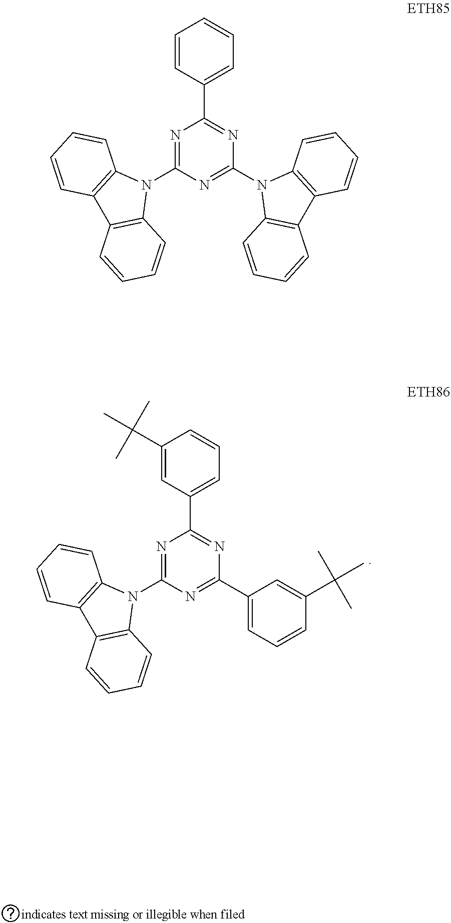 [SMILES: c1ccc(-c2nc(-n3c4ccccc4c4ccccc43)nc(-n3c4ccccc4c4ccccc43)n2)cc1 ; CC(C)(C)c1cccc(-c2nc(-c3cccc(C(C)(C)C)c3)nc(-n3c4ccccc4c4ccccc43)n2)c1]

In one or more embodiments, the emission layer EML may include a compound represented by Formula E-2a or Formula E-2b. The compound represented by Formula E-2a or Formula E-2b may be utilized as a phosphorescent host material.

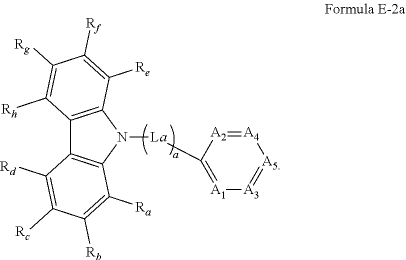

In Formula E-2a, a may be an integer of 0 to 10, and Lₐ may be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a is an integer of 2 or greater, a plurality of Lₐ's may each independently be a substituted or unsubstituted arylene group having 6 to 30 ring-forming carbon atoms, or a substituted or unsubstituted heteroarylene group having 2 to 30 ring-forming carbon atoms.

In some embodiments, in Formula E-2a, A₁ to A₅ may each independently be N or CRᵢ. Rₐ to Rᵢ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. Rₐ to Rᵢ may be bonded to an adjacent group to form a hydrocarbon ring or a heterocycle containing N, O, S, etc. as a ring-forming atom.

In some embodiments, in Formula E-2a, two or three selected from among A₁ to A₅ may be N, and the rest may be CRᵢ.

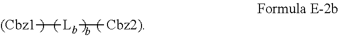

In Formula E-2b, Cbz1 and Cbz2 may each independently be an unsubstituted carbazole group or an aryl-substituted carbazole group having 6 to 30 ring-forming carbon atoms. L_{b} may be a direct linkage, a substituted or unsubstituted arylene group having 6 to 30 ring-forming carbon atoms, or a substituted or unsubstituted heteroarylene group having 2 to 30 ring-forming carbon atoms, b may be an integer of 0 to 10, and when b is an integer of 2 or greater, a plurality of L_{b}'s may each independently be a substituted or unsubstituted arylene group having 6 to 30 ring-forming carbon atoms, or a substituted or unsubstituted heteroarylene group having 2 to 30 ring-forming carbon atoms.

The compound represented by Formula E-2a or Formula E-2b may be represented by any one selected from among compounds in Compound Group E-2. However, the compounds listed in Compound Group E-2 are presented as a mere example, and the compound represented by Formula E-2a or Formula E-2b is not limited to those listed in Compound Group E-2.

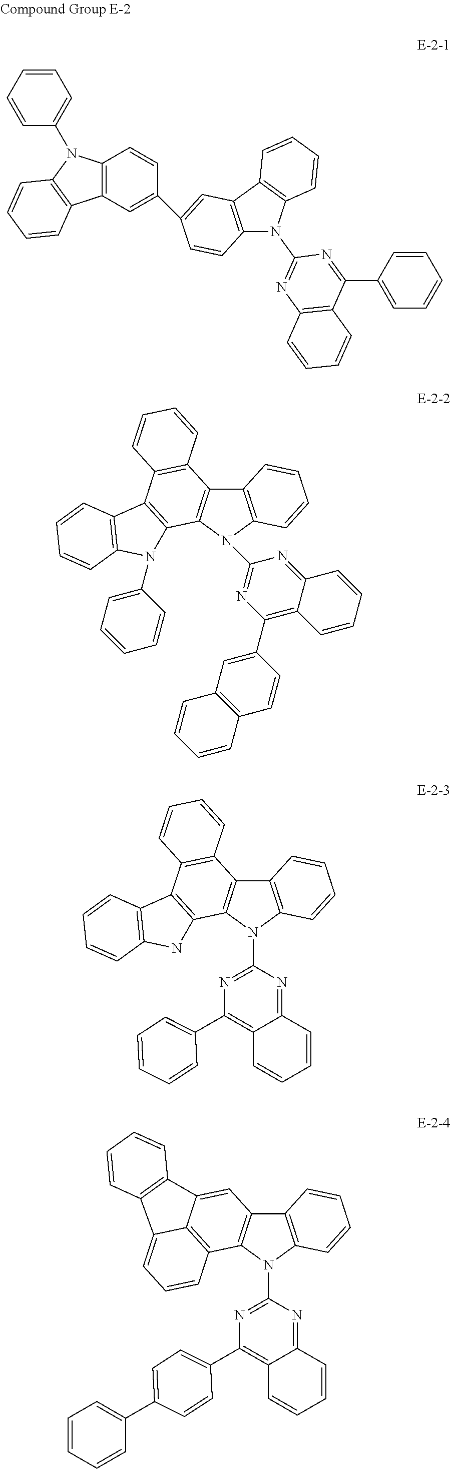

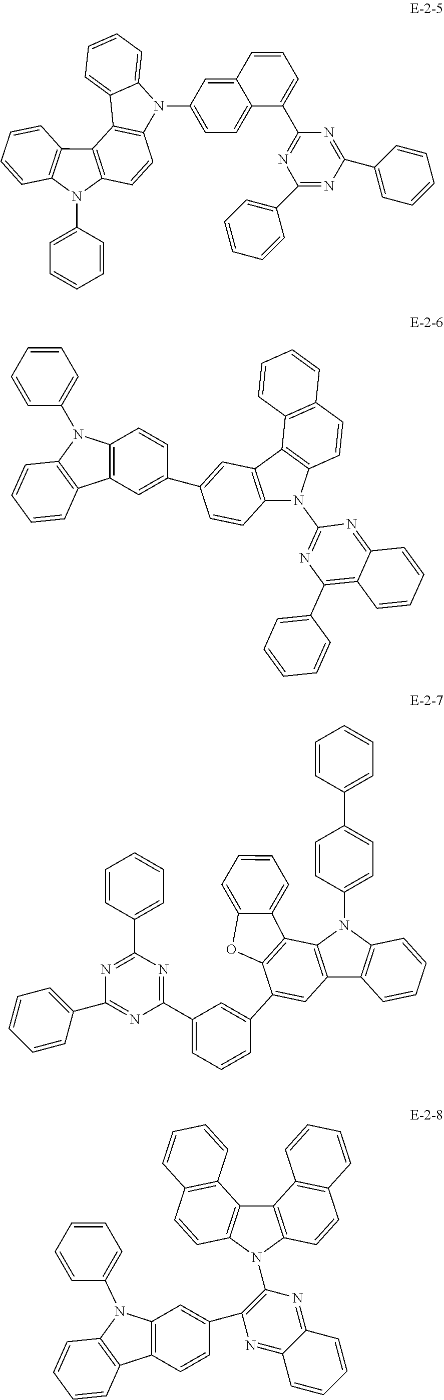 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

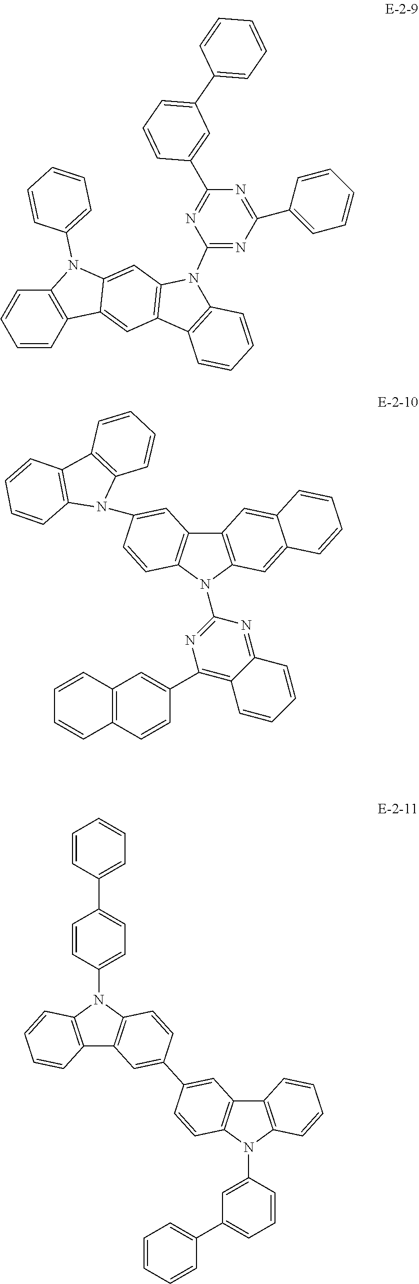 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

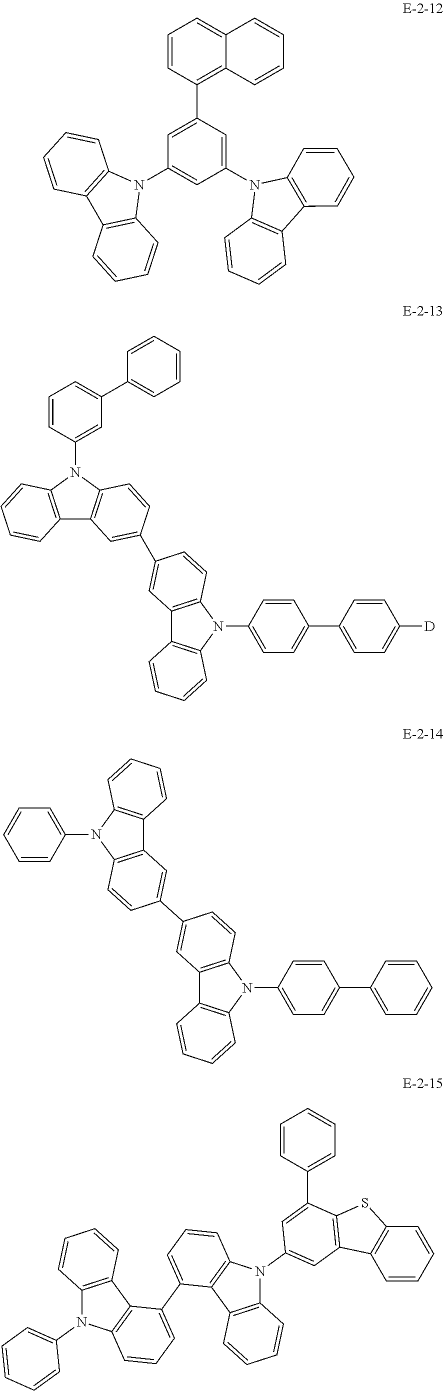 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

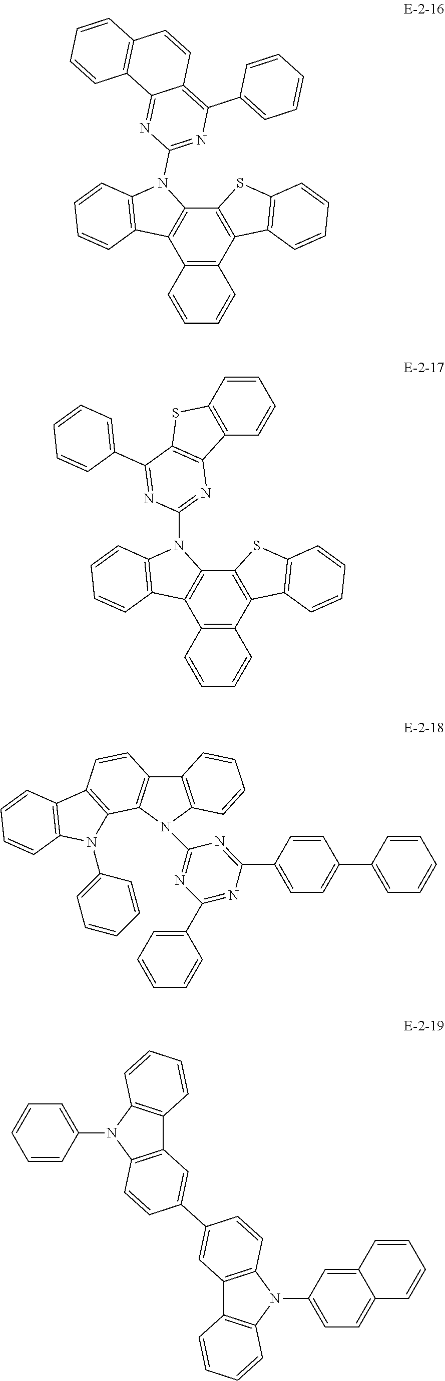 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

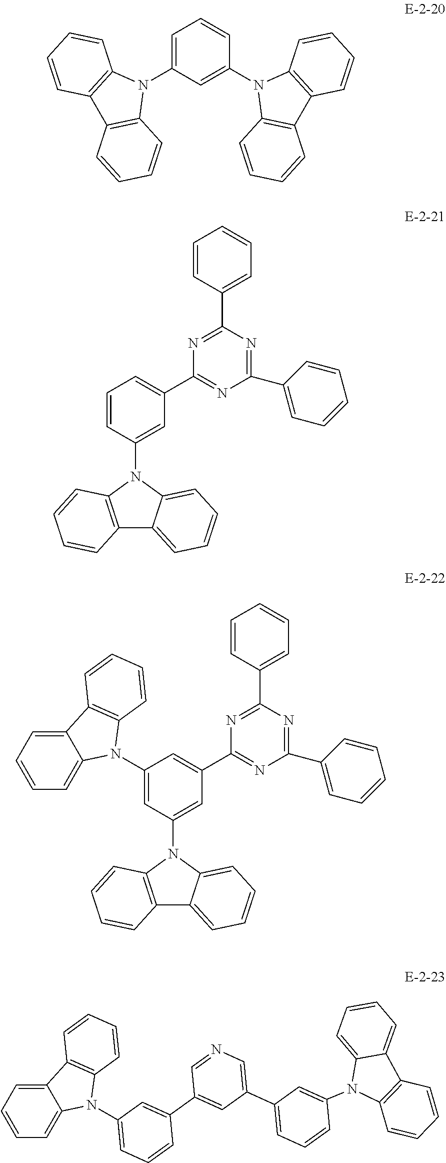 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

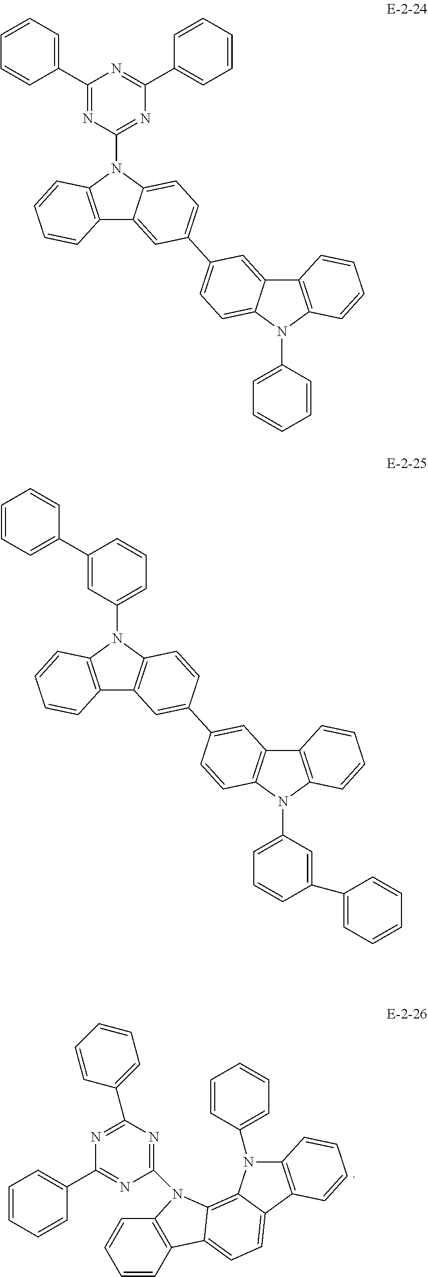 [SMILES: c1ccc(-c2nc(-c3ccccc3)nc(-n3c4ccccc4c4cc(-c5ccc6c(c5)c5ccccc5n6-c5ccccc5)ccc43)n2)cc1 ; c1ccc(-c2cccc(-n3c4ccccc4c4cc(-c5ccc6c(c5)c5ccccc5n6-c5cccc(-c6ccccc6)c5)ccc43)c2)cc1 ; c1ccc(-c2nc(-c3ccccc3)nc(-n3c4ccccc4c4ccc5c6ccccc6n(-c6ccccc6)c5c43)n2)cc1]

In one or more embodiments, the emission layer EML may further include a general material suitable in the art as a host material. For example, in some embodiments, the emission layer EML may include, as a host material, at least one selected from among bis(4-(9H-carbazol-9-yl)phenyl)diphenylsilane (BCPDS), (4-(1-(4-(diphenylamino)phenyl)cyclohexyl)phenyl)diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazolyl-9-yl)benzene (mCP), 2,8-bis(diphenylphosphoryl)dibenzofuran (PPF), 4,4′,4″-tris(carbazol-9-yl)-triphenylamine (TCTA), and 1,3,5-tris(1-phenyl-1H-benzo[d]imidazol-2-yl)benzene (TPBi). However, embodiments of the present disclosure are not limited thereto, and for example, tris(8-hydroxyquinolino)aluminum (Alq₃), 9,10-di(naphthalene-2-yl)anthracene (ADN), 3-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetrasiloxane (DPSiO₄), etc. may be utilized as a host material.

In one or more embodiments, the emission layer EML may include a compound represented by Formula M-a. The compound represented by Formula M-a may be utilized as a phosphorescent dopant material.

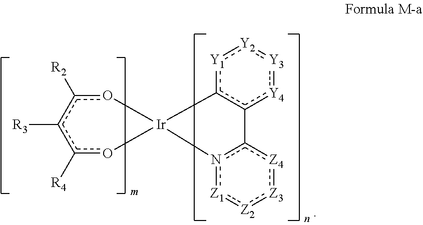

In Formula M-a, Y₁ to Y₄, and Z₁ to Z₄ may each independently be CR₁ or N, and R₁ to R₄ may each independently be hydrogen, deuterium, a substituted or unsubstituted amine group, a substituted or unsubstituted thio group, a substituted or unsubstituted oxy group, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring. In Formula M-a, m is 0 or 1, and n is 2 or 3. In Formula M-a, when m is 0, n is 3, and when m is 1, n is 2.

The compound represented by Formula M-a may be represented by any one selected from among compounds M-a1 to M-a25. However, the compounds M-a1 to M-a25 are presented as a mere example, and the compound represented by Formula M-a is not limited to those represented by the compounds M-a1 to M-a25.

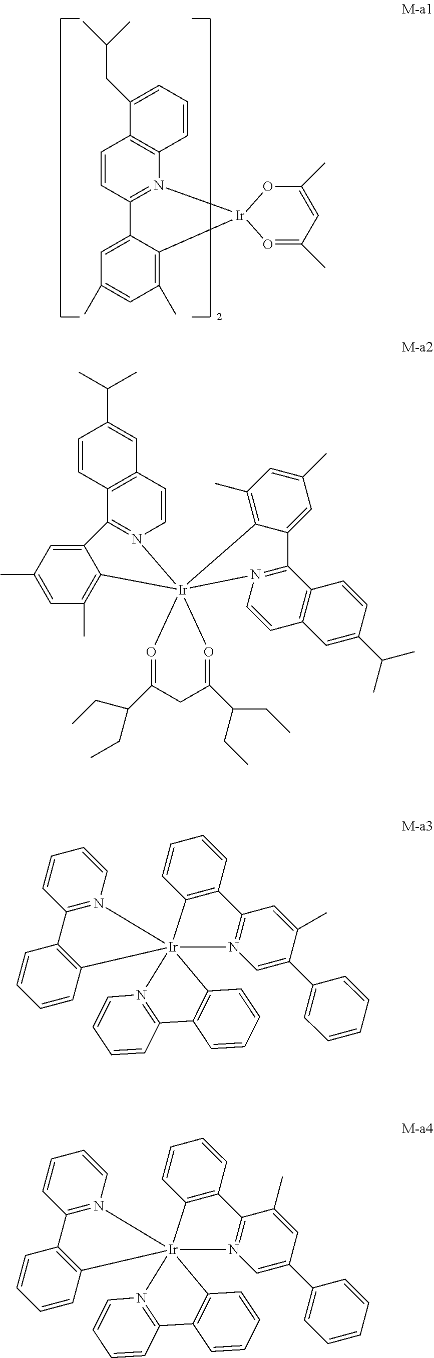

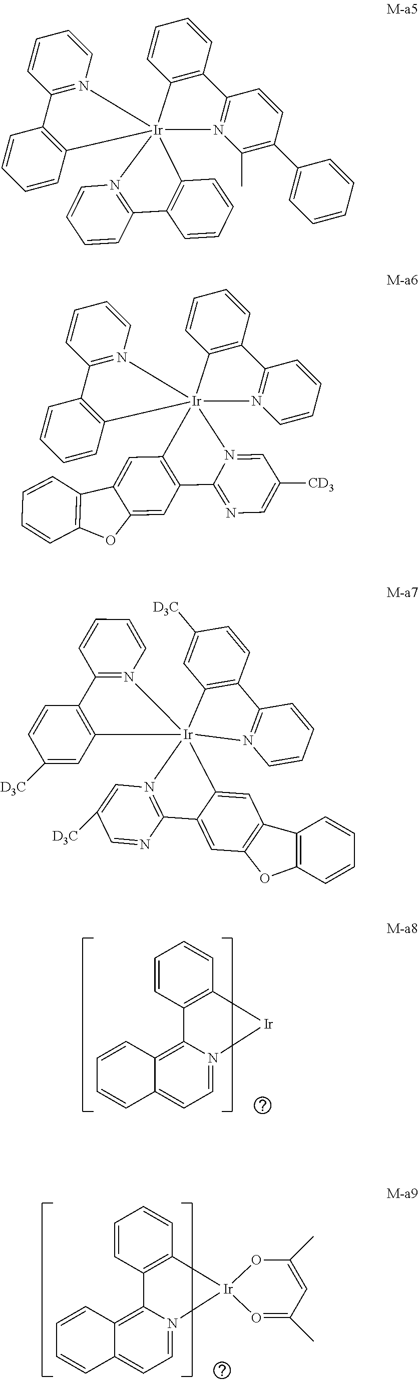

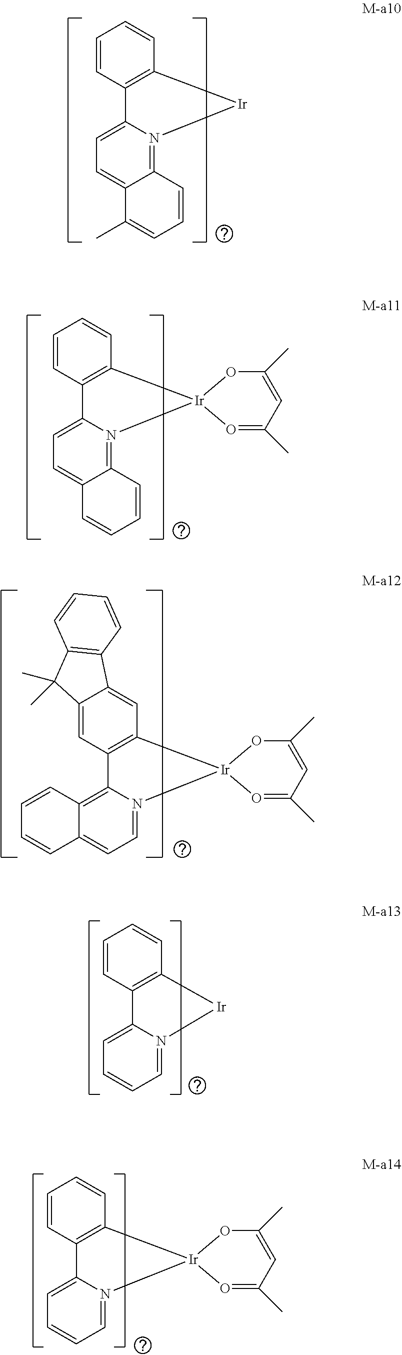

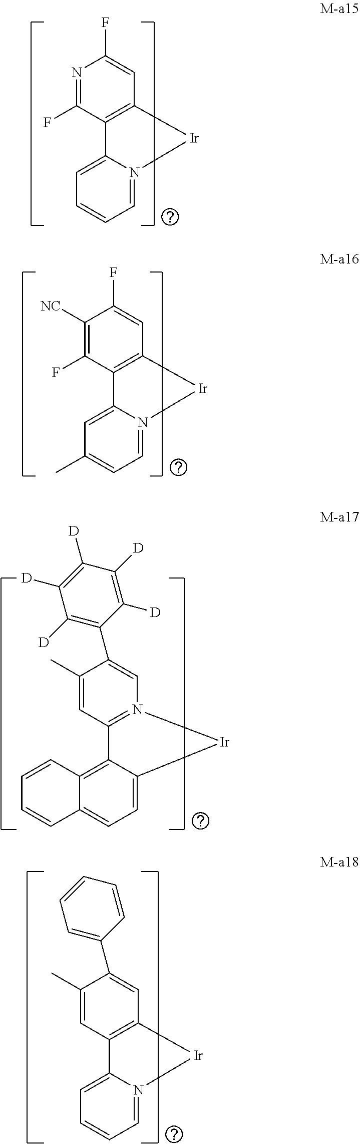

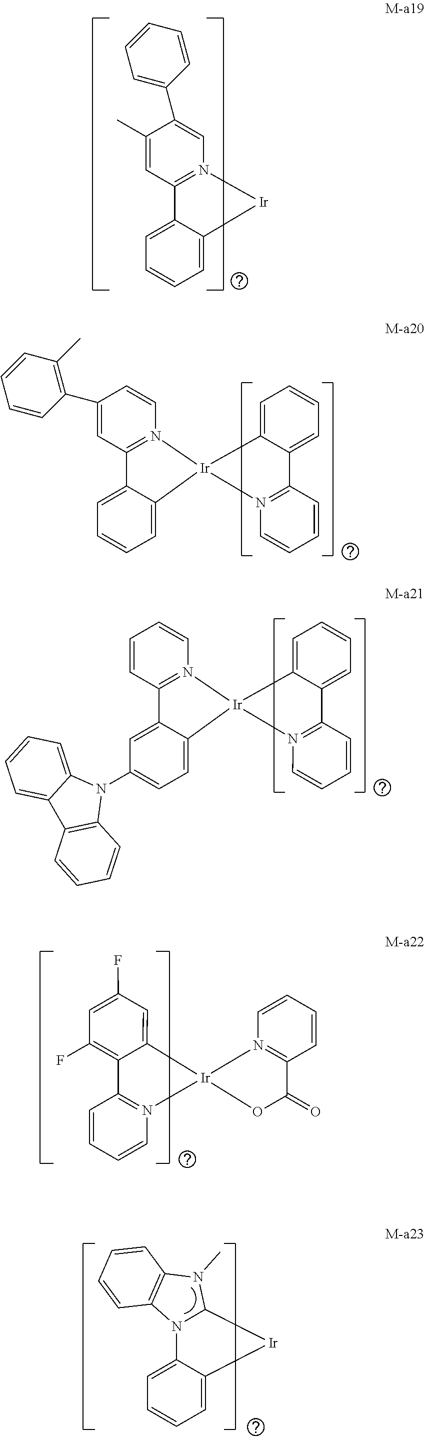

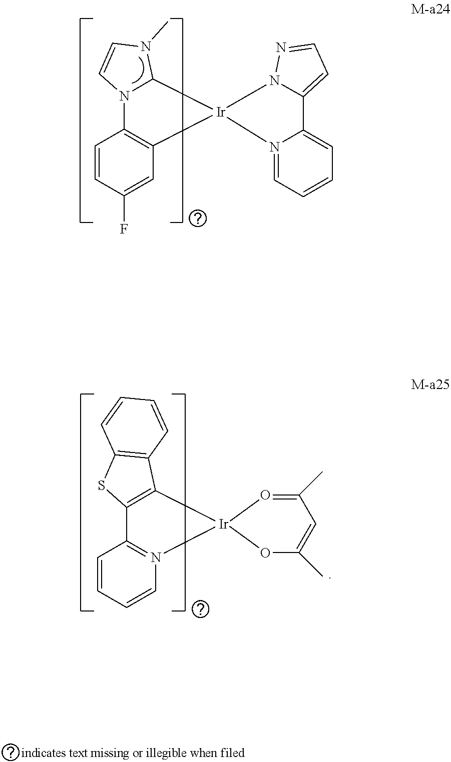

In one or more embodiments, the emission layer EML may include an organometallic complex containing platinum (Pt) as a central metal atom and ligands bound to the central metal atom.

In one or more embodiments, the emission layer EML may include a compound represented by Formula AD. The compound represented by Formula AD may be utilized as a dopant of the emission layer EML.

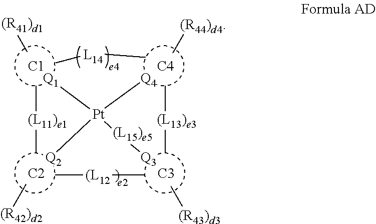

In Formula AD above, Q₁ to Q₄ may each independently be C or N.

C1 to C4 may each independently be a substituted or unsubstituted aromatic hydrocarbon ring having 5 to 30 ring-forming carbon atoms, or a substituted or unsubstituted aromatic heterocycle having 2 to 30 ring-forming carbon atoms.

L₁₁ to L₁₄ may each independently be a direct linkage,

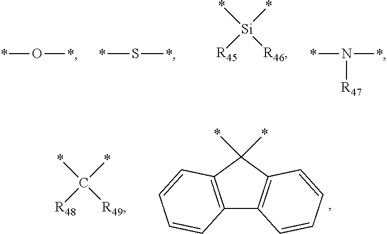

a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “ [symbol] ” may be a site connected to C1 to C4.

L₁₅ may be a direct linkage or *—O—*, and in L₁₅, “ [symbol] ” may be a site connected to Pt and C3,

e1 to e5 may each independently be 0 or 1. When e1 is 0, C1 and C2 may not be connected. When e2 is 0, C2 and C3 may not be connected. When e3 is 0, C3 and C4 may not be connected. When e4 is 0, C1 and C4 may not be connected. In some embodiments, when e5 is 0, the embodiment may be understood in substantially the same manner as when L₁₅ is a direct linkage.

R₄₁ to R₄₉ may each independently be hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring. For example, in some embodiments, R₄₁ to R₄₉ may each independently be a substituted or unsubstituted methyl group, a substituted or unsubstituted t-butyl group, or a substituted or unsubstituted phenyl group.

d1 to d4 may each independently be an integer of 0 to 4. When d1 to d4 are each 0, the compound represented by Formula AD according to one or more embodiments may not be substituted with R₄₁ to R₄₉. When d1 to d4 are each 4, and R₄₁ to R₄₉ are each hydrogen, the embodiment may be the same as when d1 to d4 are each 0. When d1 to d4 are each 2 or greater, the substituents in the parentheses may be the same or different.

In some embodiments, C1 to C4 may each independently be an aromatic substituted or unsubstituted hydrocarbon ring or a substituted or unsubstituted aromatic heterocycle, which is represented by any one selected from among C-1 to C-4.

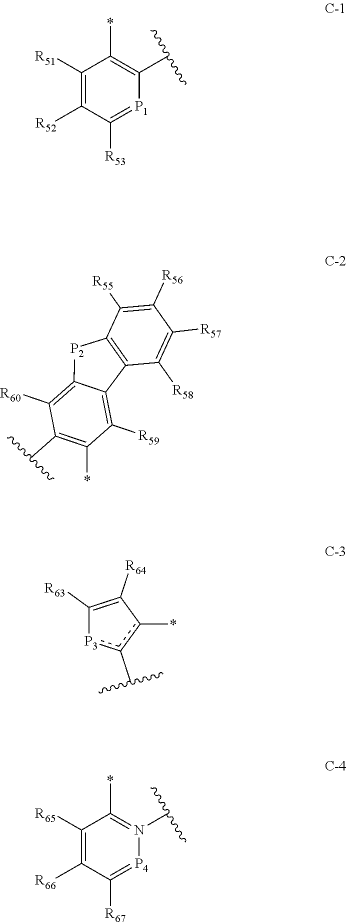

In C-1 to C-4, P₁ may be C—* or CR₅₄, P₂ may be N—* or NR₆₁, P₃ may be N—* or NR₆₂, and P₄ may be C—* or CR₆₈. R₅₁ to R₆₈ may each independently be a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In C-1 to C-4, “

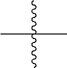

” indicates a portion connected to the central metal atom, Pt, and “ [symbol] ” indicates a portion connected to neighboring ring groups (C1 to C4) or linkers (L₁₁ to L₁₄).

In one or more embodiments, the compound represented by Formula AD may be any one selected from among the compounds of Compound Group AD. However, the compounds listed in Compound Group AD are presented as a mere example, and embodiments of the present disclosure are not limited thereto.

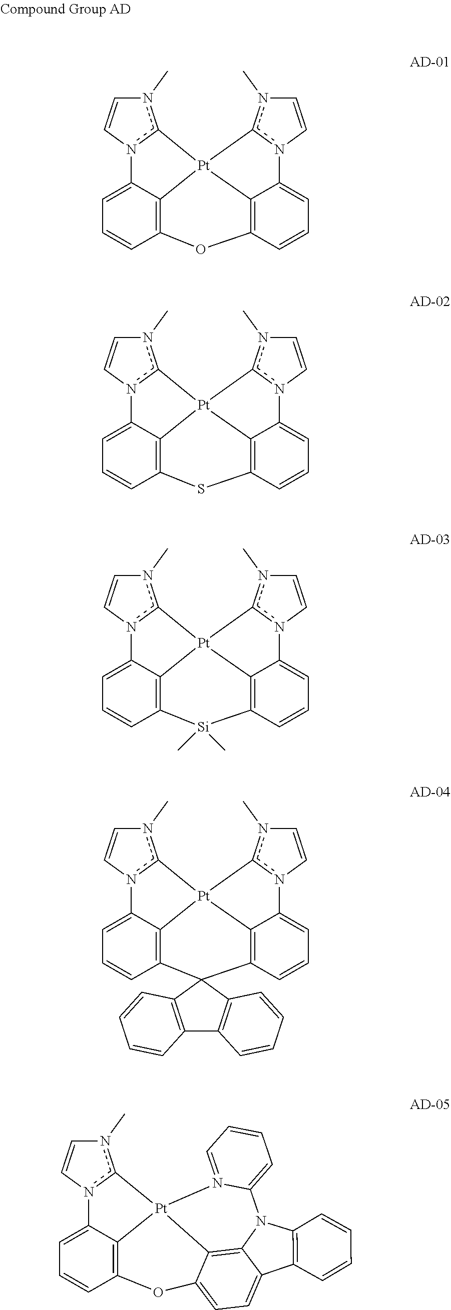

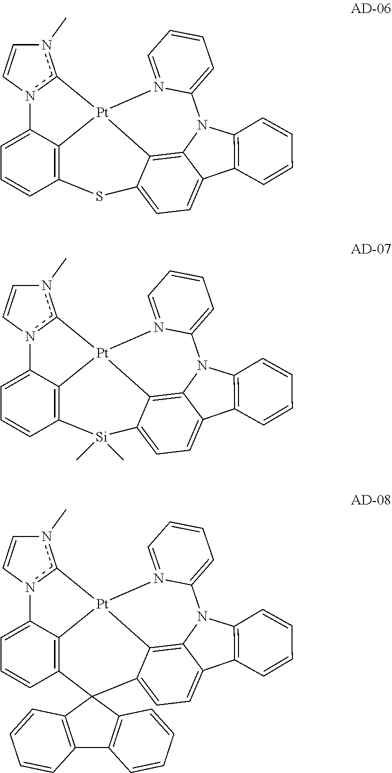

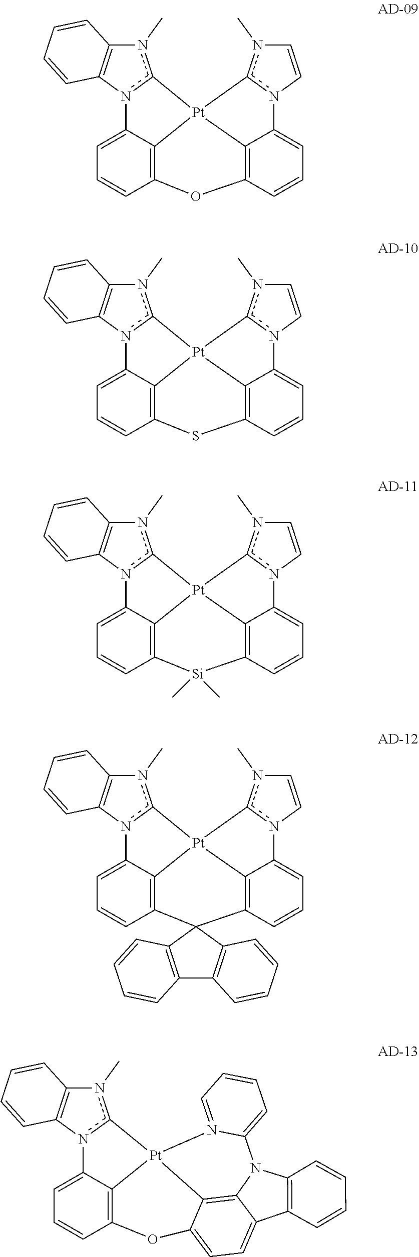

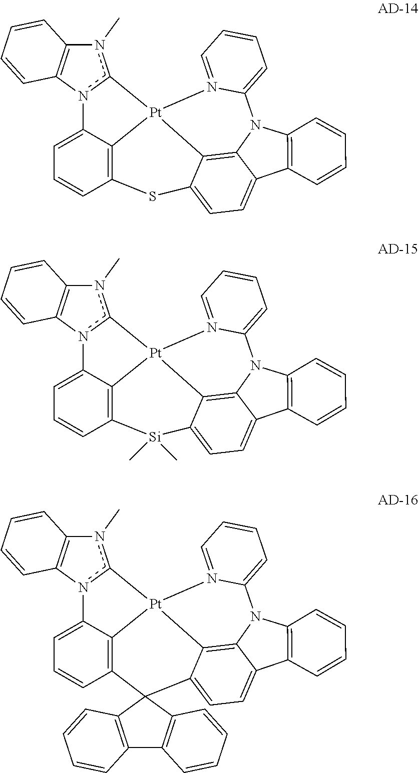

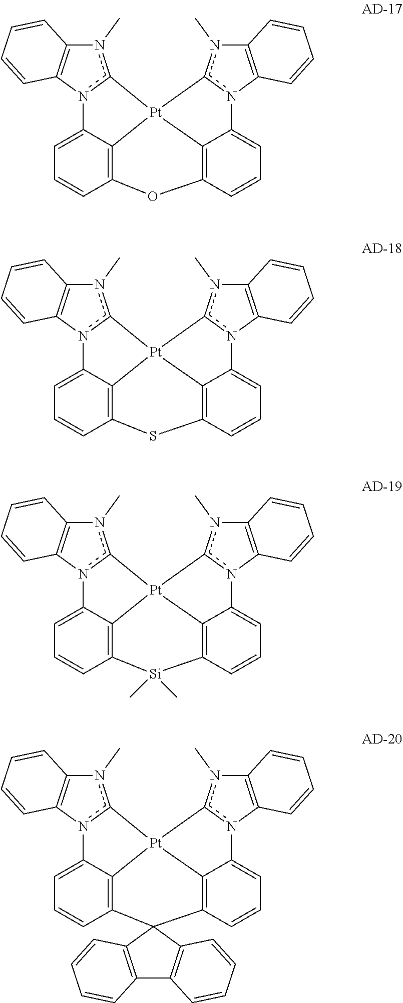

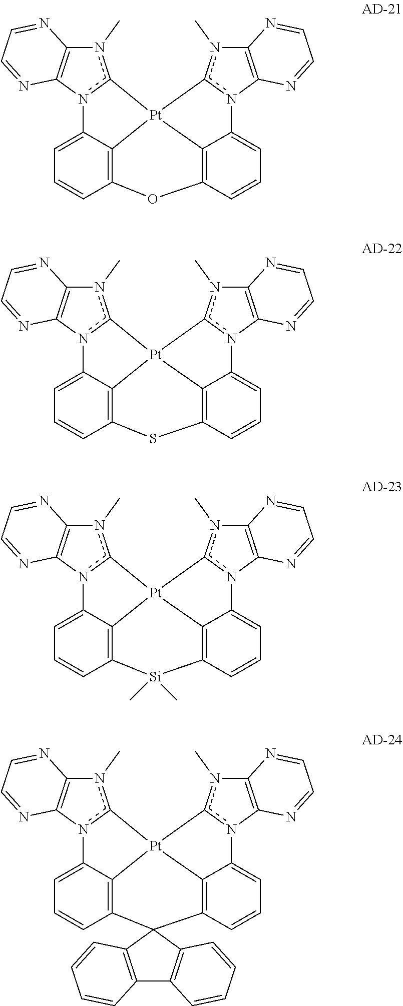

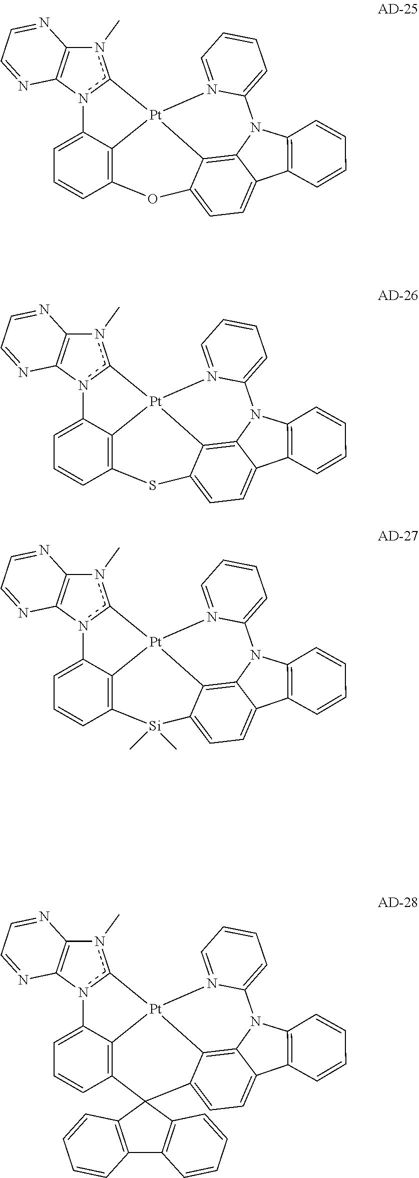

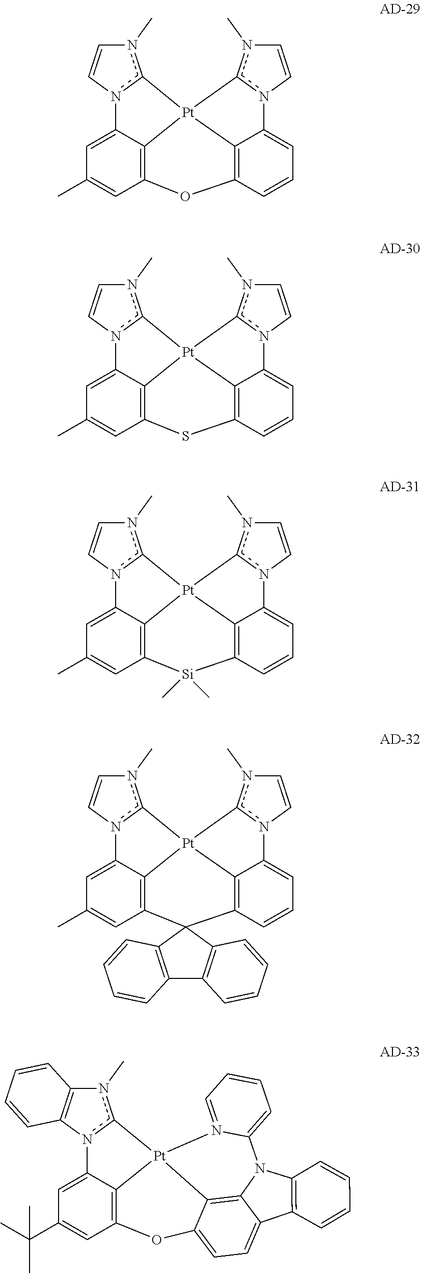

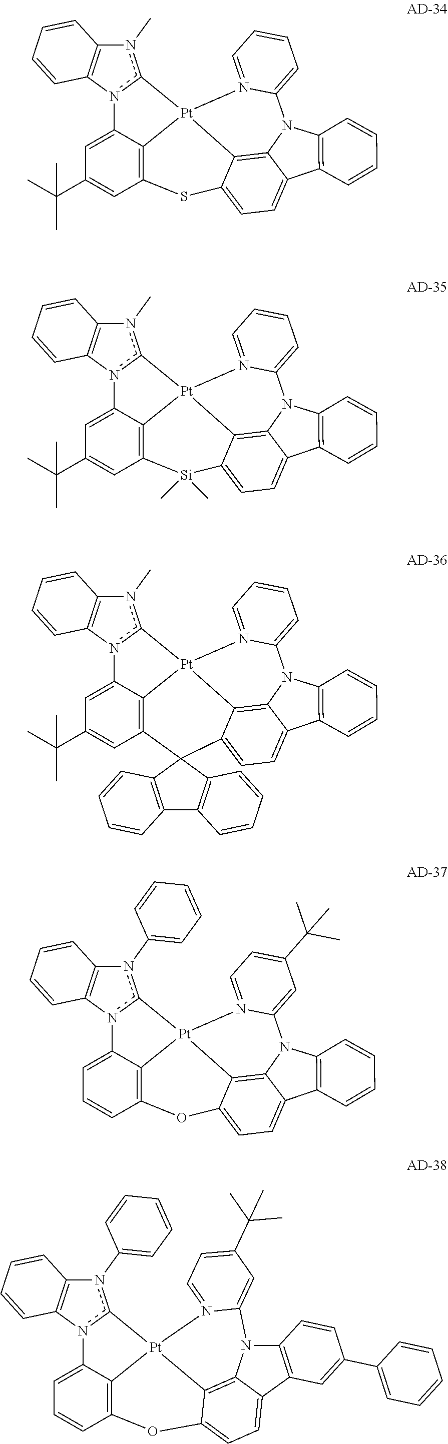

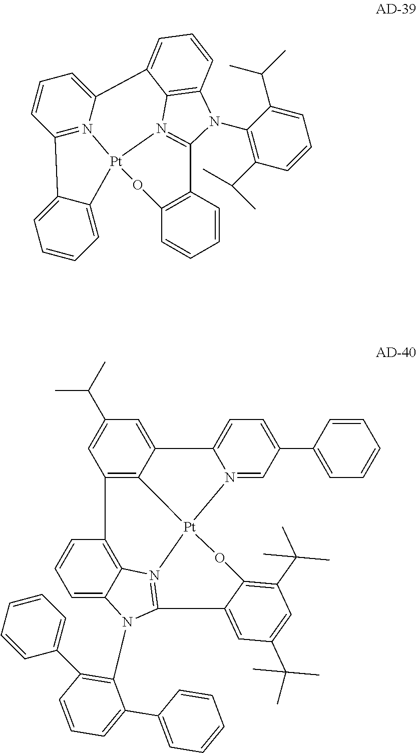

In one or more embodiments, the emission layer EML may include a compound represented by any one selected from among Formulas F-a to F-c. The compound represented by Formulas F-a to F-c may be utilized as a fluorescent dopant material.

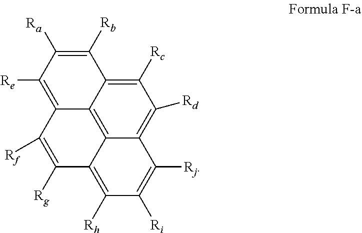

In Formula F-a, two selected from Rₐ to Rⱼ may each independently be substituted with —NAr₁Ar₂. The others among Rₐ to Rⱼ which are not substituted with *—NAr₁Ar₂ may each independently be hydrogen, deuterium, a halogen, a cyano group, a substituted or unsubstituted amine group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. In *—NAr₁Ar₂, Ar₁ and Ar₂ may each independently be a substituted or unsubstituted aryl group having 6 to 30 ring-forming carbon atoms, or a substituted or unsubstituted heteroaryl group having 2 to 30 ring-forming carbon atoms. For example, in some embodiments, at least one of Ar₁ or Ar₂ may be a heteroaryl group containing O or S as a ring-forming atom.

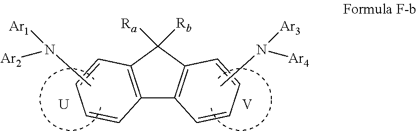

In Formula F-b, Rₐ and R_{b} may each independently be hydrogen, deuterium, a substituted or unsubstituted alkyl group having 1 to 20 carbon atoms, a substituted or unsubstituted alkenyl group having 2 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-b, Ar₁ to Ar₄ may each independently be a substituted or unsubstituted aryl group having 6 to 30 ring-forming carbon atoms, or a substituted or unsubstituted heteroaryl group having 2 to 30 ring-forming carbon atoms.

In Formula F-b, U and V may each independently be a substituted or unsubstituted hydrocarbon ring having 5 to 30 ring-forming carbon atoms, or a substituted or unsubstituted heterocycle having 2 to 30 ring-forming carbon atoms.

In Formula F-b, the number of rings represented by U and V may each independently be 0 or 1. For example, In Formula F-b, when the number of U or V is 1, one ring forms a fused ring in a portion indicated by U or V, and when the number of U or V is 0, it may refer that no ring indicated by U or V is present. In some embodiments, when the number of U is 0 and the number of V is 1, or when the number of U is 1 and the number of V is 0, a fused ring having a fluorene core of Formula F-b may be a cyclic compound having four rings. In some embodiments, when both (e.g., simultaneously) U and V are 0, the fused ring of Formula F-b may be a cyclic compound having three rings. In some embodiments, when both (e.g., simultaneously) U and V are 1, the fused ring having a fluorene core of Formula F-b may be a cyclic compound having five rings.

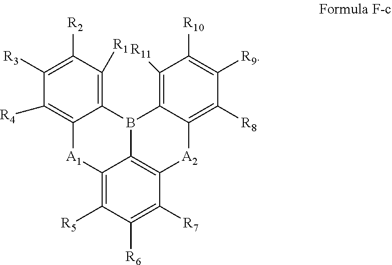

In Formula F-c, A₁ and A₂ may each independently be O, S, Se, or NRₘ, and Rₘ may be hydrogen, deuterium, a substituted or unsubstituted alkyl group having 1 to carbon atoms, a substituted or unsubstituted aryl group having 6 to 30 ring-forming carbon atoms, or a substituted or unsubstituted heteroaryl group having 2 to 30 ring-forming carbon atoms. R₁ to R₁₁ may each independently be hydrogen, deuterium, a halogen, a cyano group, a substituted or unsubstituted amine group, a substituted or unsubstituted boryl group, a substituted or unsubstituted oxy group, a substituted or unsubstituted thio group, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms, and/or bonded to an adjacent group to form a ring.

In Formula F-c, A₁ and A₂ may each independently be bonded to substituents of neighboring rings to form a fused ring. For example, when A₁ and A₂ may each independently be NRₘ, in some embodiments, A₁ may be bonded to R₄ or R₅ to form a ring. In some embodiments, A₂ may be bonded to R₇ or R₈ to form a ring.

In one or more embodiments, the emission layer EML may include, as a suitable dopant material, one or more selected from styryl derivatives (e.g., 1,4-bis[2-(3-N-ethylcarbazoryl)vinyl]benzene (BCzVB), 4-(di-p-tolylamino)-4′-[(di-p-tolylamino)styryl]stilbene (DPAVB), and N-(4-((E)-2-(6-((E)-4-(diphenylamino)styryl)naphthalen-2-yl)vinyl)phenyl)-N-phenylbenzenamine (N-BDAVBi)), perylene and derivatives thereof (e.g., 2,5,8,11-tetra-t-butylperylene (TBP)), pyrene and derivatives thereof (e.g., 1,1-dipyrene, 1,4-dipyrenylbenzene, 1,4-bis(N,N-diphenylamino)pyrene), etc.

In one or more embodiments, the emission layer EML may include a suitable phosphorescent dopant material. For example, in some embodiments, as a phosphorescent dopant, a metal complex including iridium (Ir), platinum (Pt), osmium (Os), gold (Au), titanium (Ti), zirconium (Zr), hafnium (Hf), europium (Eu), terbium (Tb), or thulium (Tm) may be utilized. In some embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Flr6), platinum octaethyl porphyrin (PtOEP), etc. may be utilized as a phosphorescent dopant. However, embodiments of the present disclosure are not limited thereto.

In one or more embodiments, the emission layer EML may include a hole transporting host and an electron transporting host. In some embodiments, the emission layer EML may include an auxiliary dopant and a light emitting dopant. In some embodiments, the auxiliary dopant may include a phosphorescent dopant material or a thermally activated delayed fluorescent dopant material. For example, in one or more embodiments, the emission layer EML may include a hole transporting host, an electron transporting host, an auxiliary dopant, and a light emitting do pant.

In some embodiments, in the emission layer EML, the hole transporting host and the electron transporting host may form an exciplex. In these embodiments, the triplet energy of the exciplex formed by the hole transporting host and the electron transporting host may correspond to T1, which is a gap between LUMO (lowest unoccupied molecular orbital) energy level of the electron transporting host and HOMO (highest occupied molecular orbital) energy level of the hole transporting host.

In one or more embodiments, the triplet energy level T1 of the exciplex formed by the hole transporting host and the electron transporting host may be about 2.4 eV to about 3.0 eV. In some embodiments, the triplet energy of the exciplex may have a value smaller than the energy gap of each host material. Accordingly, the exciplex may have a triplet energy of 3.0 eV or less, which is an energy gap between the hole transporting host and the electron transporting host.

In one or more embodiments, the emission layer EML may include a quantum dot material. The core of a quantum dot may be selected from a Group II-VI compound, a Group III-VI compound, a Group I-III-VI compound, a Group III-V compound, a Group III-II-V compound, a Group IV-VI compound, a Group IV element, a Group IV compound, and a combination thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof.

The Group III-VI compound may include a binary compound such as In₂S₃ and In₂Se₃, a ternary compound such as InGaS₃ and InGaSe₃, or any combination thereof.

The Group I-III-VI compound may include a ternary compound selected from the group consisting of AgInS, AgInS₂, CuInS, CuInS₂, AgGaS₂, CuGaS₂ CuGaO₂, AgGaO₂, AgAlO₂, and any mixture thereof, and/or a quaternary compound such as AgInGaS₂ and CuInGaS₂.

The Group III-V compound may be selected from the group consisting of a binary compound selected from the group consisting of GaN, GaP, GaAs, GaSb, AlN, AlP, AlAs, AlSb, InN, InP, InAs, InSb, and a mixture thereof, a ternary compound selected from the group consisting of GaNP, GaNAs, GaNSb, GaPAs, GaPSb, AINP, AlNAs, AlNSb, AlPAs, AlPSb, InGaP, InAlP, InNP, InNAs, InNSb, InPAs, InPSb, and a mixture thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and a mixture thereof. In some embodiments, the Group III-V compound may further include a Group II metal. For example, InZnP, etc. may be selected as a Group III-II-V compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof. The Group IV element may be selected from the group consisting of Si, Ge, and a mixture thereof. The Group IV compound may be a binary compound selected from the group consisting of SiC, SiGe, and a mixture thereof.

In one or more embodiments, the binary compound, the ternary compound, or the quaternary compound may be present in particles having a substantially uniform concentration distribution, or may be present in substantially the same particles having a partially different concentration distribution. In some embodiments, a core/shell structure in which one quantum dot surrounds another quantum dot may be present. The core/shell structure may have a concentration gradient in which the concentration of an element present in the shell becomes lower towards the core.

In some embodiments, a quantum dot may have the core/shell structure including a core having nano-crystals, and a shell around (e.g., surrounding) the core, which are described above. The shell of the quantum dot may serve as a protection layer to prevent or reduce the chemical deformation of the core so as to keep semiconductor properties, and/or a charging layer to impart electrophoresis properties to the quantum dot. The shell may be a single layer or multiple layers. Examples of the shell of the quantum dot may be a metal or non-metal oxide, a semiconductor compound, or a combination thereof.

For example, the metal or non-metal oxide suitable as a shell may be a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄, NiO, and/or a ternary compound such as MgAl₂O₄, CoFe₂O₄, NiFe₂O₄, and CoMn₂O₄, but embodiments of the present disclosure are not limited thereto.

In some embodiments, the semiconductor compound suitable as a shell may be, for example, CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but embodiments of the present disclosure are not limited thereto.

The quantum dot may have, in an emission wavelength spectrum, a full width of half maximum (FWHM) of about 45 nm or less, about 40 nm or less, or about nm or less. Within this range, the color purity or the color reproducibility may be improved. In some embodiments, light emitted through the quantum dot is emitted in all directions, and thus a wide viewing angle may be improved.

In some embodiments, the form/shape of a quantum dot is not particularly limited as long as it is a form/shape commonly utilized in the art. In one or more embodiments, a quantum dot in the form/shape of substantially spherical, pyramidal, multi-arm, or cubic nanoparticles, nanotubes, nanowires, nanofibers, nanoplatelets, etc. may be utilized.

The quantum dot may control the color of emitted light according to the particle size thereof, and thus the quantum dot may have one or more suitable light emission colors such as blue, red, green, etc.

In one or more embodiments, in the light emitting element ED shown in FIGS. 3 to 5, an electron transport region ETR is provided on the emission layer EML. The electron transport region ETR may include at least one selected from among a hole blocking layer HBL, an electron transport layer ETL, and an electron injection layer EIL, but embodiments of the present disclosure are not limited thereto.

The electron transport region ETR may have a single layer formed of a single material, a single layer formed of a plurality of different materials, or a multilayer structure having a plurality of layers formed of a plurality of different materials.

For example, in some embodiments, the electron transport region ETR may have a single layer structure of an electron injection layer EIL or an electron transport layer ETL, and may have a single layer structure formed of an electron injection material and an electron transport material. In some embodiments, the electron transport region ETR may have a single layer structure formed of a plurality of different materials, or may have a structure in which an electron transport layer ETL/electron injection layer EIL, or a hole blocking layer HBL/electron transport layer ETL/electron injection layer EIL are stacked in order (in the stated order) from the emission layer EML, but embodiments of the present disclosure are not limited thereto. The electron transport region ETR may have a thickness of, for example, about 1000 Å to about 1500 Å.

The electron transport region ETR may be formed utilizing one or more suitable methods such as a vacuum deposition method, a spin coating method, a casting method, a Langmuir-Blodgett (LB) method, an inkjet printing method, a laser printing method, a laser induced thermal imaging (LITI) method, etc.

In one or more embodiments, the electron transport region ETR may include a compound represented by Formula ET-1.

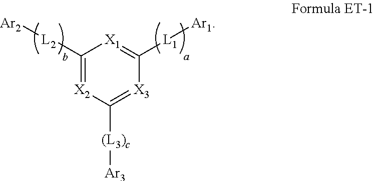

In Formula ET-1, at least one selected from among X₁ to X₃ is N and the rest are CRₐ. Rₐ may be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms. Ar₁ to Ar₃ may each independently be hydrogen, deuterium, a substituted or unsubstituted alkyl group having 1 to 20 carbon atoms, a substituted or unsubstituted aryl group having 6 to 30 ring-forming carbon atoms, or a substituted or unsubstituted heteroaryl group having 2 to 30 ring-forming carbon atoms.

In Formula ET-1, a to c may each independently be an integer of 0 to 10. In Formula ET-1, L₁ to L₃ may each independently be a direct linkage, a substituted or unsubstituted arylene group having 6 to 30 ring-forming carbon atoms, or a substituted or unsubstituted heteroarylene group having 2 to 30 ring-forming carbon atoms. In some embodiments, when a to c are an integer of 2 or greater, L₁ to L₃ may each independently be a substituted or unsubstituted arylene group having 6 to 30 ring-forming carbon atoms, or a substituted or unsubstituted heteroarylene group having 2 to 30 ring-forming carbon atoms.

In one or more embodiments, the electron transport region ETR may include an anthracene-based compound. However, embodiments of the present disclosure are not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-ylphenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), or a mixture thereof.

In one or more embodiments, the electron transport region ETR may include at least one selected from among compounds ET1 to ET37.

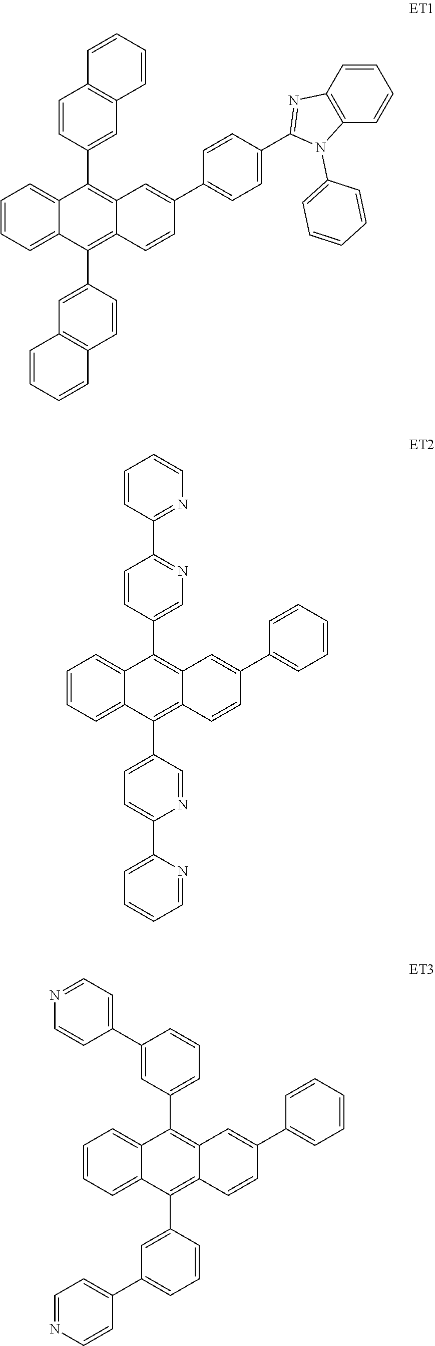 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

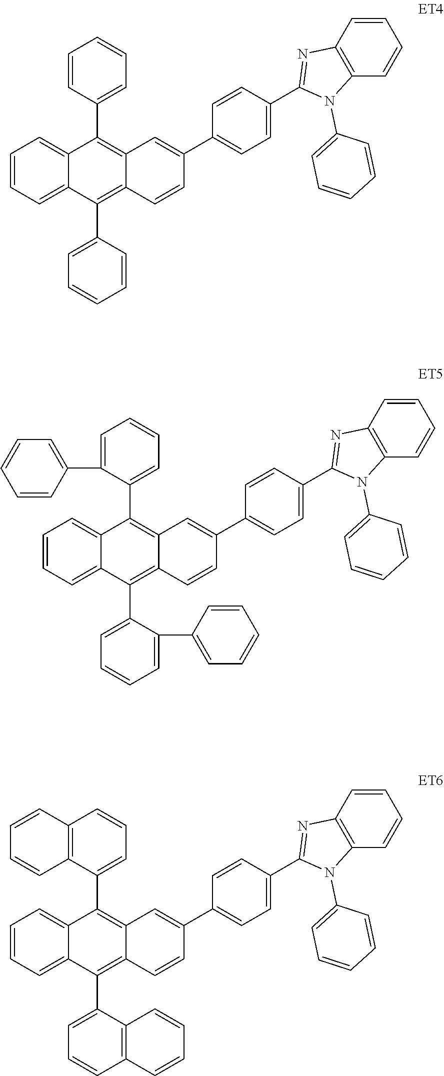 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1]

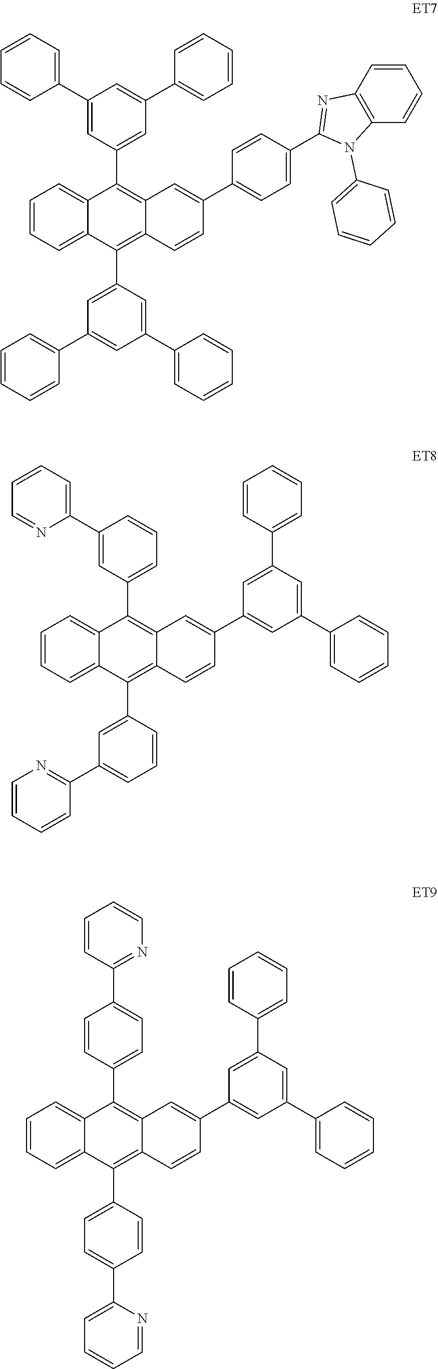

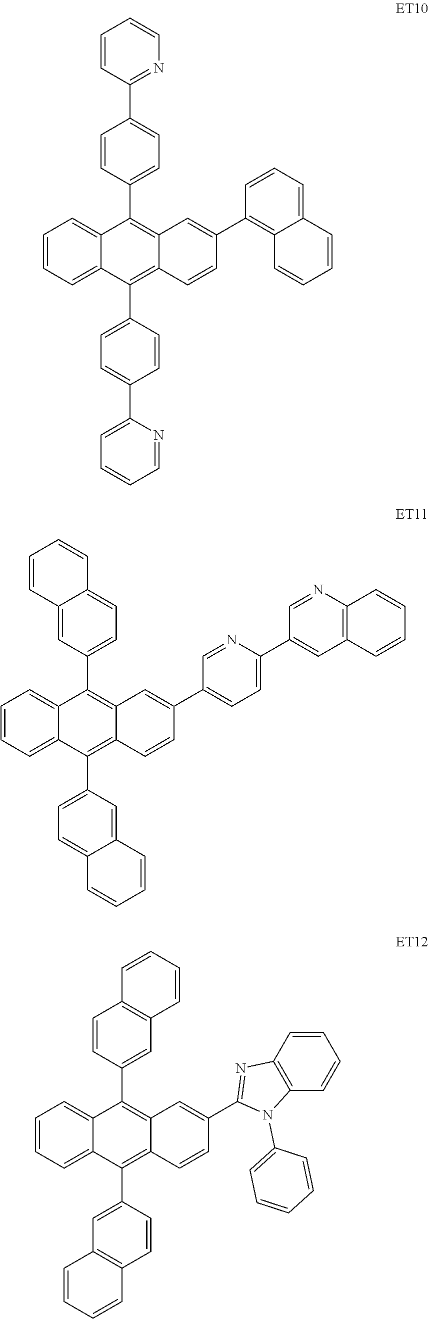

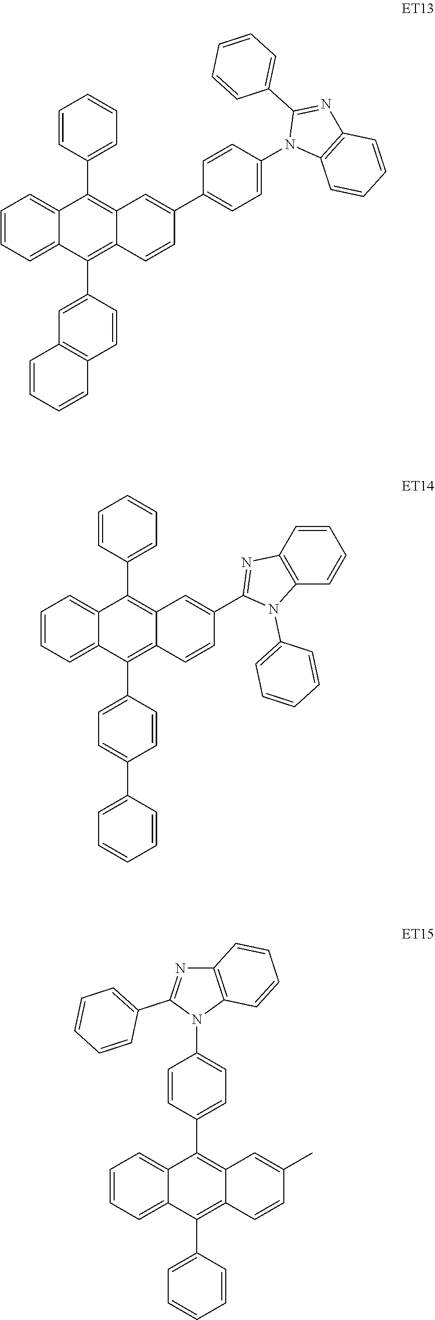 [SMILES: c1ccc(-c2c3ccccc3c(-c3ccc4ccccc4c3)c3ccc(-c4ccc(-n5c(-c6ccccc6)nc6ccccc65)cc4)cc23)cc1 ; c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1]

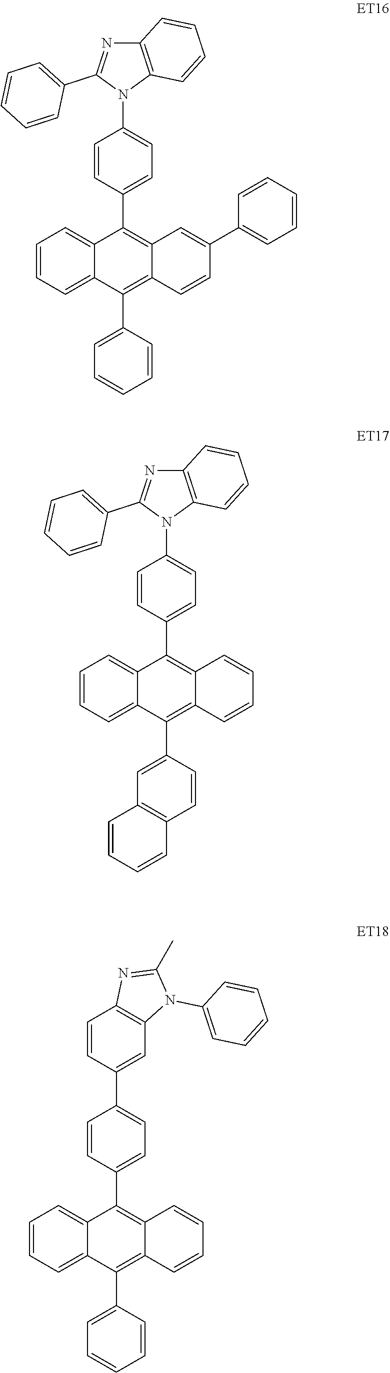 [SMILES: c1ccc(-c2ccc3c(-c4ccccc4)c4ccccc4c(-c4ccc(-n5c(-c6ccccc6)nc6ccccc65)cc4)c3c2)cc1 ; c1ccc(-c2nc3ccccc3n2-c2ccc(-c3c4ccccc4c(-c4ccc5ccccc5c4)c4ccccc34)cc2)cc1 ; Cc1nc2ccc(-c3ccc(-c4c5ccccc5c(-c5ccccc5)c5ccccc45)cc3)cc2n1-c1ccccc1]

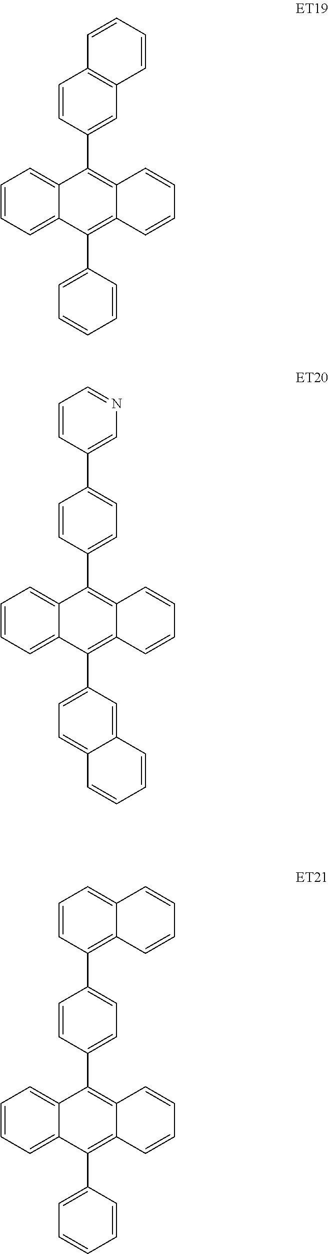

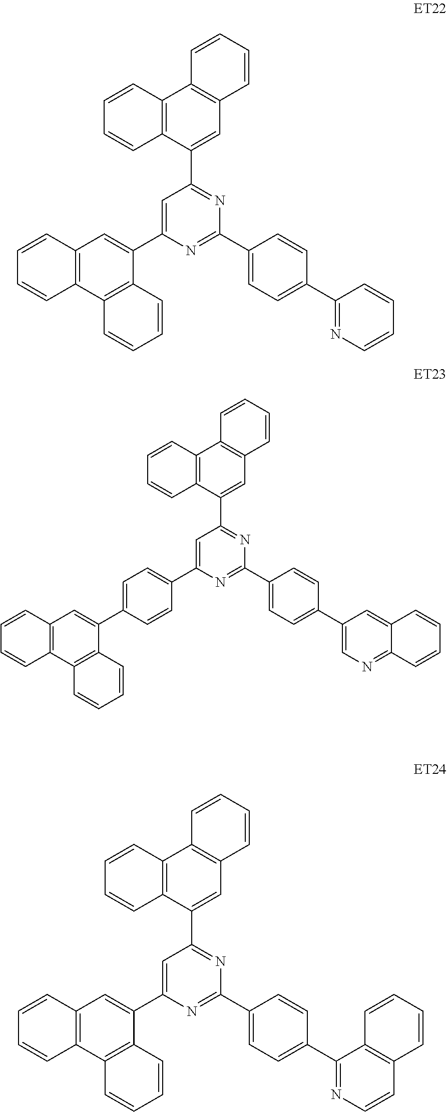 [SMILES: c1ccc(-c2ccc(-c3nc(-c4cc5ccccc5c5ccccc45)cc(-c4cc5ccccc5c5ccccc45)n3)cc2)nc1 ; c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1]

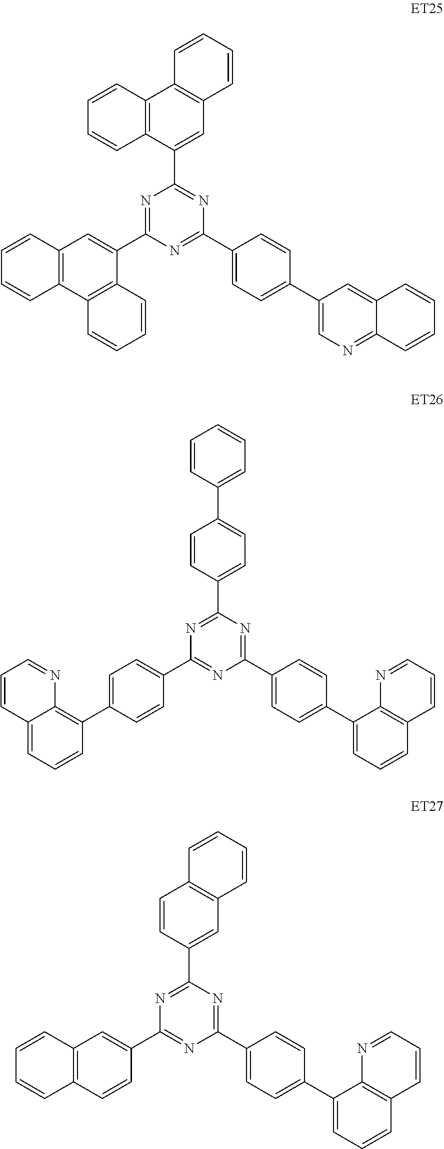 [SMILES: c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1 ; c1ccc2cc(-c3nc(-c4ccc(-c5cccc6cccnc56)cc4)nc(-c4ccc5ccccc5c4)n3)ccc2c1]

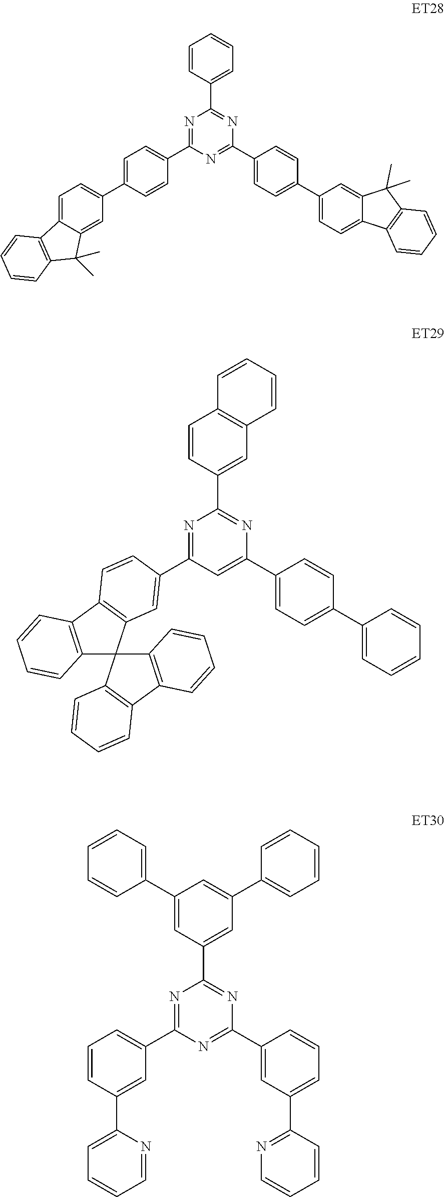 [SMILES: CC1(C)c2ccccc2-c2ccc(-c3ccc(-c4nc(-c5ccccc5)nc(-c5ccc(-c6ccc7c(c6)C(C)(C)c6ccccc6-7)cc5)n4)cc3)cc21 ; c1ccc(-c2ccc(-c3cc(-c4ccc5c(c4)C4(c6ccccc6-c6ccccc64)c4ccccc4-5)nc(-c4ccc5ccccc5c4)n3)cc2)cc1 ; c1ccc(-c2cc(-c3ccccc3)cc(-c3nc(-c4cccc(-c5ccccn5)c4)nc(-c4cccc(-c5ccccn5)c4)n3)c2)cc1]

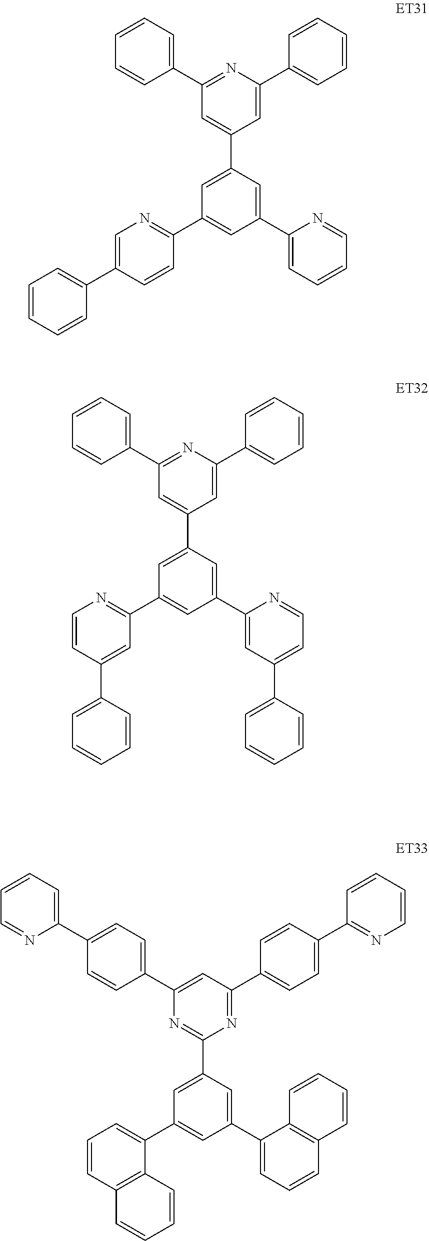 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

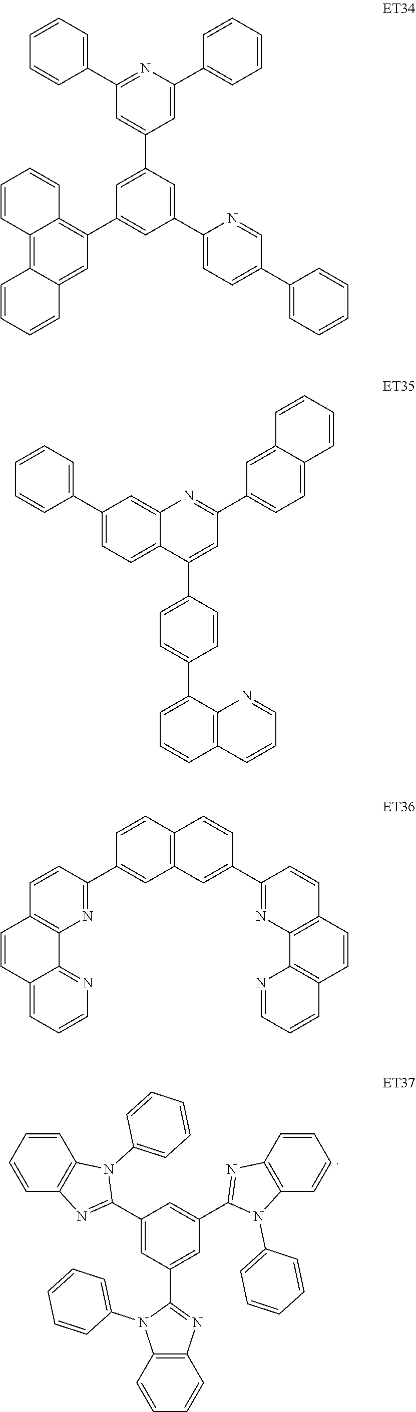 [SMILES: c1ccc(-c2ccc(-c3cc(-c4cc(-c5ccccc5)nc(-c5ccccc5)c4)cc(-c4cc5ccccc5c5ccccc45)c3)nc2)cc1 ; c1ccc(-c2ccc3c(-c4ccc(-c5cccc6cccnc56)cc4)cc(-c4ccc5ccccc5c4)nc3c2)cc1 ; c1cnc2c(c1)ccc1ccc(-c3ccc4ccc(-c5ccc6ccc7cccnc7c6n5)cc4c3)nc12 ; c1ccc(-n2c(-c3cc(-c4nc5ccccc5n4-c4ccccc4)cc(-c4nc5ccccc5n4-c4ccccc4)c3)nc3ccccc32)cc1]

In some embodiments, the electron transport region ETR may include one or more selected from halogenated metals such as LiF, NaCl, CsF, RbCl, RbI, CuI, and/or KI, lanthanide metals such as Yb, and co-deposition materials of a halogenated metal and a lanthanide metal. For example, the electron transport region ETR may include KI:Yb, RbI:Yb, LiF:Yb, etc. as a co-deposition material. In some embodiments, for the electron transport region ETR, a metal oxide such as Li₂O and BaO, or 8-hydroxyl-lithium quinolate (Liq), etc. may be utilized, but embodiments of the present disclosure are limited thereto. In some embodiments, the electron transport region ETR may also be formed of a mixture material of an electron transport material and an insulating organo-metal salt. The organo-metal salt may be a material having an energy band gap of about 4 eV or greater. For example, the organo-metal salt may include, for example, metal acetates, metal benzoates, metal acetoacetates, metal acetylacetonates, and/or metal stearates.

In one or more embodiments, the electron transport region ETR may further include, for example, at least one selected from 2,9-dimethyl-4,7-diphenyl-1,10-phenanthroline (BCP), diphenyl(4-(triphenylsilyl)phenyl)phosphine oxide (TSPO1), and 4,7-diphenyl-1,10-phenanthroline (Bphen) in addition to the materials described above, but embodiments of the present disclosure are not limited thereto.

The electron transport region ETR may include the compounds of the electron transport region described above in at least one selected from among the electron injection layer EIL, the electron transport layer ETL, and the hole blocking layer HBL.

When the electron transport region ETR includes the electron transport layer ETL, the electron transport layer ETL may have a thickness of about 100 Å to about 1000 Å, for example, about 150 Å to about 500 Å. When the thickness of the electron transport layer ETL satisfies the above-described range, satisfactory electron transport properties may be obtained without a substantial increase in driving voltage. When the electron transport region ETR includes the electron injection layer EIL, the electron injection layer EIL may have a thickness of about 1 Å to about 100 Å, for example, about 3 Å to about 90 Å. When the thickness of the electron injection layer EIL satisfies the above-described ranges, satisfactory electron injection properties may be obtained without a substantial increase in driving voltage.

The second electrode EL2 may be provided on the electron transport region ETR. The second electrode EL2 may be a common electrode. The second electrode EL2 may be a cathode or an anode but embodiments of the present disclosure are not limited thereto. For example, when the first electrode EL1 is an anode, the second electrode EL2 may be a cathode, and when the first electrode EL1 is a cathode, the second electrode EL2 may be an anode. The second electrode may include at least one selected from among Ag, Mg, Cu, Al, Pt, Pd, Au, Ni, Nd, Ir, Cr, Li, Ca, LiF, Mo, Ti, W, In, Sn, and Zn, two or more compounds selected therefrom, two or more mixtures selected therefrom, and/or oxides thereof.

The second electrode EL2 may be a transmissive electrode, a transflective electrode, or a reflective electrode. When the second electrode EL2 is a transmissive electrode, the second electrode EL2 may be formed of a transparent metal oxide, for example, indium tin oxide (ITO), indium zinc oxide (IZO), zinc oxide (ZnO), indium tin zinc oxide (ITZO), etc.

When the second electrode EL2 is a transflective electrode or a reflective electrode, the second electrode EL2 may include Ag, Mg, Cu, Al, Pt, Pd, Au, Ni, Nd, Ir, Cr, Li, Ca, LiF/Ca, LiF/Al, Mo, Ti, Yb (ytterbium), W, a compound thereof, or a mixture thereof (e.g., AgMg, AgYb, or MgAg). In some embodiments, the second electrode EL2 may have a multilayer structure including a reflective film or a transflective film formed of one or more selected from the above-described materials, and/or a transparent conductive film formed of indium tin oxide (ITO), indium zinc oxide (IZO), zinc oxide (ZnO), indium tin zinc oxide (ITZO), etc. For example, the second electrode EL2 may include one or more selected from the above-described metal materials, a combination of two or more metal materials selected from the above-described metal materials, and/or oxides of the above-described metal materials.

In some embodiments, the second electrode EL2 may be connected with an auxiliary electrode. When the second electrode EL2 is connected with the auxiliary electrode, the resistance of the second electrode EL2 may decrease.

In one or more embodiments, a capping layer CPL may be disposed on the second electrode EL2 of the light emitting element ED. The capping layer CPL may include multi-layers or a single layer.

In the light emitting element ED according to one or more embodiments, the capping layer CPL may include the fused compound represented by Formula 1 according to one or more embodiments.

The fused compound according to one or more embodiments may include a 5-ring heterocyclic core in which a π-donating structure and a π-accepting structure are alternately disposed at both (e.g., simultaneously) sides of a benzene ring as a center. The core may include two heterocycles. For example, in some embodiments, the core may include two sulfur atoms, two oxygen atoms, or one sulfur atom and one oxygen atom.

The fused compound according to one or more embodiments may include two substituents that are positioned para with respect to each other in a benzene ring placed at the center of the core. The two substituents may be a substituted or unsubstituted aryl group, or a substituted or unsubstituted heteroaryl group.

The π-donating structure may refer to a structure with a tendency to donate electrons in molecules, and the π-accepting structure may refer to a structure with a tendency to accept electrons in molecules. For example, the π-donating structure may be a p-type or kind structure of a pyrrole ring, a furan ring, a thiophene ring, and/or the like. The π-accepting structure may be an n-type or kind structure of a benzene ring, a pyridine ring, a pyrimidine ring, and/or the like.

In one or more embodiments, the capping layer CPL may include a fused compound represented by Formula 1. The fused compound represented by Formula 1 corresponds to the fused compound according to one or more embodiments described above.

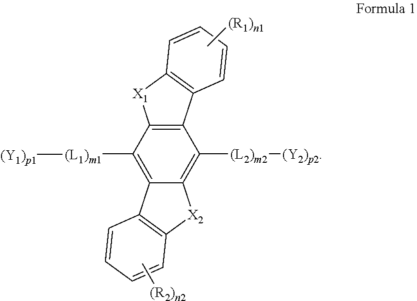

In Formula 1, X₁ and X₂ may each independently be S or O. X₁ and X₂ may be the same or different. For example, both (e.g., simultaneously) X₁ and X₂ may be S or O, or one may be S and the other may be O.

R₁ and R₂ may each independently be hydrogen or deuterium. For example, in some embodiments, R₁ and R₂ may be hydrogen atoms.

n1 and n2 may each independently be an integer of 0 to 4. The embodiment in which n1 is 0 may be the same as the embodiment in which n1 is 4 and all R₁'s are hydrogen. When n1 is 0, it may be understood that R₁ is not substituted in the fused compound represented by Formula 1. The embodiment in which n2 is 0 may be the same as the embodiment in which n2 is 4 and all R₂'s are hydrogen. When n2 is 0, it may be understood that R₂ is not substituted in the fused compound represented by Formula 1. When n1 and n2 are each 2 or greater, the substituents in the parentheses may be the same or different.

L₁ and L₂ may each independently be a direct linkage or N. L₁ and L₂ may be the same or different. For example, both (e.g., simultaneously) L₁ and L₂ may be a direct linkage or N.

m1 and m2 may each independently be 0 or 1. m1 and m2 may be the same or different. For example, both (e.g., simultaneously) m1 and m2 may be 0 or 1. When m1 and m2 are 0, each of L₁ and L₂ may be understood as a direct linkage.

Y₁ and Y₂ may each independently be a substituted or unsubstituted aryl group having 6 to 20 ring-forming carbon atoms, or a substituted or unsubstituted heteroaryl group having 2 to 20 ring-forming carbon atoms. For example, in some embodiments, Y₁ and Y₂ may each independently be a substituted or unsubstituted aryl group having 6 to 10 ring-forming carbon atoms, or a substituted or unsubstituted heteroaryl group having 2 to 10 ring-forming carbon atoms. In one or more embodiments, Y₁ and Y₂ may each independently be a naphthyl group, a benzothiophene group, a benzofuran group, a cyclopentadithiophene group, or a dihydrothienodioxineyl group.

p1 and p2 may each independently be 1 or 2. p1 and p2 may be the same or different. For example, both (e.g., simultaneously) p1 and p2 may be 1 or 2. When both (e.g., simultaneously) m1 and m2 are 0, both (e.g., simultaneously) p1 and p2 may be 1. When both (e.g., simultaneously) m1 and m2 are 1, both (e.g., simultaneously) p1 and p2 may be 2.

In some embodiments, when both (e.g., simultaneously) m1 and m2 are 1, and both (e.g., simultaneously) p1 and p2 are 2, it may be understood that each of L₁ and L₂ is connected to each of Y₁ and Y₂ as shown in Structural Formulas A and B.

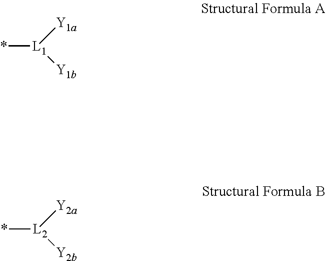

For example, two Y₁'s, as shown in Structural Formula A, may each be represented by Y₁ₐ and Y_{1b}, and Y₁ₐ and Y_{1b} may each be connected to L₁. Two Y₂'s, as shown in Structural Formula B, may each be represented by Y₂ₐ and Y_{2b}, and Y₂ₐ and Y_{2b} may each be connected to L₂.

In Structural Formulas A and B, “ [symbol] ” is a site connected to Formula 1.

In one or more embodiments, the fused compound represented by Formula 1 may be represented by any one selected from among Formulas 1-1a to 1-1c.

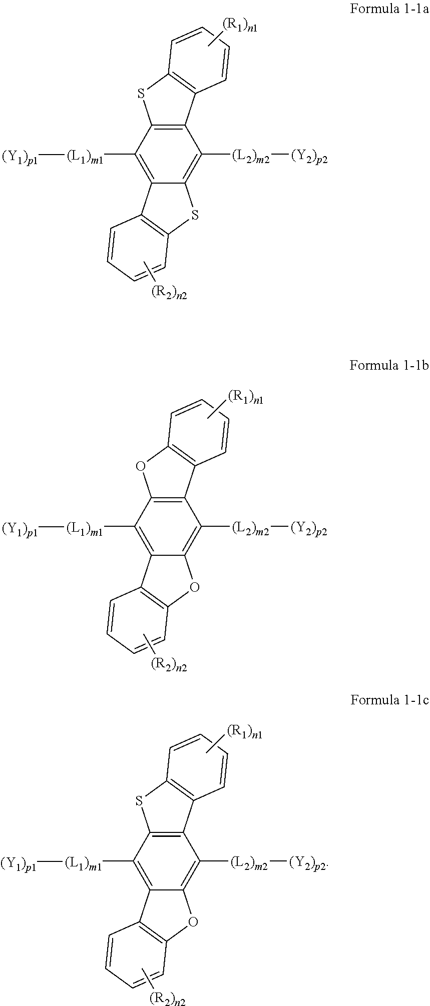

Formulas 1-1a to 1-1c specifically indicate X₁ and X₂ in Formula 1. Formula 1-1a shows embodiments in which both (e.g., simultaneously) X₁ and X₂ are Sin Formula 1, Formula 1-1b shows embodiments in which both (e.g., simultaneously) X₁ and X₂ are O in Formula 1, and Formula 1-c shows embodiments in which X₁ is S and X₂ is O in Formula 1.

In Formulas 1-1a to 1-1c, R₁, R₂, n1, n2, L₁, L₂, m1, m2, Y₁, Y₂, p1, and p2 may each independently be the same as defined in Formula 1.

In one or more embodiments, the fused compound represented by Formula 1 may be represented by Formula 1-2a or Formula 1-2b.

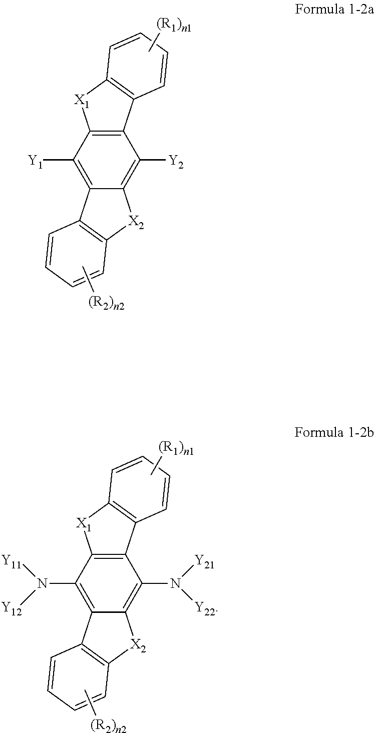

Formulas 1-2a and 1-2b specifically indicate L₁ and L₂ in Formula 1. Formula 1-2a shows embodiments in which both (e.g., simultaneously) L₁ and L₂ are direct linkages, and Formula 1-2b shows embodiments in which both (e.g., simultaneously) L₁ and L₂ are N.

In Formula 1-2b, Y₁₁, Y₁₂, Y₂₁, and Y₂₂ may each independently be a substituted or unsubstituted aryl group having 6 to 20 ring-forming carbon atoms, or a substituted or unsubstituted heteroaryl group having 2 to 20 ring-forming carbon atoms. For example, in some embodiments, Y₁₁, Y₁₂, Y₂₁, and Y₂₂ may each independently be a substituted or unsubstituted aryl group having 6 to 10 ring-forming carbon atoms, or a substituted or unsubstituted heteroaryl group having 2 to 10 ring-forming carbon atoms. In some embodiments, Y₁₁, Y₁₂, Y₂₁, and Y₂₂ may each independently be a naphthyl group, a benzothiophene group, a benzofuran group, a cyclopentadithiophene group, or a dihydrothienodioxineyl group.

In Formula 1-2a or Formula 1-2b, X₁, X₂, R₁, R₂, n1, n2, Y₁, and Y₂ may each independently be the same as defined in Formula 1.

In one or more embodiments, Y₁ and Y₂ may each independently be a substituted or unsubstituted bicyclic or tricyclic aryl group, or a substituted or unsubstituted bicyclic or tricyclic heteroaryl group.

In one or more embodiments, Y₁ and Y₂ may each independently be represented by any one selected from among Formulas 2-1 to 2-4.

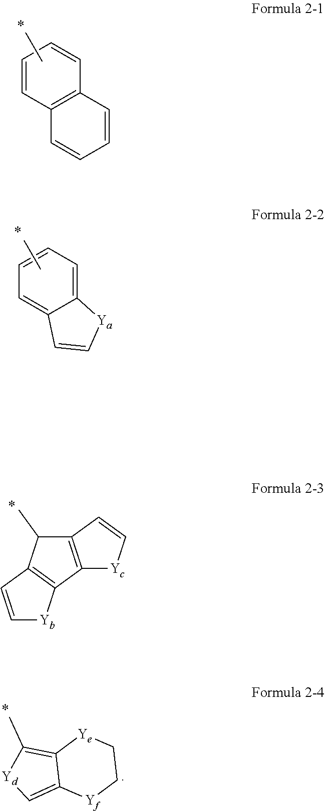

Formulas 2-1 to 2-4 specifically indicate Y₁ and Y₂ in Formula 1.

In Formulas 2-1 to 2-4, Yₐ to Yᵣ may be S or O. For example, Yₐ may be S or O. Y_{b} and Y_{c} may each be S. Y_{d} may be S, and Yₑ and Yᵣ may each be O.

In Formulas 2-1 to 2-4, “ [symbol] ” is a site connected to Formula 1.

In one or more embodiments, R₁ and R₂ may each be hydrogen.

In one or more embodiment, the fused compound represented by Formula 1 may have a monomolecular refractive index of about 1.7 to about 2.5 with respect to light having a wavelength of about 490 nm to about 570 nm. In some embodiments, the monomolecular refractive index of the fused compound represented by Formula 1 at a wavelength of about 520 nm to about 560 nm may be about 1.7 to about 2.5.

In one or more embodiments, the capping layer CPL may include a fused compound represented by Formula 3. The fused compound represented by Formula 3 corresponds to the fused compound according to one or more embodiments described above.

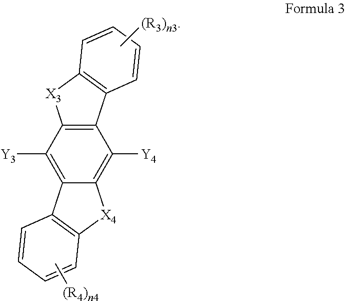

In Formula 3, X₃ and X₄ may each independently be S or O. X₃ and X₄ may be the same or different. For example, in some embodiments, both (e.g., simultaneously) X₃ and X₄ may be S or O. X₃ and X₄ may each correspond to X₁ and X₂ of Formula 1, respectively.

R₃ and R₄ may be hydrogen or deuterium. For example, in some embodiments, R₃ and R₄ may be hydrogen. R₃ and R₄ may each correspond to R₁ and R₂ of Formula 1, respectively.

n3 and n4 may each independently be an integer of 0 to 4. The embodiment in which n3 is 0 may be the same as the embodiment in which n3 is 4 and all R₃'s are hydrogen. When n3 is 0, it may be understood that R₃ is not substituted in the fused compound represented by Formula 3. The embodiment in which n4 is 0 may be the same as the embodiment in which n4 is 4 and all R₄'s are hydrogen. When n4 is 0, it may be understood that R₄ is not substituted in the fused compound represented by Formula 3. When n3 and n4 are each 2 or greater, the substituents in the parentheses may be the same or different. n3 and n4 may each correspond to n1 and n2 of Formula 1, respectively.

Y₃ and Y₄ may each independently be *—NR₅R₆, a substituted or unsubstituted aryl group having 6 to 20 ring-forming carbon atoms, or a substituted or unsubstituted heteroaryl group having 2 to 20 ring-forming carbon atoms.

When Y₃ and Y₄ are each a substituted or unsubstituted aryl group having 6 to 20 ring-forming carbon atoms, or a substituted or unsubstituted heteroaryl group having 2 to 20 ring-forming carbon atoms, Y₃ and Y₄ may each independently be a substituted or unsubstituted aryl group having 6 to 10 ring-forming carbon atoms, or a substituted or unsubstituted heteroaryl group having 2 to 10 ring-forming carbon atoms. For example, in some embodiments, Y₃ and Y₄ may each independently be a naphthyl group, a benzothiophene group, a benzofuran group, a cyclopentadithiophene group, or a dihydrothienodioxineyl group.

When Y₃ and Y₄ are each *—NR₅R₆, R₅ and R₆ may each independently be a substituted or unsubstituted aryl group having 6 to 20 ring-forming carbon atoms, or a substituted or unsubstituted heteroaryl group having 2 to 20 ring-forming carbon atoms. For example, in some embodiments, R₅ and R₆ may each independently be a substituted or unsubstituted aryl group having 6 to 10 ring-forming carbon atoms, or a substituted or unsubstituted heteroaryl group having 2 to 10 ring-forming carbon atoms. In some embodiments, R₅ and R₆ may each independently be a naphthyl group, a benzothiophene group, a benzofuran group, a cyclopentadithiophene group, or a dihydrothienodioxineyl group.

In one or more embodiments, the fused compound represented by Formula 3 may be represented by any one selected from among Formulas 3-1a to 3-1c.

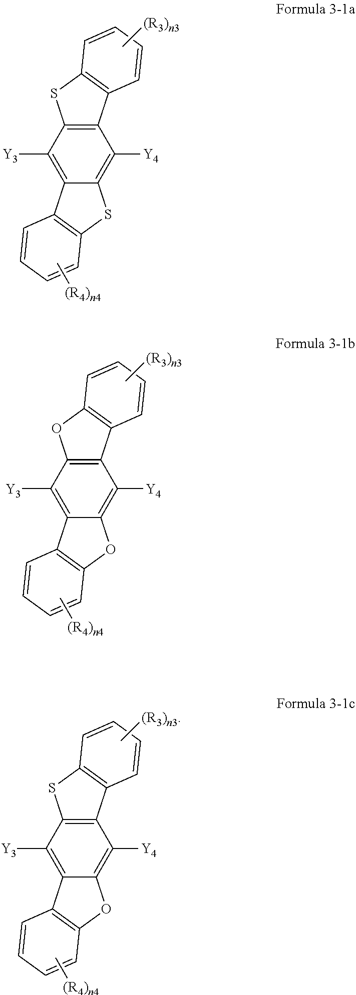

Formulas 3-1a to 3-1c specifically indicate X₃ and X₄ in Formula 3. Formula 3-1a shows embodiments in which both (e.g., simultaneously) X₃ and X₄ are Sin Formula 3, Formula 3-1b shows embodiments in which both (e.g., simultaneously) X₃ and X₄ are 0 in Formula 3, and Formula 3-c shows embodiments in which X₃ is S and X₄ is 0 in Formula 3.

In Formulas 3-1a to 3-1c, R₃, R₄, n3, n4, Y₃, and Y₄ may each be the same as defined in Formula 3.

In one or more embodiments, Y₃ and Y₄ may each independently be *—NR₅R₆, or represented by any one selected from among Formulas 4-1 to 4-4, and R₅ and R₆ may be represented by any one selected from among Formulas 4-1 to 4-4.

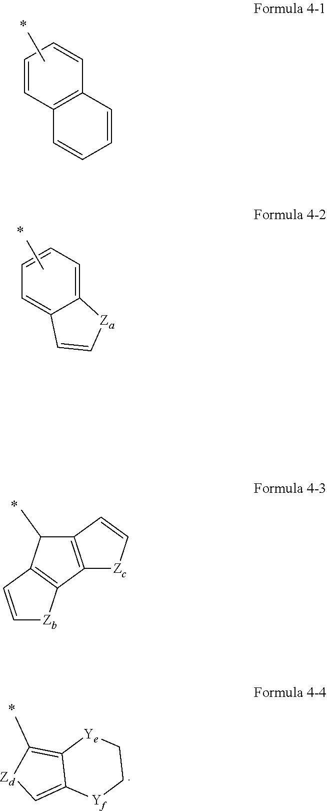

Formulas 4-1 to 4-4 specifically indicate Y₃, Y₄, R₅, and R₆ in Formula 3.

In Formulas 4-1 to 4-4, Zₐ to Z_{f} may be S or O. For example, in some embodiments, Zₐ may be S or O. In some embodiments, Z_{b} and Z_{c} may each be S. In some embodiments, Z_{d} may be S, and Zₑ and Z_{f} may each be O.

In Formulas 4-1 to 4-4, “ [symbol] ” is a site connected to Formula 3.

In one or more embodiments, R₃ and R₄ may each be hydrogen.

In one or more embodiments, the fused compound represented by Formula 3 may have a monomolecular refractive index of about 1.7 to about 2.5 with respect to light having a wavelength of about 490 nm to about 570 nm.

In one or more embodiments, the fused compound represented by Formula 1 and the fused compound represented by Formula 3 may each include at least one selected from among the compounds of Compound Group 1.

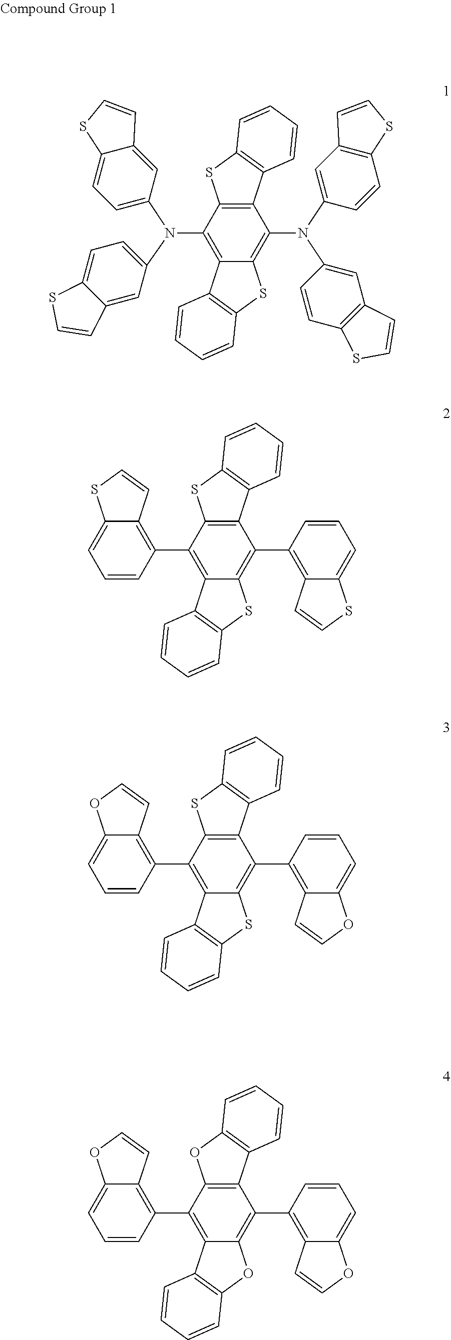 [SMILES: c1ccc2c(c1)sc1c(N(c3ccc4sccc4c3)c3ccc4sccc4c3)c3c(sc4ccccc43)c(N(c3ccc4sccc4c3)c3ccc4sccc4c3)c12 ; c1cc(-c2c3sc4ccccc4c3c(-c3cccc4sccc34)c3sc4ccccc4c23)c2ccsc2c1 ; c1cc(-c2c3sc4ccccc4c3c(-c3cccc4occc34)c3sc4ccccc4c23)c2ccoc2c1 ; c1cc(-c2c3oc4ccccc4c3c(-c3cccc4occc34)c3oc4ccccc4c23)c2ccoc2c1]

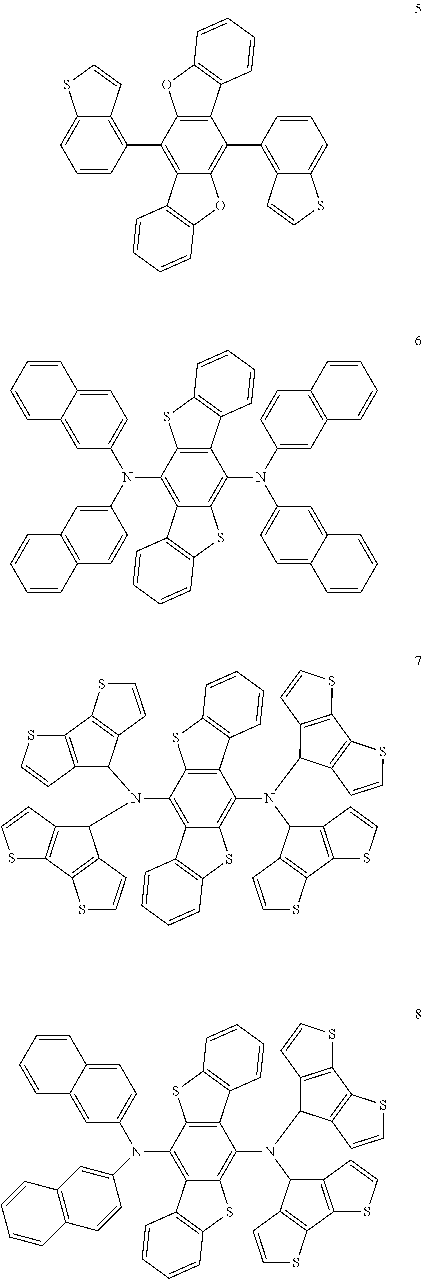 [SMILES: c1ccc2c(c1)oc1c(-c3cccc4sccc34)c3c(oc4ccccc43)c(-c3cccc4sccc34)c12 ; c1ccc2cc(N(c3ccc4ccccc4c3)c3c4sc5ccccc5c4c(N(c4ccc5ccccc5c4)c4ccc5ccccc5c4)c4sc5ccccc5c34)ccc2c1 ; c1ccc2c(c1)sc1c(N(C3c4ccsc4-c4sccc43)C3c4ccsc4-c4sccc43)c3c(sc4ccccc43)c(N(C3c4ccsc4-c4sccc43)C3c4ccsc4-c4sccc43)c12 ; c1ccc2cc(N(c3ccc4ccccc4c3)c3c4sc5ccccc5c4c(N(C4c5ccsc5-c5sccc54)C4c5ccsc5-c5sccc54)c4sc5ccccc5c34)ccc2c1]

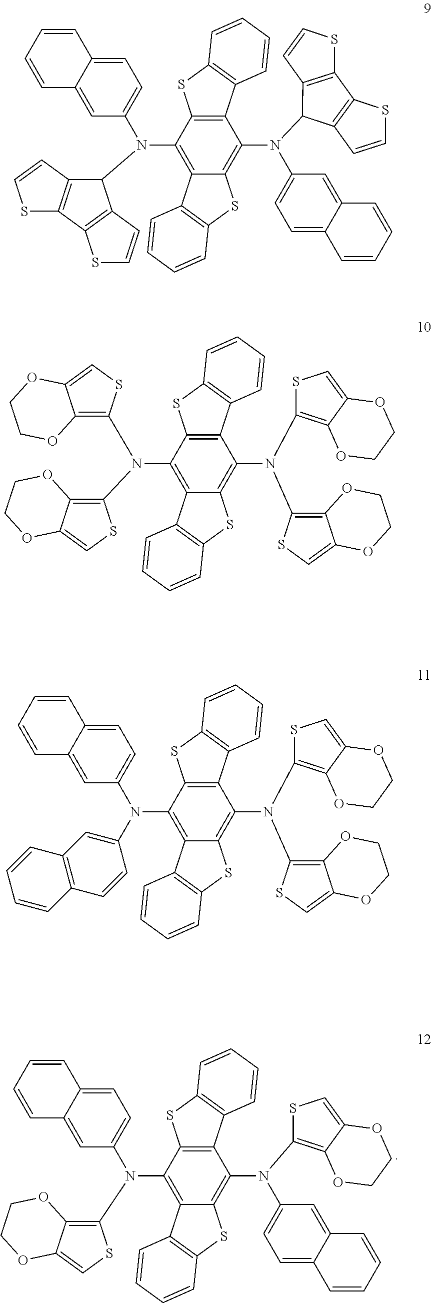 [SMILES: c1ccc2cc(N(c3c4sc5ccccc5c4c(N(c4ccc5ccccc5c4)C4c5ccsc5-c5sccc54)c4sc5ccccc5c34)C3c4ccsc4-c4sccc43)ccc2c1 ; c1ccc2c(c1)sc1c(N(c3scc4c3OCCO4)c3scc4c3OCCO4)c3c(sc4ccccc43)c(N(c3scc4c3OCCO4)c3scc4c3OCCO4)c12 ; c1ccc2cc(N(c3ccc4ccccc4c3)c3c4sc5ccccc5c4c(N(c4scc5c4OCCO5)c4scc5c4OCCO5)c4sc5ccccc5c34)ccc2c1 ; c1ccc2cc(N(c3scc4c3OCCO4)c3c4sc5ccccc5c4c(N(c4ccc5ccccc5c4)c4scc5c4OCCO5)c4sc5ccccc5c34)ccc2c1]

In one or more embodiments, the capping layer CPL may have a density (e.g., a volumetric mass density) of about 1.0 g/cm³ to about 1.3 g/cm³. When the capping layer CPL is formed having a density within the above range, intermolecular conjugation may be optimized, and consequently, light extraction efficiency of the light emitting element ED may increase. The optimization of intermolecular conjugation will be described later.

In one or more embodiments, the capping layer CPL may have a thickness of about 100 Å to about 1000 Å. For example, in some embodiments, the capping layer CPL may have a thickness of about 300 Å to about 800 Å. When the capping layer CPL is formed having a thickness within the above range, the microcavity effect inside an element may be optimized. The microcavity effect will be described later.

In some embodiments, in the light emitting element ED, the capping layer CPL may further include an organic material or an inorganic material, in addition to the fused compound according to one or more embodiments described above. For example, in some embodiments, when the capping layer CPL further includes an inorganic material, the inorganic material may include an alkali metal compound such as LiF, an alkaline earth metal compound such as MgF₂, SiON, SiNx, SiO_{y}, etc.

For example, in some embodiments, when the capping layer CPL further includes an organic material, the organic material may include α-NPD, NPB, TPD, m-MTDATA, Alq₃ Cu Pc, N4,N4,N4′,N4′-tetra(biphenyl-4-yl) biphenyl-4,4′-diamine (TPD15), 4,4′,4″-tris(carbazol-9-yl)triphenylamine (TCTA), etc., or may include epoxy resins or acrylates such as methacrylates. However, embodiments of the present disclosure are not limited thereto, and the capping layer CPL may further include at least one selected from compounds P1 to P5.

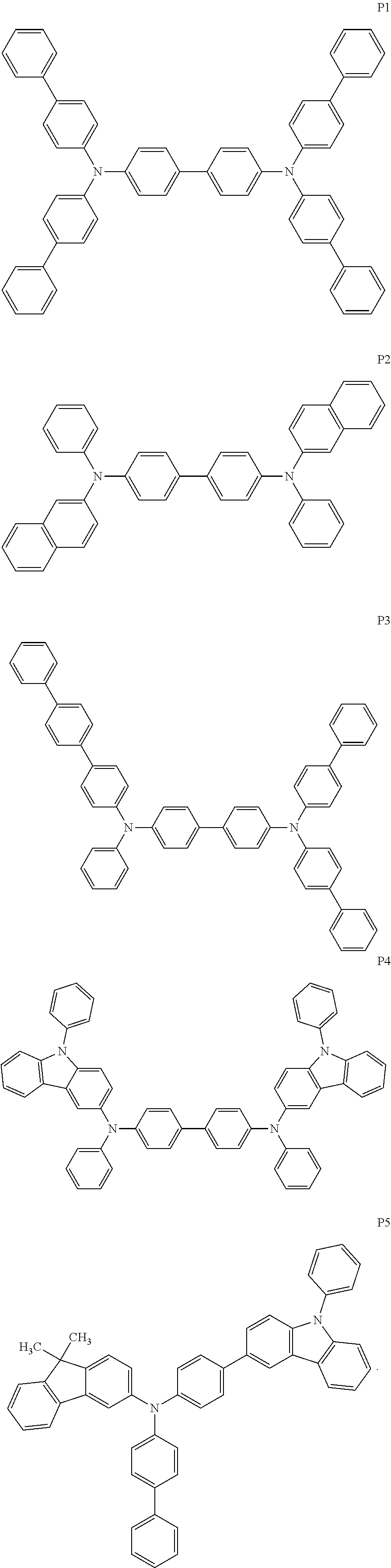 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1 ; c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

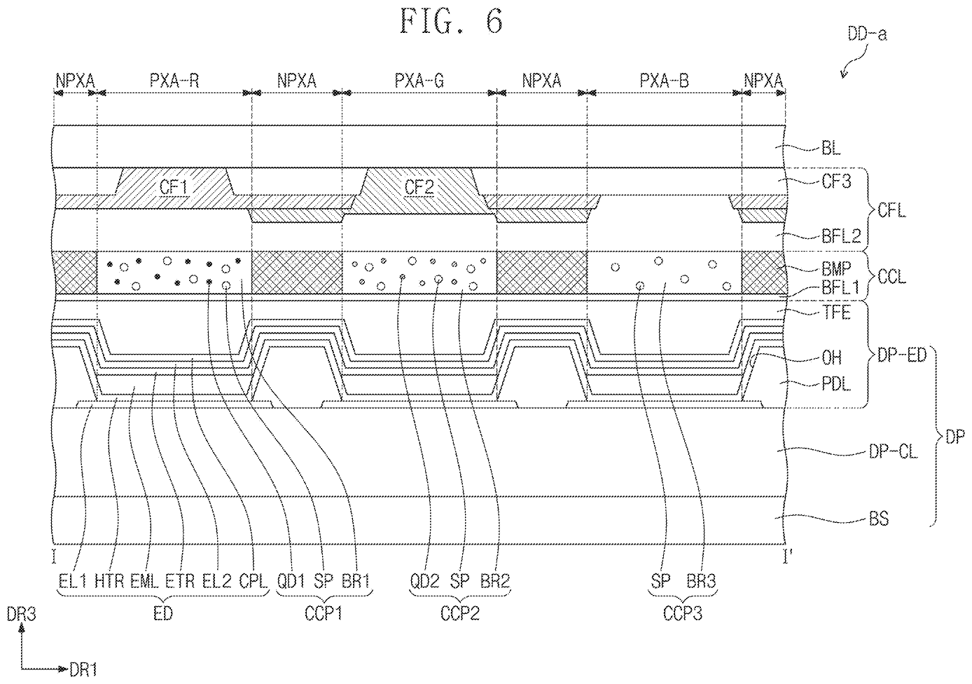

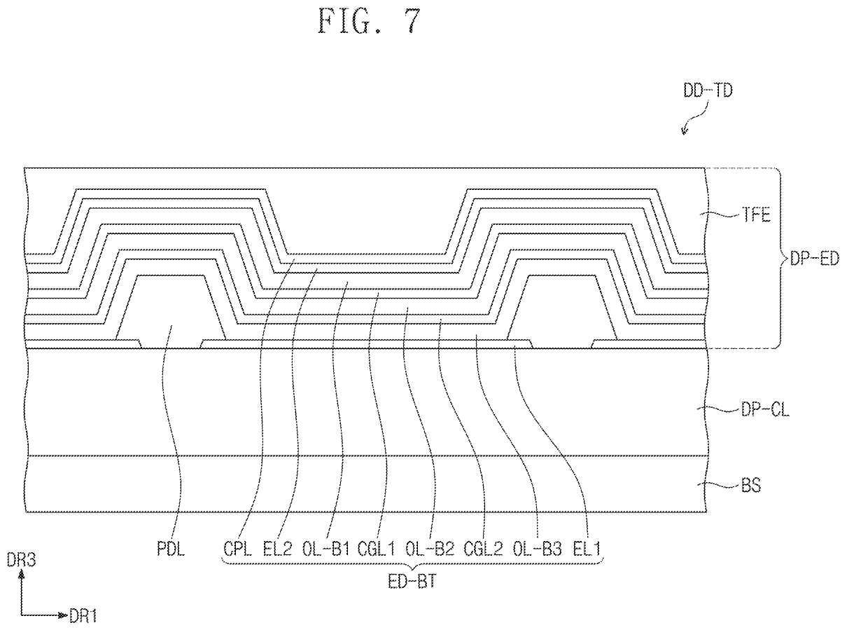

FIGS. 6 and 7 each are cross-sectional views of a display device according to one or more embodiments of the present disclosure. Hereinafter, in the description of the display device according to one or more embodiments with reference to FIGS. 6 and 7, content and features overlapping the one described above with reference to FIGS. 1 to 5 will not be described again for conciseness, and the differences will be mainly described.

Referring to FIG. 6, a display device DD-a according to one or more embodiments may include a display panel DP having a display element layer DP-ED, a light control layer CCL disposed on the display panel DP, and a color filter layer CFL.

In one or more embodiments shown in FIG. 6, the display panel DP may include a base layer BS, a circuit layer DP-CL provided on the base layer BS, and a display element layer DP-ED, and the display element layer DP-ED may include a light emitting element ED.

The light emitting element ED may include a first electrode EL1, a hole transport region HTR disposed on the first electrode EL1, an emission layer EML disposed on the hole transport region HTR, an electron transport region ETR disposed on the emission layer EML, a second electrode EL2 disposed on the electron transport region ETR, and a capping layer CPL disposed on the second electrode EL2. In some embodiments, a structure of the light emitting element ED shown in FIG. 6 may be substantially the same as the structure of the light emitting element ED of FIGS. 3 to 5 described above.

The capping layer CPL of the light emitting element ED included in a display device DD-a according to one or more embodiments may include the fused compound according to one or more embodiments described above.

Referring to FIG. 6, the emission layers EML may be disposed in openings OH defined in pixel defining films PDL. For example, the emission layers EML separated by the pixel defining films PDL and provided corresponding to each of light emitting regions PXA-R, PXA-G, and PXA-B may be to emit light in substantially the same wavelength ranges. In some embodiments, the emission layer EML may be provided as a common layer throughout the light emitting regions PXA-R, PXA-G, and PXA-B.

The light control layer CCL may be disposed on the display panel DP. The light control layer CCL may include a light converter. The light converter may be quantum dots or phosphors. The light converter may wavelength-convert the provided light and emit the wavelength-converted light. For example, the light control layer CCL may be a layer containing quantum dots or phosphors.

The light control layer CCL may include a plurality of light control units CCP1, CCP2, and CCP3. The light control units CCP1, CCP2, and CCP3 may be spaced apart from each other.

Referring to FIG. 6, a division pattern BMP may be disposed between the light control units CCP1, CCP2, and CCP3 spaced apart from each other, but embodiments of the present disclosure are not limited thereto. In FIG. 6, the division pattern BMP is shown to non-overlap the light control units CCP1, CCP2, and CCP3, but edges of the light control units CCP1, CCP2, and CCP3 may overlap at least a portion of the division pattern BMP.

The light control layer CCL may include a first light control unit CCP1 including a first quantum dot QD1 for converting first color light provided from the light emitting element ED into second color light, a second light control unit CCP2 including a second quantum dot QD2 for converting the first color light into third color light, and a third light control unit CCP3 transmitting the first color light.

In one or more embodiments, the first light control unit CCP1 may provide red light, which is the second color light, and the second light control unit CCP2 may provide green light, which is the third color light. The third light control unit CCP3 may be to transmit and provide blue light, which is the first color light provided from the light emitting element ED. For example, in some embodiments, the first quantum dot QD1 may be a red quantum dot to emit red light and the second quantum dot QD2 may be a green quantum dot to emit green light. The same descriptions above may be applied to the quantum dots QD1 and QD2.

In some embodiments, the light control layer CCL may further include scatterers SP. The first light control unit CCP1 may include the first quantum dot QD1 and the scatterers SP, the second light control unit CCP2 may include the second quantum dot QD2 and the scatterers SP, and the third light control unit CCP3 may not include (e.g., may exclude) a quantum dot but may include the scatterers SP.

The scatterers SP may be inorganic particles. For example, the scatterers SP may include at least one selected from among TiO₂, ZnO, Al₂O₃, SiO₂, and hollow silica. The scatterers SP may include any one selected from among TiO₂, ZnO, Al₂O₃, SiO₂, and hollow silica, or may be a mixture of two or more materials selected from TiO₂, ZnO, Al₂O₃, SiO₂, and hollow silica.

The first light control unit CCP1, the second light control unit CCP2, and the third light control unit CCP3 may respectively include base resins BR1, BR2, and BR3 for dispersing the quantum dots QD1 and QD2 and the scatterers SP. In one or more embodiments, the first light control unit CCP1 may include the first quantum dot QD1 and the scatterers SP dispersed in the first base resin BR1, the second light control unit CCP2 may include the second quantum dot QD2 and the scatterers SP dispersed in the second base resin BR2, and the third light control unit CCP3 may include the scatterers SP dispersed in the third base resin BR3.

The base resins BR1, BR2, and BR3 are a medium in which the quantum dots QD1 and QD2 and the scatterers SP are dispersed, and may be formed of one or more suitable resin compositions, which may be generally referred to as a binder. For example, the base resins BR1, BR2, and BR3 may be an acrylic-based resin, a urethane-based resin, a silicone-based resin, an epoxy-based resin, etc. The base resins BR1, BR2, and BR3 may be a transparent resin. In one or more embodiments, the first base resin BR1, the second base resin BR2, and the third base resin BR3 may each be the same as or different from each other.

The light control layer CCL may include a barrier layer BFL1. The barrier layer BFL1 may serve to prevent or reduce moisture and/or oxygen (hereinafter referred to as “moisture/oxygen”) from being introduced. The barrier layer BFL1 may be disposed on the light control units CCP1, CCP2, and CCP3 to prevent or reduce the light control units CCP1, CCP2, and CCP3 from being exposed to moisture/oxygen. In some embodiments, the barrier layer BFL1 may cover the light control units CCP1, CCP2, and CCP3. In some embodiments, a barrier layer BFL2 may be provided between the light control units CCP1, CCP2, and CCP3 and filters CF1, CF2, and CF3.

The barrier layers BFL1 and BFL2 may include at least one inorganic layer. For example, the barrier layers BFL1 and BFL2 may be formed of an inorganic material. For example, in some embodiments, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide, silicon oxynitride, or a thin metal film in which light transmittance is secured, etc. In some embodiments, the barrier layers BFL1 and BFL2 may further include an organic film. The barrier layers BFL1 and BFL2 may be formed of a single layer or a plurality of layers.

In one or more embodiments, in the display device DD-a, the color filter layer CFL may be disposed on the light control layer CCL. For example, in one embodiment, the color filter layer CFL may be directly disposed on the light control layer CCL. In this embodiment, the barrier layer BFL2 may not be provided.

The color filter layer CFL may include a light blocking unit BM and filters CF1, CF2, and CF3. For example, in some embodiments, the color filter layer CFL may include a first filter CF1 transmitting second color light, a second filter CF2 transmitting third color light, and a third filter CF3 transmitting first color light. For example, the first filter CF1 may be a red filter, the second filter CF2 may be a green filter, and the third filter CF3 may be a blue filter. The filters CF1, CF2, and CF3 may each include a polymer photosensitive resin, a pigment, and/or a dye. The first filter CF1 may include a red pigment and/or a red dye, the second filter CF2 may include a green pigment and/or a green dye, and the third filter CF3 may include a blue pigment and/or a blue dye. However, embodiments of the present disclosure are not limited thereto, for example, in some embodiments, the third filter CF3 may not include (e.g., may exclude) a pigment or a dye. The third filter CF3 may include a polymer photosensitive resin, but not include a pigment or a dye. The third filter CF3 may be transparent. In some embodiments, the third filter CF3 may be formed of a transparent photosensitive resin.

In one or more embodiments, the first filter CF1 and the second filter CF2 may be yellow filters. The first filter CF1 and the second filter CF2 may not be separated and may be provided as a single body. The first to third filters CF1, CF2, and CF3 may be disposed corresponding to the red light emitting region PXA-R, the green light emitting region PXA-G, and the blue light emitting region PXA-B, respectively.

In some embodiments, although not shown, the color filter layer CFL may include a light blocking unit. The color filter layer CFL may include the light blocking unit disposed to overlap the boundaries of the neighboring filters CF1, CF2, and CF3. The light blocking unit may be a black matrix. The light blocking unit may be formed by including an organic light blocking material or an inorganic light blocking material, both (e.g., simultaneously) including a black pigment or a black dye. The light blocking unit may separate boundaries between the adjacent filters CF1, CF2, and CF3. In one or more embodiments, the light blocking unit may be formed of a blue filter.

The base substrate BL may be disposed on the color filter layer CFL. The base substrate BL may be a member providing a base surface on which the color filter layer CFL and the light control layer CCL are disposed. The base substrate BL may be a glass substrate, a metal substrate, a plastic substrate, etc. However, embodiments of the present disclosures are not limited thereto, and the base substrate BL may be an inorganic layer, an organic layer, or a composite material layer. In some embodiments, the base substrate BL may not be provided.

FIG. 7 is a cross-sectional view showing a portion of a display device DD-TD according to one or more embodiments of the present disclosure. In a display device DD-TD according to one or more embodiments, a light emitting element ED-BT may include a plurality of light emitting structures OL-B1, OL-B2, and OL-B3. The light emitting element ED-BT may include a first electrode EL1 and a second electrode EL2 facing each other, the plurality of light emitting structures OL-B1, OL-B2, and OL-B3 provided by being sequentially stacked in a thickness direction between the first electrode EL1 and the second electrode EL2, and a capping layer CPL disposed on the second electrode EL2. The light emitting structures OL-B1, OL-B2, and OL-B3 each may include an emission layer EML (FIG. 6), a hole transport region HTR, and an electron transport region ETR, disposed with the emission layer EML (FIG. 6) therebetween.

For example, in some embodiments, the light emitting element ED-BT included in the display device DD-TD may be a light emitting element having a tandem structure including a plurality of emission layers.

In one or more embodiments shown in FIG. 7, light emitted from each of the light emitting structures OL-B1, OL-B2, and OL-B3 may all be blue light. However, embodiments of the present disclosure are not limited thereto, and wavelength ranges of light emitted from each of the light emitting structures OL-B1, OL-B2, and OL-B3 may be different from each other. For example, in some embodiments, the light emitting element ED-BT including the plurality of light emitting structures OL-B1, OL-B2, and OL-B3 emitting light in different wavelength ranges may be to emit white light (e.g., combined white light).

A charge generation layer CGL (e.g., CGL1, CGL2) may be disposed between neighboring light emitting structures OL-B1, OL-B2, and OL-B3. The charge generation layer CGL may include a p-type or kind charge (e.g., P-charge) generation layer and/or an n-type or kind charge (e.g., N-charge) generation layer.

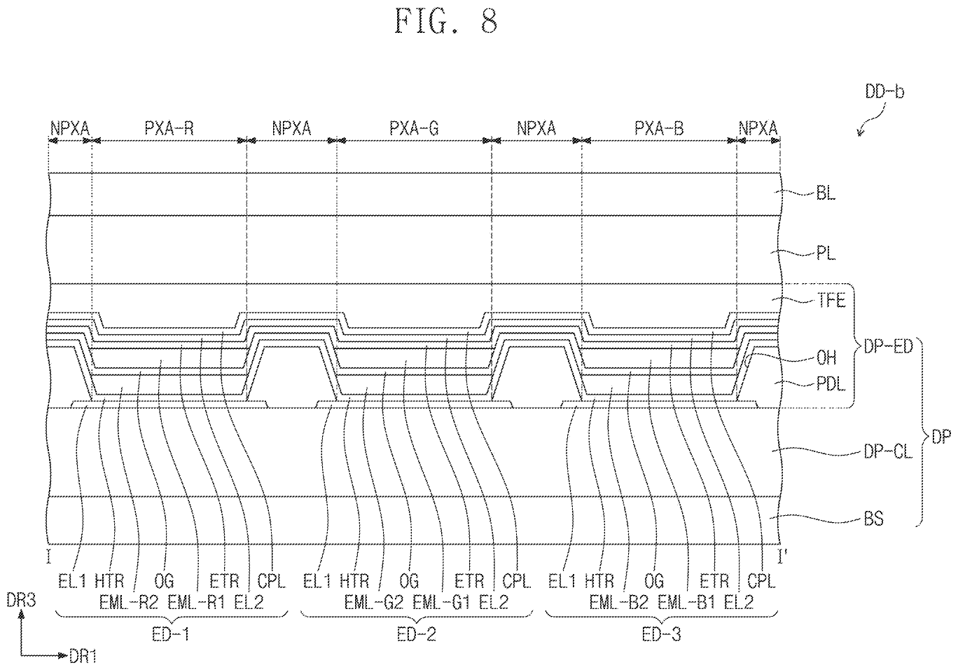

Referring to FIG. 8, a display device DD-b according to one or more embodiments of the present disclosure may include light emitting elements ED-1, ED-2, and ED-3 in which two emission layers are stacked. Compared to the display device DD shown in FIG. 2, the difference is that in the display device DD-b shown in FIG. 8, the first to third light emitting elements ED-1, ED-2, and ED-3 each include two emission layers stacked in a thickness direction. In each of the first to third light emitting elements ED-1, ED-2, and ED-3, the two emission layers may be to emit light in substantially the same wavelength range.

The first light emitting element ED-1 may include a first red emission layer EML-R₁ and a second red emission layer EML-R₂. The second light emitting element ED-2 may include a first green emission layer EML-G1 and a second green emission layer EML-G2. In addition, the third light emitting element ED-3 may include a first blue emission layer EML-B1 and a second blue emission layer EML-B2. A light emitting auxiliary portion OG may be disposed between the first red emission layer EML-R1 and the second red emission layer EML-R2, between the first green emission layer EML-G1 and the second green emission layer EML-G2, and between the first blue emission layer EML-B1 and the second blue emission layer EML-B2.

The light emitting auxiliary portion OG may include a single layer or a plurality of layers. The light emitting auxiliary portion OG may include a charge generation layer. In some embodiments, the light emitting auxiliary portion OG may include an electron transport region, a charge generation layer, and a hole transport region that are sequentially stacked in the stated order. The light emitting auxiliary portion OG may be provided as a common layer throughout the first to third light emitting elements ED-1, ED-2, and ED-3. However, embodiments of the present disclosure are not limited thereto, and the light emitting auxiliary portion OG may be provided to be patterned inside the openings OH defined in the pixel defining films PDL.

The first red emission layer EML-R1, the first green emission layer EML-G1, and the first blue emission layer EML-B1 may be disposed between the hole transport region HTR and the emission auxiliary portion OG. The second red emission layer EML-R2, the second green emission layer EML-G2, and the second blue emission layer EML-B2 may be disposed between the emission auxiliary portion OG and the electron transport region ETR.

For example, in one or more embodiments, the light emitting element ED-1 may include the first electrode EL1, the hole transport region HTR, the second red emission layer EML-R2, the emission auxiliary portion OG, the first red emission layer EML-R₁, the electron transport region ETR, the second electrode EL2, and the capping layer CPL, which are sequentially stacked in the stated order. The second light emitting element ED-2 may include the first electrode EL1, the hole transport region HTR, the second green emission layer EML-G2, the emission auxiliary portion OG, the first green emission layer EML-G1, the electron transport region ETR, the second electrode EL2, and the capping layer CPL, which are sequentially stacked in the stated order. The third light emitting element ED-3 may include the first electrode EL1, the hole transport region HTR, the second blue emission layer EML-B2, the emission auxiliary portion OG, the first blue emission layer EML-B1, the electron transport region ETR, the second electrode EL2, and the capping layer CPL, which are sequentially stacked in the stated order.

In some embodiments, an optical auxiliary layer PL may be disposed on the display element layer DP-ED. The optical auxiliary layer PL may include a polarizing layer. The optical auxiliary layer PL may be disposed on the display panel DP to control reflected light in the display panel DP due to external light. In one or more embodiments, the optical auxiliary layer PL may not be provided in the display device.

In one or more embodiments, the capping layer CPL included in a display device DD-b shown in FIG. 8 may include the fused compound represented by Formula 1 described above.

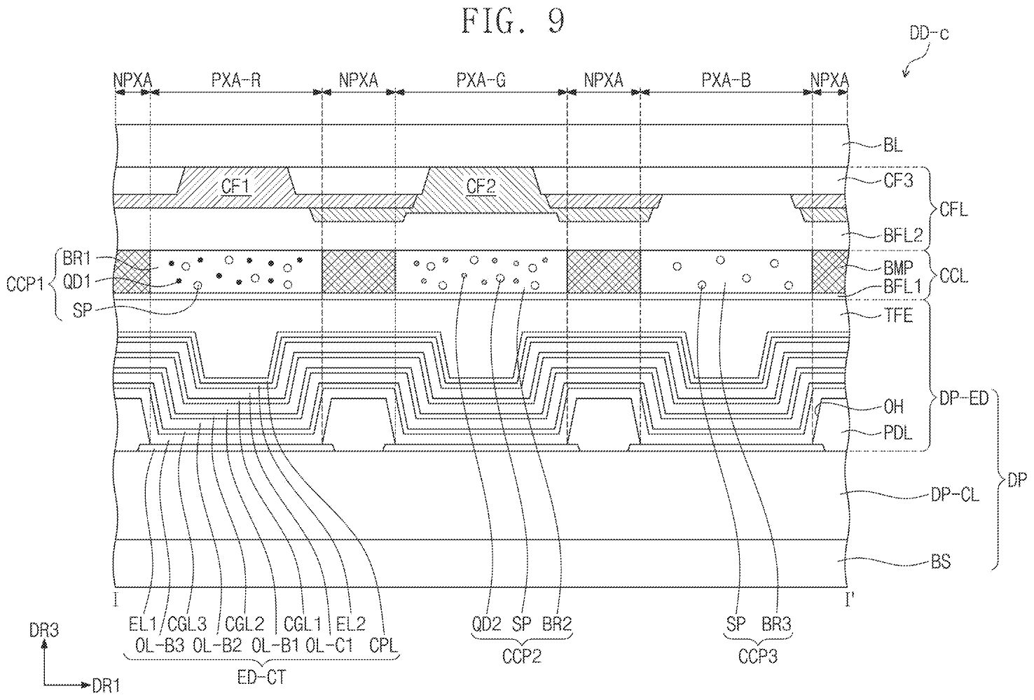

FIG. 9 is a cross-sectional view of a display device DD-c according to one or more embodiments of the present disclosure. Unlike the display devices shown in FIGS. 7 and 8, the display device DD-c of FIG. 9 is shown to include four light emitting structures OL-B1, OL-B2, OL-B3, and OL-C1. The light emitting element ED-CT may include a first electrode EL1 and a second electrode EL2 facing each other, the first to fourth light emitting structures L-B1, OL-B2, OL-B3, and OL-C1 sequentially stacked in a thickness direction between the first electrode EL1 and the second electrode EL2, and a capping layer CPL disposed on the second electrode EL2. Charge generation layers CGL1, CGL2, and CGL3 may be disposed between the first to fourth light emitting structures OL-B1, OL-B2, OL-B3, and OL-C1. In some embodiments, among the four light emitting structures, the first to third light emitting structures OL-B1, OL-B2, and OL-B3 may be to emit blue light, and the fourth light emitting structure OL-C1 may be to emit green light. However, embodiments of the present disclosure are not limited thereto, and the first to fourth light emitting structures OL-B1, OL-B2, OL-B3, and OL-C1 may be to emit light having different wavelength ranges.

The charge generation layers CGL1, CGL2, and CGL3 disposed between the neighboring light emitting structures OL-B1, OL-B2, OL-B3, and OL-C1 may include a p-type or kind charge generation layer and/or an n-type or kind charge generation layer.

In one or more embodiments, the capping layer CPL included in the display device DD-c may include the fused compound represented by Formula 1 described above.

The light emitting element ED according to one or more embodiments of the present disclosure includes the fused compound according to one or more embodiments described above in the capping layer CPL disposed on the second electrode EL2, and may thus exhibit increased light extraction efficiency.

In the light emitting element ED having a top emission structure, a portion of light generated from the emission layer EML may be reflected by one or more suitable interfaces present in the light emitting element ED and may be extracted to the outside of the element. When the reflected light that has undergone reflection is extracted by constructive interference, the light is amplified to increase light extraction efficiency (i.e., microcavity effect).

With respect to materials applied to the capping layer CPL, molecules with low intermolecular conjugation may have a low density of stacked molecules when applied to the capping layer CPL, even when the refractive index of a single molecule is high. For example, the refractive index of the capping layer CPL itself may be sharply decreased compared to the refractive index of a single molecule.

The fused compound according to one or more embodiments described above may include a 5-ring heterocyclic core in which a π-donating structure and a π-accepting structure are alternately disposed at both (e.g., simultaneously) sides of a benzene ring as a center. In addition, two substituents that are positioned para with respect to each other may be included in the benzene ring placed at the center of a core. Accordingly, when the fused compound according to one or more embodiments is utilized in the capping layer CPL, intermolecular conjugation may be increased, and stacking of molecules may be maximized or increased. For example, the density of molecules stacked in the capping layer CPL may be shown to be high, and a high-refractive capping layer CPL may be obtained.

Hereinafter, with reference to Examples and Comparative Examples, fused compounds according to one or more embodiments of the present disclosure and light emitting elements according to one or more embodiments of the present disclosure will be specifically described in more detail. In addition, Examples shown are illustrated only for the understanding of the present disclosure, and the scope of the present disclosure is not limited thereto.

### EXAMPLES

### 1. Synthesis of Fused Compounds

First, a process of synthesizing fused compounds according to one or more embodiments of the present disclosure will be described in more detail by presenting a process of synthesizing Compounds 1, 6, 7, and 11 as an example. In addition, a process of synthesizing fused compounds, which will be described hereinafter, is provided as an example, and thus a process of synthesizing fused compounds according to one or more embodiments of the present disclosure is not limited to Examples.

### (1) Synthesis of Compound 1

Compound 1 according to one or more embodiments may be synthesized according to, for example, Reaction Routes 1-1 and 1-2.

### 1) Synthesis of Intermediate benzo bis benzothiophene (BBBT)

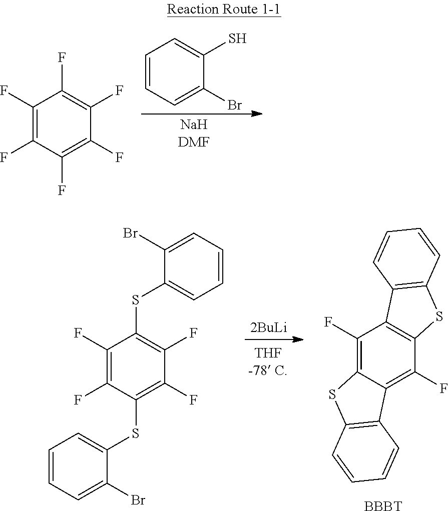

### 2) Synthesis of Compound 1

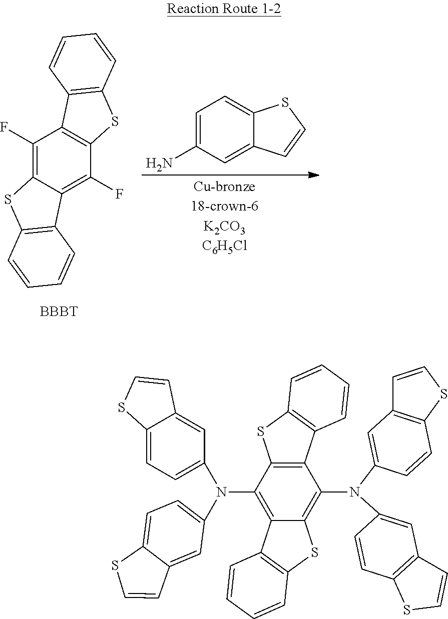

### (2) Synthesis of Compound 6

Compound 6 according to one or more embodiments may be synthesized according to, for example, Reaction Route 2.

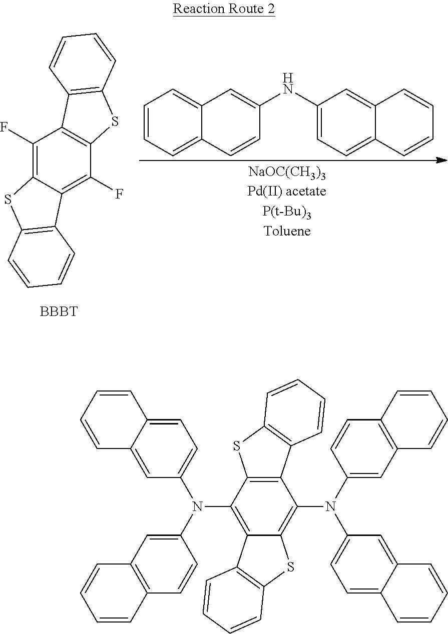

### (3) Synthesis of Compound 7

Compound 7 according to one or more embodiments may be synthesized according to, for example, Reaction Routes 3-1 and 3-2.

### 1) Synthesis of Intermediate cyclopenta dithiophene amine

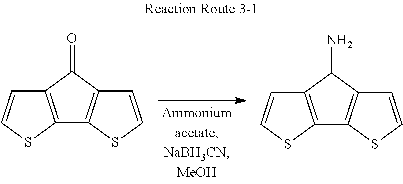 [SMILES: O=C1c2ccsc2-c2sccc21 ; NC1c2ccsc2-c2sccc21]

### 2) Synthesis of Compound 7

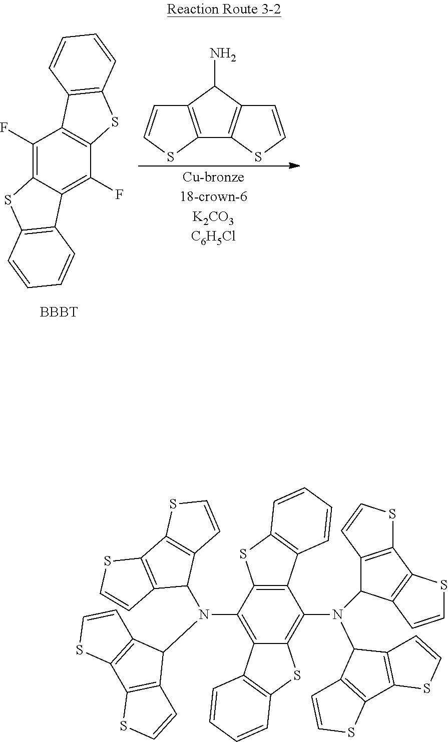

### (4) Synthesis of Compound 11

Compound 11 according to one or more embodiments may be synthesized according to, for example, Reaction Route 4.

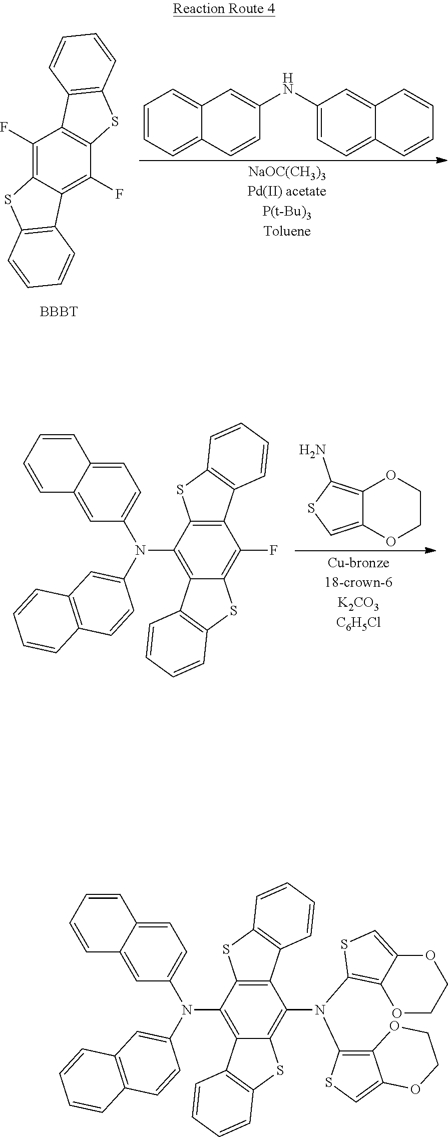

### 2. Monomolecular Refractive Index and Density of Fused Compounds

The monomolecular refractive index of each of the fused compounds according to one and more embodiments of the present disclosure and the compounds of Comparative Examples was calculated by DFT (density functional theory) calculation using Gaussian 09. The density of each of the fused compounds according to one and more embodiments of the present disclosure and the compounds of Comparative Examples was calculated using Schrodinger's Molecular Dynamics (MD) SW. After applying molecular deposition and MD (NVT 500K, 1000ps), the densities were each calculated. For each of the fused compounds according to one and more embodiments of the present disclosure and the compounds of Comparative Examples, the monomolecular refractive index and density are shown in Table 1.

TABLE 1

| | Monomolecular | |
|---|---|---|
| | refractive index | Density |
| Compound | (530 nm) | (g/cm³) |
| Example Compound 1 | 2.034 | 1.159 |
| Example Compound 2 | 1.920 | 1.123 |
| Example Compound 3 | 1.898 | 1.104 |
| Example Compound 4 | 1.887 | 1.112 |
| Example Compound 5 | 1.897 | 1.139 |
| Example Compound 6 | 2.075 | 1.078 |
| Example Compound 7 | 1.764 | 1.222 |
| Example Compound 8 | 1.897 | 1.139 |
| Example Compound 9 | 1.875 | 1.125 |
| Example Compound 10 | 1.751 | 1.242 |
| Example Compound 11 | 1.907 | 1.157 |
| Example Compound 12 | 1.885 | 1.149 |
| Comparative Example | 2.049 | 1.141 |
| Compound C1 | | |
| Comparative Example | 2.024 | 0.963 |
| Compound C2 | | |
| Comparative Example | 2.099 | 0.837 |
| Compound C3 | | |

Referring to Table 1, the monomolecular refractive indices of Example Compounds 1 to 12 according to one or more embodiments of the present disclosure are similar to those of Comparative Example Compounds C1 to C3. However, densities of Example Compounds 1 to 12 according to one or more embodiments of the present disclosure after stacking tend to be generally higher than the densities of Comparative Example Compounds C1 to C3. To be specific, the densities of Example Compounds 1 to 12 according to one or more embodiments of the present disclosure after stacking are higher than the densities of Comparative Example Compounds C2 and C3 after stacking. In addition, the density of Example Compound 1 after stacking is higher than the density of Comparative Example Compound C1, which has the same substituent, after stacking.

Comparative Example Compound C1 is a compound in which the substituent is the same, but the core is different as the number of rings constituting the core is three compared to Example Compound 1. Even when the substituent is the same, it is seen that the density of the fused compound according to one or more embodiments of the present disclosure after stacking is shown to be higher than the density of Comparative Example Compound.

As described above, even for molecules having a similar monomolecular refractive index, a high-refractive capping layer CPL may be obtained as the molecules have a greater density. Accordingly, even when the monomolecular refractive indices of Example Compounds 1 to 12 are similar to the monomolecular refractive indices of Comparative Example Compounds C1 to C3, it is believed that the refractive index of a capping layer composed of Example Compound selected from 1 to 12 is higher than that of a capping layer composed of Comparative Example Compound selected from C1 to C3 when the capping layer is formed by stacking each compound. Accordingly, it is believed that when the fused compound according to one or more embodiments of the present disclosure is included in a capping layer, a high-refractive capping layer may be obtainable.

### 3. Manufacture and Evaluation of Light Emitting Elements Including a Fused Compound

### (1) Manufacture of Light Emitting Elements

Light emitting elements according to one or more embodiments including a fused compound according to one or more embodiments in a capping layer were manufactured utilizing a method described below. Light emitting elements of Examples 1 to 7 were manufactured utilizing fused compounds of Compounds 1, 6, 7, and 11, which are Example Compounds described above, as a capping layer material. Comparative Examples 1 and 4 correspond to light emitting elements manufactured utilizing Comparative Example Compounds C1 to C3 as a capping layer material.

### Example Compounds

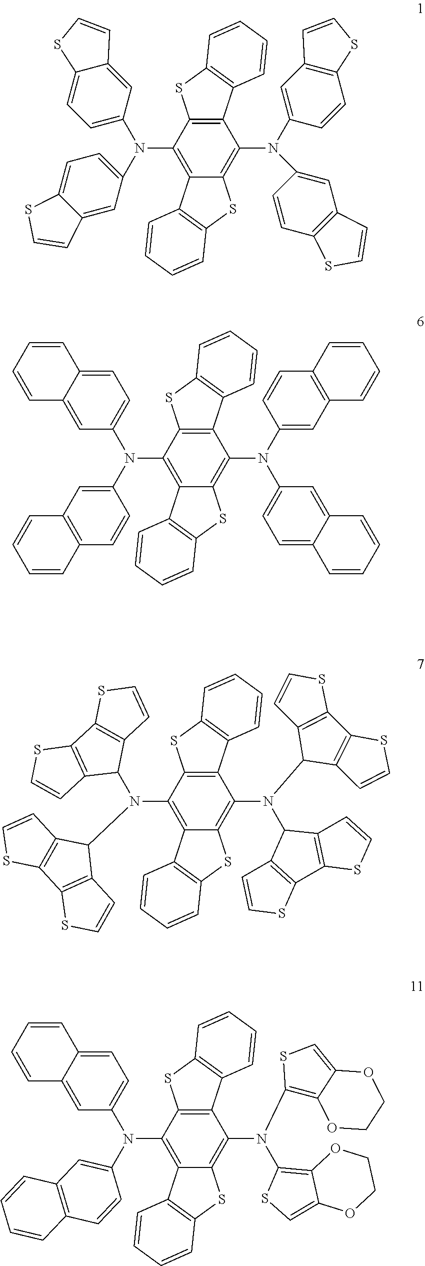 [SMILES: c1ccc2c(c1)sc1c(N(c3ccc4sccc4c3)c3ccc4sccc4c3)c3c(sc4ccccc43)c(N(c3ccc4sccc4c3)c3ccc4sccc4c3)c12 ; c1ccc2cc(N(c3ccc4ccccc4c3)c3c4sc5ccccc5c4c(N(c4ccc5ccccc5c4)c4ccc5ccccc5c4)c4sc5ccccc5c34)ccc2c1 ; c1ccc2c(c1)sc1c(N(C3c4ccsc4-c4sccc43)C3c4ccsc4-c4sccc43)c3c(sc4ccccc43)c(N(C3c4ccsc4-c4sccc43)C3c4ccsc4-c4sccc43)c12 ; c1ccc2cc(N(c3ccc4ccccc4c3)c3c4sc5ccccc5c4c(N(c4scc5c4OCCO5)c4scc5c4OCCO5)c4sc5ccccc5c34)ccc2c1]

### 1) Light Emitting Element Manufacturing Example 1

An ITO-formed glass substrate was cut into a size of about 50 mm×50 mm×0.7 mm, subjected to ultrasonic cleaning utilizing isopropyl alcohol and pure water for 5 minutes each and ultraviolet irradiation for 30 minutes, and then exposed to ozone for cleaning to form a first electrode which was then installed in a vacuum deposition apparatus.

H-1-19 was utilized to form a hole transport layer having a thickness of 200 Å on the first electrode, and CzSi was vacuum deposited on the hole transport layer to form a light emitting auxiliary layer having a thickness of 100 Å.

On the light emitting auxiliary layer, HT1 as a hole transporting host, ETH85 as an electron transporting host, and AD-39 as a dopant were each vacuum deposited in a weight ratio of 45:45:10 to form an emission layer having a thickness of 200 Å.

BUF was utilized to form a buffer layer having a thickness of 200 Å on the emission layer, and LiQ and ET37 were vacuum deposited at a ratio of 5:5 on the buffer layer to form an electron transport layer having a thickness of 300 Å. Thereafter, Y_{b} having a thickness of 13 Å was vacuum deposited on the electron transport layer, and then Ag and Mg were vacuum deposited to form a second electrode having a thickness of 105 Å.

Thereafter, Example Compounds or Comparative Example Compounds shown in Table 2 were vacuum deposited on the second electrode to form a capping layer having a thickness of 700 Å, thereby manufacturing an organic light emitting element.

### 2) Light Emitting Element Manufacturing Example 2

Except for utilizing AD-40 instead of AD-39 as a dopant of an emission layer and utilizing Example Compounds or Comparative Example Compounds shown in Table 3 for a capping layer, the rest of the manufacturing process is substantially the same as in the light emitting element example 1.

The compounds utilized in the manufacture of the light emitting elements of Examples and Comparative Examples are as follows. The following materials were utilized for the manufacture of the light emitting elements after sublimation-purifying commercially available products.

### Comparative Example Compounds

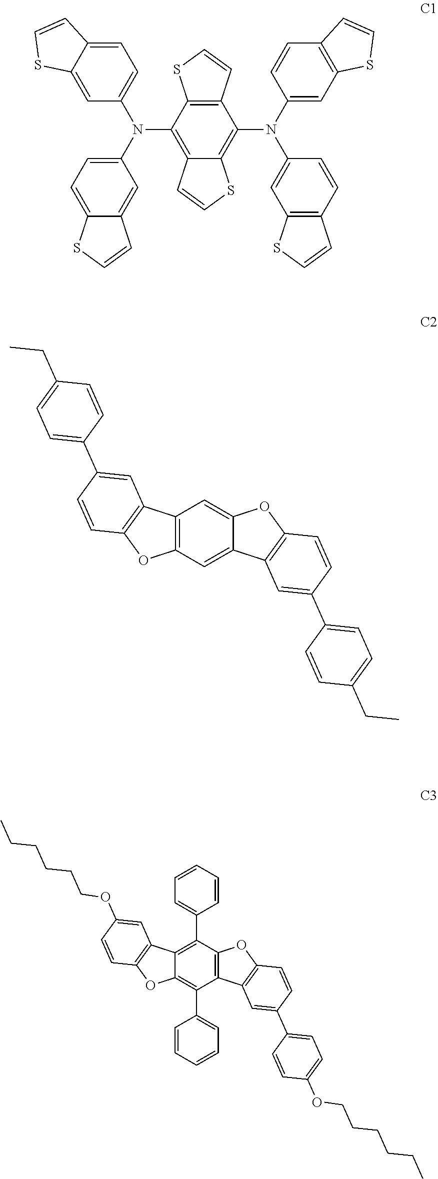

### Functional Layer Compound

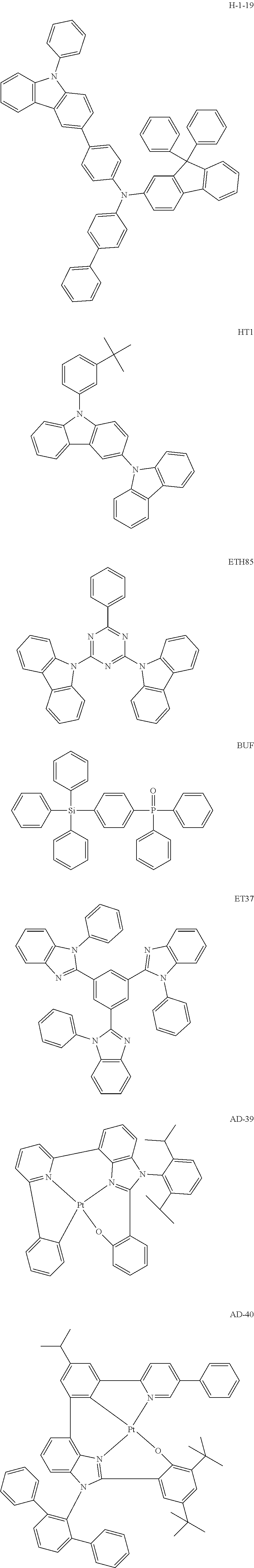

### (2) Characteristics Evaluation of Light Emitting Elements

Table 2 shows evaluation on characteristics of light emitting elements of Examples 1 to 4 and Comparative Example 1. The light emitting elements of Examples 1 to 4 and Comparative Example 1 were manufactured according to the light emitting element manufacturing example 1.

Table 3 shows evaluation on characteristics of light emitting elements of Examples 5 to 7 and Comparative Example 4. The light emitting elements of Examples 5 to 7 and Comparative Example 4 were manufactured according to the light emitting element manufacturing example 2.

Tables 2 and 3 show frontal efficiency, lateral efficiency, and light emitting color each measured utilizing the flat panel display (FPD) Performance Measurement System (FPMS, SR-UL2). As for the frontal efficiency and the lateral efficiency, light extracted when a capping layer CPL was applied was described with respect to light extracted from an emission layer EML. The frontal efficiency is determined by measuring light in a direction perpendicular to a plane of an light emitting element, and the lateral efficiency is determined by measuring light in the direction of 45° to a plane of an light emitting element.

TABLE 2

| | Emission | | Frontal | Lateral | | |
|---|---|---|---|---|---|---|
| | layer | | efficiency | efficiency | | |
| | dopant | Capping layer | (0°) a.u. | (45°) a.u. | CIE(x) | CIE(y) |
| Example 1 | AD-39 | Example | 1.40 | 0.56 | 0.2594 | 0.7212 |
| | | Compound 1 | | | | |
| Example 2 | AD-39 | Example | 1.42 | 0.57 | 0.2599 | 0.7208 |
| | | Compound 6 | | | | |
| Example 3 | AD-39 | Example | 1.49 | 0.60 | 0.2597 | 0.7212 |
| | | Compound 7 | | | | |
| Example 4 | AD-39 | Example | 1.54 | 0.62 | 0.2598 | 0.7212 |
| | | Compound 11 | | | | |
| Comparative | AD-39 | Comparative | 1.39 | 0.56 | 0.2597 | 0.7208 |
| Example 1 | | Example | | | | |
| | | Compound C1 | | | | |
| Comparative | AD-39 | Comparative | 1.12 | 0.60 | 0.2599 | 0.7210 |
| Example 2 | | Example | | | | |
| | | Compound C2 | | | | |
| Comparative | AD-39 | Comparative | 1.02 | 0.62 | 0.2597 | 0.7208 |
| Example 3 | | Example | | | | |
| | | Compound C3 | | | | |

TABLE 3

| | Emission | | Frontal | Lateral | | |
|---|---|---|---|---|---|---|
| | layer | | efficiency | efficiency | | |
| | dopant | Capping layer | (0°) a.u. | (45°) a.u. | CIE(x) | CIE(y) |
| Example 5 | AD-40 | Example | 2.61 | 1.05 | 0.2600 | 0.7112 |
| | | Compound 1 | | | | |
| Example 6 | AD-40 | Example | 2.80 | 1.12 | 0.2599 | 0.7118 |
| | | Compound 7 | | | | |
| Example 7 | AD-40 | Example | 2.93 | 1.18 | 0.2599 | 0.7123 |
| | | Compound 11 | | | | |
| Comparative | AD-40 | Comparative | 2.54 | 1.02 | 0.2587 | 0.7118 |
| Example 4 | | Example | | | | |
| | | Compound C1 | | | | |
| Comparative | AD-40 | Comparative | 2.46 | 1.01 | 0.2598 | 0.7042 |
| Example 5 | | Example | | | | |
| | | Compound C2 | | | | |
| Comparative | AD-40 | Comparative | 2.41 | 1.02 | 0.2597 | 0.7035 |
| Example 6 | | Example | | | | |
| | | Compound C3 | | | | |

Referring to Tables 2 and 3, the light emitting elements of Examples 1 to 7 each including the fused compound according to one or more embodiments of the present disclosure in the capping layer exhibit excellent or suitable light extraction efficiency compared to the light emitting elements of Comparative Examples 1 and 6. For example, the light emitting elements of Examples 1 to 4 exhibit superior frontal efficiency to the light emitting elements of Comparative Examples 1 to 3. In addition, the light emitting elements of Examples 5 to 7 exhibit superior frontal efficiency and lateral efficiency to the light emitting elements of Comparative Examples 4 to 6.

As described above, the fused compound included in the capping layer of the light emitting element according to one or more embodiments of the present disclosure may include a 5-ring heterocyclic core in which π-donating and π-accepting structures are alternately disposed at both (e.g., simultaneously) sides of a benzene ring as a center. In addition, two substituents that are positioned para with respect to each other may be included in the benzene ring placed at the center of the core.

Consequently, intermolecular conjugation may be increased, and when the fused compound according to one or more embodiments is included in the capping layer CPL, stacking of molecules may be maximized or increased. For example, the density of molecules stacked in the capping layer may be shown to be high, and a high-refractive capping layer may be obtained.

Meanwhile, unlike the fused compound included in the capping layer according to one or more embodiments of the present disclosure, Comparative Example Compound C1 is a compound having a 3-ring core, in which π-donating and π-accepting structures are not alternately disposed at both (e.g., simultaneously) sides of a benzene ring of the core. In particular, Comparative Example Compound C1 has a structure that substituents are the same as Example Compound 1 except for the core. Accordingly, it is believed that although the monomolecular refractive index of Comparative Example Compound C1 is high, Comparative Example Compound C1 is stacked to have low intermolecular conjugation when applied as a capping layer of a light emitting element, so that the refractive index of the capping layer itself is lowered, and the light extraction efficiency is low.

In addition, Comparative Example Compound C2 is a compound including a substituent at a different position from the fused compound included in the capping layer according to one or more embodiments of the present disclosure. Accordingly, it is believed that although the monomolecular refractive index of Comparative Example Compound C2 is high, Comparative Example Compound C2 is stacked to have low intermolecular conjugation when applied as a capping layer of a light emitting element, so that the refractive index of the capping layer itself is lowered, and the light extraction efficiency is low.

Comparative Example Compound C3 is a compound including, along with a substituent at the same position, a substituent at a different position from the fused compound included in the capping layer according to one or more embodiments of the present disclosure. Accordingly, it is believed that although the monomolecular refractive index of Comparative Example Compound C3 is high, Comparative Example Compound C3 is stacked to have low intermolecular conjugation when applied as a capping layer of a light emitting element, so that the refractive index of the capping layer itself is lowered, and the light extraction efficiency is low.

A light emitting element according to one or more embodiments of the present disclosure includes a fused compound that has a 5-ring heterocyclic core in which π-donating and π-accepting structures are alternately disposed at both (e.g., simultaneously) sides of a benzene ring as a center in a capping layer, and has two substituents that are positioned para with respect to each other in the benzene ring placed at the center of the core. Consequently, the capping layer has high intermolecular conjugation, so that stacking of molecules is maximized or increased, thereby obtaining a high-refractive capping layer. For example, when the capping layer is formed by stacking the fused compounds of the present disclosure, a high-refractive capping layer may be obtained and light extraction efficiency of the light emitting element may be increased.

The light emitting element according to one or more embodiments of the present disclosure includes a fused compound exhibiting high density with maximized or increased stacking efficiency in the capping layer, and may thus obtain a high-refractive capping layer. Consequently, the light emitting element may have increased light efficiency.

A light emitting element according to one or more embodiments includes a high-refractive capping layer, and may thus exhibit high efficiency characteristics.

The present disclosure may be modified in many alternate forms, and thus certain specific embodiments have been exemplified in the drawings and described in more detail. It should be understood, however, that it is not intended to limit the present disclosure to the particular forms disclosed, but rather, is intended to cover all modifications, equivalents, and alternatives falling within the spirit and scope of the present disclosure.

In the present disclosure, singular expressions may include plural expressions unless the context clearly indicates otherwise.

Throughout the present disclosure, when a component such as a layer, a film, a region, or a plate is mentioned to be placed “on” another component, it will be understood that it may be directly on another component or that another component may be interposed therebetween. In some embodiments, “directly on” may refer to that there are no additional layers, films, regions, plates, etc., between a layer, a film, a region, a plate, etc. and the other part. For example, “directly on” may refer to two layers or two members are disposed without utilizing an additional member such as an adhesive member therebetween.

In the present disclosure, although the terms “first,” “second,” etc., may be utilized herein to describe one or more elements, components, regions, and/or layers, these elements, components, regions, and/or layers should not be limited by these terms. These terms are only utilized to distinguish one component from another component.

As utilized herein, the singular forms “a,” “an,” and “the” are intended to include the plural forms as well, unless the context clearly indicates otherwise. Further, the use of “may” when describing embodiments of the present disclosure refers to “one or more embodiments of the present disclosure”.

In the present disclosure, when particles are spherical, “diameter” indicates a particle diameter or an average particle diameter, and when the particles are non-spherical, the “diameter” indicates a major axis length or an average major axis length. The diameter (or size) of the particles may be measured utilizing a scanning electron microscope or a particle size analyzer. As the particle size analyzer, for example, HORIBA, LA-950 laser particle size analyzer, may be utilized. When the size of the particles is measured utilizing a particle size analyzer, the average particle diameter (or size) is referred to as D50. D50 refers to the average diameter (or size) of particles whose cumulative volume corresponds to 50 vol % in the particle size distribution (e.g., cumulative distribution), and refers to the value of the particle size corresponding to 50% from the smallest particle when the total number of particles is 100% in the distribution curve accumulated in the order of the smallest particle size to the largest particle size.

As utilized herein, the terms “substantially,” “about,” or similar terms are used as terms of approximation and not as terms of degree, and are intended to account for the inherent deviations in measured or calculated values that would be recognized by those of ordinary skill in the art. “About” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value.

Any numerical range recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein.

The light-emitting device, the display device, or any other relevant devices or components according to embodiments of the present disclosure described herein may be implemented utilizing any suitable hardware, firmware (e.g., an application-specific integrated circuit), software, or a combination of software, firmware, and hardware. For example, the various components of the device may be formed on one integrated circuit (IC) chip or on separate IC chips. Further, the various components of the device may be implemented on a flexible printed circuit film, a tape carrier package (TCP), a printed circuit board (PCB), or formed on one substrate. Further, the various components of the device may be a process or thread, running on one or more processors, in one or more computing devices, executing computer program instructions and interacting with other system components for performing the various functionalities described herein. The computer program instructions are stored in a memory which may be implemented in a computing device using a standard memory device, such as, for example, a random access memory (RAM). The computer program instructions may also be stored in other non-transitory computer readable media such as, for example, a CD-ROM, flash drive, or the like. Also, a person of skill in the art should recognize that the functionality of various computing devices may be combined or integrated into a single computing device, or the functionality of a particular computing device may be distributed across one or more other computing devices without departing from the scope of the embodiments of the present disclosure.

Although the present disclosure has been described with reference to some embodiments of the present disclosure, it will be understood that the present disclosure should not be limited to these embodiments, but one or more suitable changes and modifications can be made by those skilled in the art without departing from the spirit and scope of the present disclosure.

Accordingly, the technical scope of the present disclosure is not intended to be limited to the contents set forth in the detailed description of the specification, but is intended to be defined by the appended claims and equivalent thereof.

What is claimed is:

1. A light emitting element comprising:
a first electrode;
a second electrode facing the first electrode;
at least one functional layer between the first electrode and the second electrode; and
a capping layer on the second electrode and comprising a fused compound represented by Formula 1: 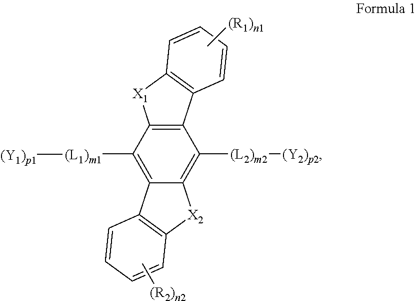
wherein, in Formula 1,
X₁ and X₂ are each independently S or O,
R₁ and R₂ are each independently hydrogen or deuterium,
n1 and n2 are each independently an integer of 0 to 4,
L₁ and L₂ are each independently a direct linkage or N,
m1 and m2 are each independently 0 or 1,
Y₁ and Y₂ are each independently a substituted or unsubstituted aryl group having 6 to 20 ring-forming carbon atoms, or a substituted or unsubstituted heteroaryl group having 2 to 20 ring-forming carbon atoms, and
p1 and p2 are each independently 1 or 2.

2. The light emitting element of claim 1, wherein the fused compound represented by Formula 1 is represented by any one selected from among Formulas 1-1a to 1-1c: 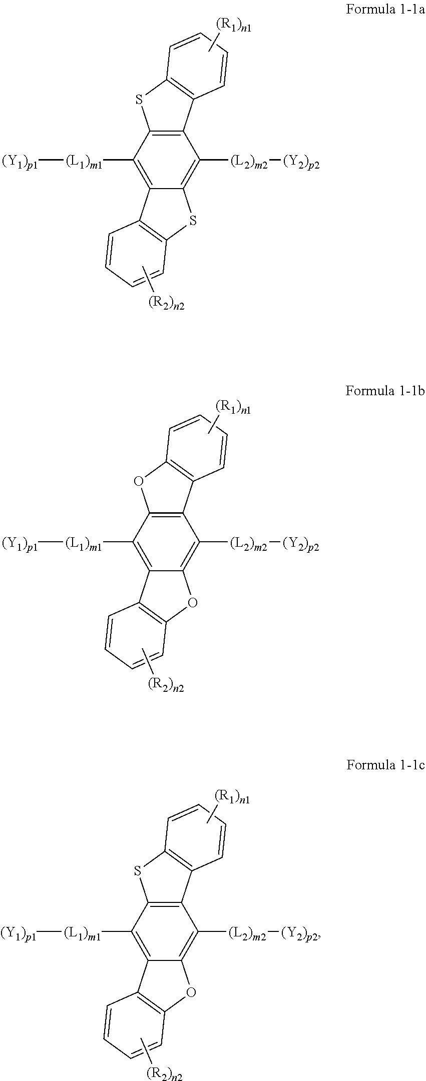
wherein, in Formulas 1-1a to 1-1c,
R₁, R₂, n1, n2, L₁, L₂, m1, m2, Y₁, Y₂, p1, and p2 are each the same as defined in Formula 1.

3. The light emitting element of claim 1, wherein the fused compound represented by Formula 1 is represented by Formula 1-2a or Formula 1-2b: 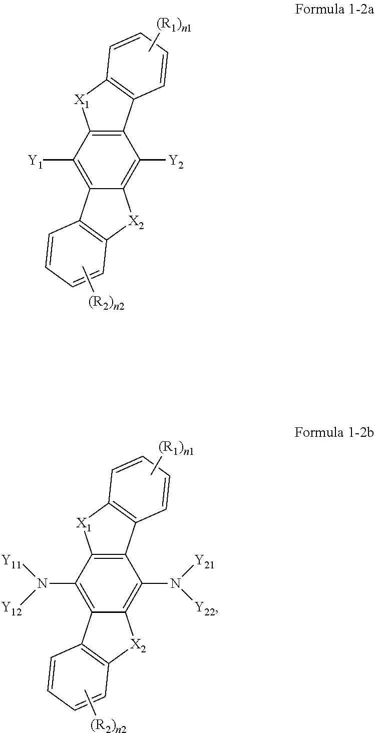
wherein, in Formulas 1-2a and 1-2b,
Y₁₁, Y₁₂, Y₂₁, and Y₂₂ are each independently a substituted or unsubstituted aryl group having 6 to 20 ring-forming carbon atoms, or a substituted or unsubstituted heteroaryl group having 2 to 20 ring-forming carbon atoms, and
X₁, X₂, R₁, R₂, n1, n2, Y₁, and Y₂ are each the same as defined in Formula 1.

4. The light emitting element of claim 1, wherein Y₁ and Y₂ are each independently a substituted or unsubstituted bicyclic or tricyclic aryl group, or a substituted or unsubstituted bicyclic or tricyclic heteroaryl group.

5. The light emitting element of claim 1, wherein Y₁ and Y₂ are each independently represented by any one selected from among Formulas 2-1 to 2-4: 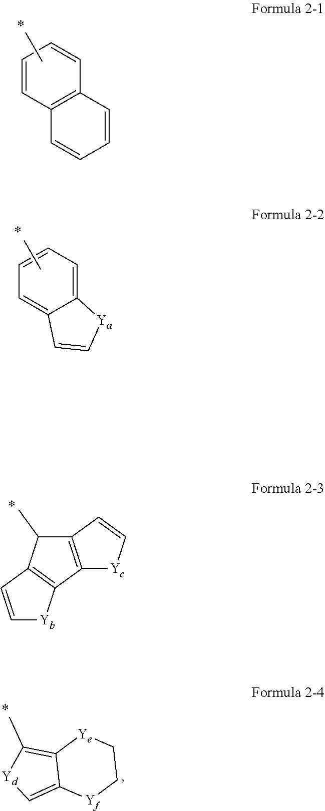
wherein, in Formulas 2-1 to 2-4,
Yₐ to Y_{f} are each independently S or O, and
“ [symbol] ” is a site connected to Formula 1.

6. The light emitting element of claim 1, wherein R₁ and R₂ are each hydrogen.

7. The light emitting element of claim 1, wherein the fused compound represented by Formula 1 comprises at least one selected from among the compounds of Compound Group 1:

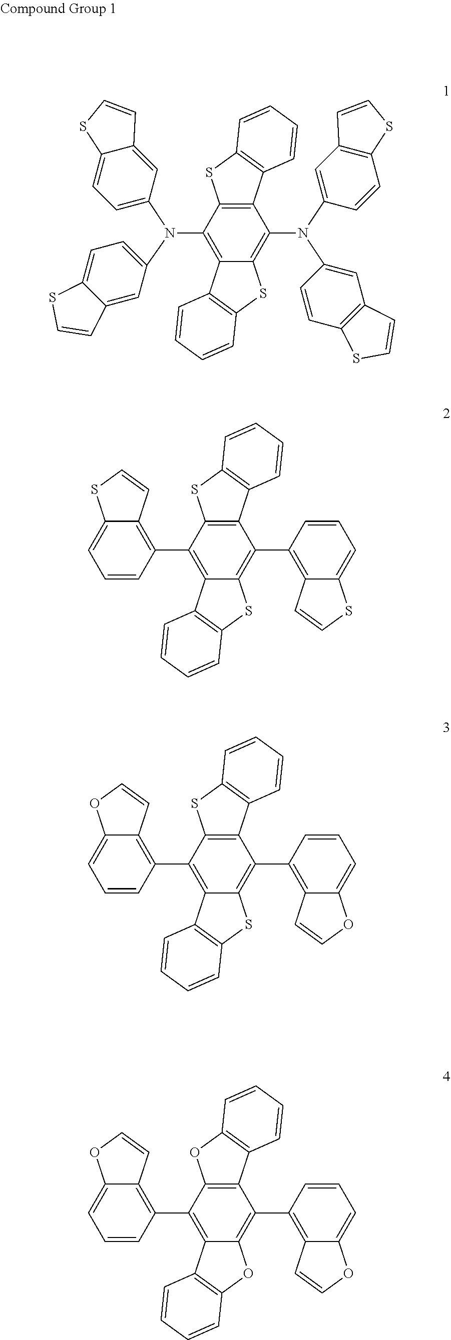 [SMILES: c1ccc2c(c1)sc1c(N(c3ccc4sccc4c3)c3ccc4sccc4c3)c3c(sc4ccccc43)c(N(c3ccc4sccc4c3)c3ccc4sccc4c3)c12 ; c1cc(-c2c3sc4ccccc4c3c(-c3cccc4sccc34)c3sc4ccccc4c23)c2ccsc2c1 ; c1cc(-c2c3sc4ccccc4c3c(-c3cccc4occc34)c3sc4ccccc4c23)c2ccoc2c1 ; c1cc(-c2c3oc4ccccc4c3c(-c3cccc4occc34)c3oc4ccccc4c23)c2ccoc2c1]

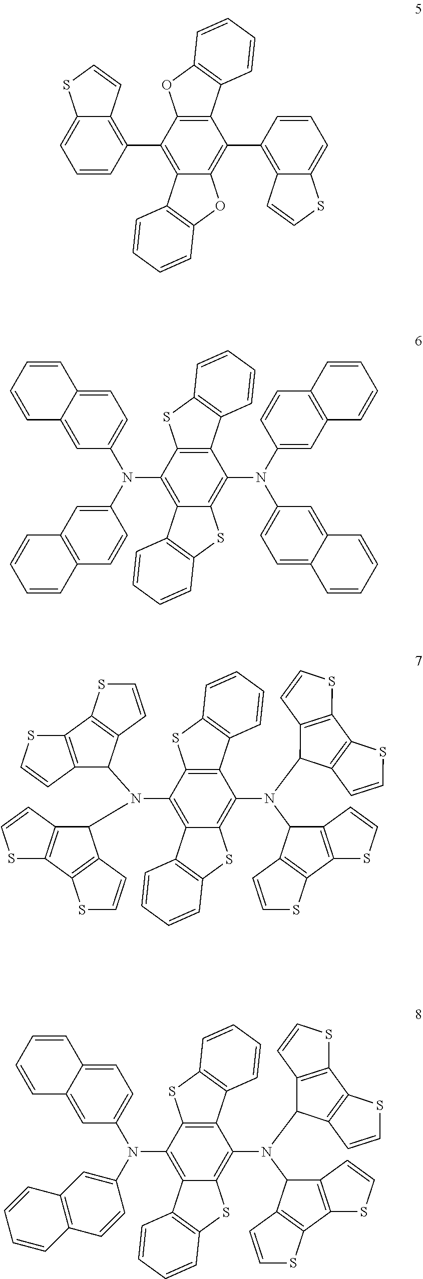 [SMILES: c1ccc2c(c1)oc1c(-c3cccc4sccc34)c3c(oc4ccccc43)c(-c3cccc4sccc34)c12 ; c1ccc2cc(N(c3ccc4ccccc4c3)c3c4sc5ccccc5c4c(N(c4ccc5ccccc5c4)c4ccc5ccccc5c4)c4sc5ccccc5c34)ccc2c1 ; c1ccc2c(c1)sc1c(N(C3c4ccsc4-c4sccc43)C3c4ccsc4-c4sccc43)c3c(sc4ccccc43)c(N(C3c4ccsc4-c4sccc43)C3c4ccsc4-c4sccc43)c12 ; c1ccc2cc(N(c3ccc4ccccc4c3)c3c4sc5ccccc5c4c(N(C4c5ccsc5-c5sccc54)C4c5ccsc5-c5sccc54)c4sc5ccccc5c34)ccc2c1]

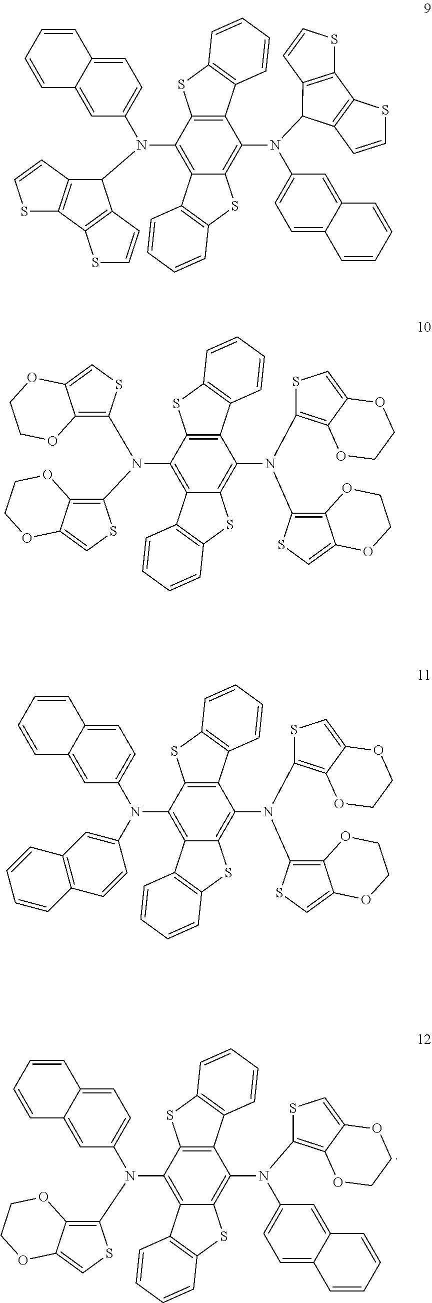 [SMILES: c1ccc2cc(N(c3c4sc5ccccc5c4c(N(c4ccc5ccccc5c4)C4c5ccsc5-c5sccc54)c4sc5ccccc5c34)C3c4ccsc4-c4sccc43)ccc2c1 ; c1ccc2c(c1)sc1c(N(c3scc4c3OCCO4)c3scc4c3OCCO4)c3c(sc4ccccc43)c(N(c3scc4c3OCCO4)c3scc4c3OCCO4)c12 ; c1ccc2cc(N(c3ccc4ccccc4c3)c3c4sc5ccccc5c4c(N(c4scc5c4OCCO5)c4scc5c4OCCO5)c4sc5ccccc5c34)ccc2c1 ; c1ccc2cc(N(c3scc4c3OCCO4)c3c4sc5ccccc5c4c(N(c4ccc5ccccc5c4)c4scc5c4OCCO5)c4sc5ccccc5c34)ccc2c1]

8. The light emitting element of claim 1, wherein the fused compound represented by Formula 1 has a monomolecular refractive index of about 1.7 to about 2.5 with respect to light having a wavelength of about 490 nm to about 570 nm.

9. The light emitting element of claim 1, wherein the capping layer has a density of about 1.0 g/cm³ to about 1.3 g/cm³.

10. The light emitting element of claim 1, wherein the capping layer has a thickness of about 100 Å to about 1000 Å.

11. The light emitting element of claim 1, wherein the at least one functional layer comprises an emission layer, a hole transport region between the first electrode and the emission layer, and an electron transport region between the emission layer and the second electrode,
the emission layer comprising a compound represented by Formula AD: 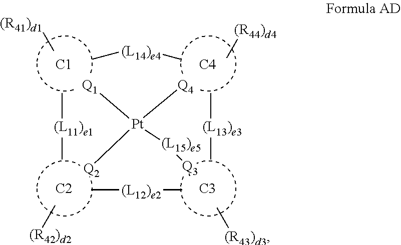
wherein, in Formula AD,
Q₁ to Q₄ are each independently C or N,
C1 to C4 are each independently a substituted or unsubstituted aromatic hydrocarbon ring having 5 to 30 ring-forming carbon atoms, or a substituted or unsubstituted aromatic heterocycle having 2 to 30 ring-forming carbon atoms,
L₁₁ to L₁₄ are each independently a direct linkage, 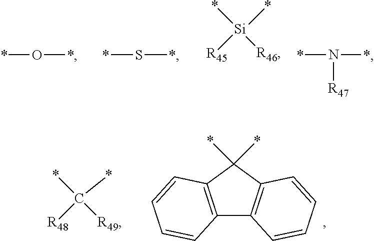
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “ [symbol] ” is a site connected to C1 to C4,
L₁₅ is a direct linkage or *—O—*, and in L₁₅, “ [symbol] ” is a site connected to Pt and C3,
e1 to e5 are each independently 0 or 1,
R₄₁ to R₄₉ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
d1 to d4 are each independently an integer of 0 to 4.

12. A light emitting element comprising:
a first electrode;
a second electrode facing the first electrode;
at least one functional layer between the first electrode and the second electrode; and
a capping layer on the second electrode and comprising a fused compound represented by Formula 3: 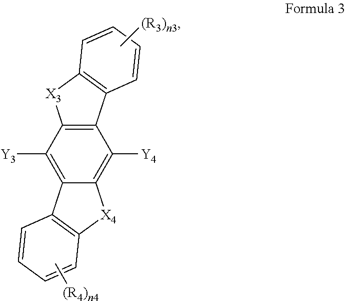
wherein, in Formula 3,
X₃ and X₄ are each independently S or O,
R₃ and R₄ are each independently hydrogen or deuterium,
n3 and n4 are each independently an integer of 0 to 4,
Y₃ and Y₄ are each independently *—NR₅R₆, a substituted or unsubstituted aryl group having 6 to 20 ring-forming carbon atoms, or a substituted or unsubstituted heteroaryl group having 2 to 20 ring-forming carbon atoms, and
R₅ and R₆ are each independently a substituted or unsubstituted aryl group having 6 to 20 ring-forming carbon atoms, or a substituted or unsubstituted heteroaryl group having 2 to 20 ring-forming carbon atoms.

13. The light emitting element of claim 12, wherein the fused compound represented by Formula 3 is represented by any one selected from among Formulas 3-1a to 3-1c: 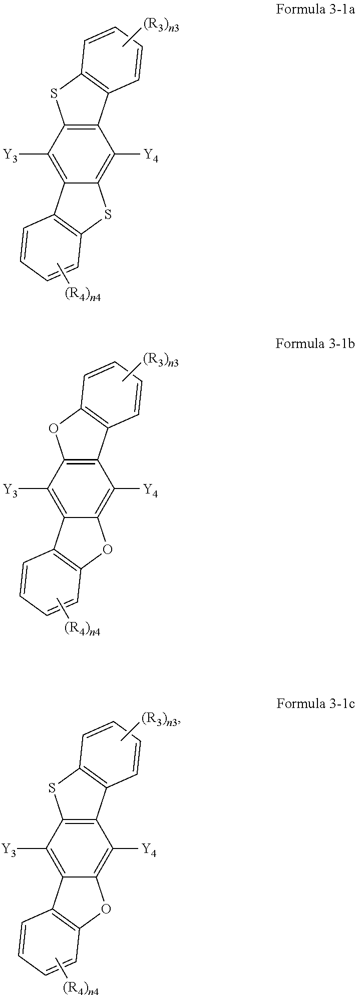
wherein, in Formulas 3-1a to 3-1c,
R₃, R₄, n3, n4, Y₃, and Y₄ are each the same as defined in Formula 3.

14. The light emitting element of claim 12, wherein Y₃ and Y₄ are each independently *—NR₅R₆ or represented by any one selected from among Formulas 4-1 to 4-4, and
R₅ and R₆ are each independently represented by any one selected from among Formulas 4-1 to 4-4: 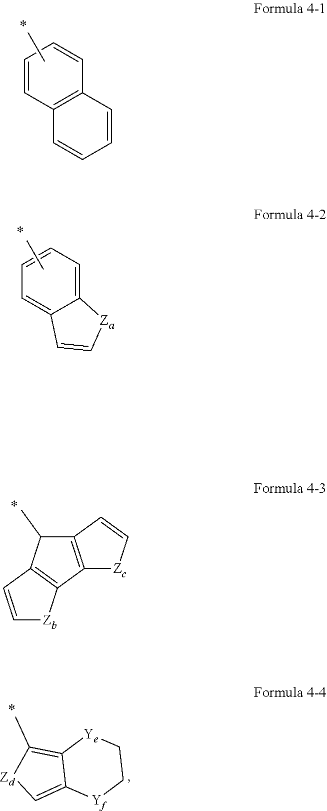
wherein, in Formulas 4-1 to 4-4,
Zₐ to Z_{f} are each independently S or O, and
“ [symbol] ” is a site connected to Formula 3.

15. The light emitting element of claim 12, wherein R₃ and R₄ are each hydrogen.

16. The light emitting element of claim 12, wherein the fused compound comprises at least one selected from among the compounds of Compound Group 1:

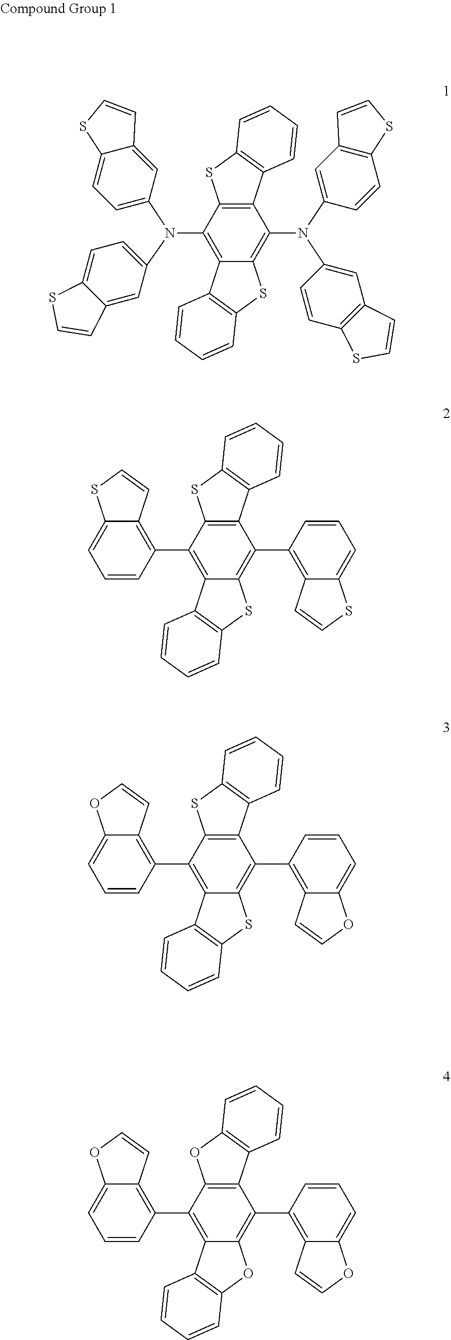 [SMILES: c1ccc2c(c1)sc1c(N(c3ccc4sccc4c3)c3ccc4sccc4c3)c3c(sc4ccccc43)c(N(c3ccc4sccc4c3)c3ccc4sccc4c3)c12 ; c1cc(-c2c3sc4ccccc4c3c(-c3cccc4sccc34)c3sc4ccccc4c23)c2ccsc2c1 ; c1cc(-c2c3sc4ccccc4c3c(-c3cccc4occc34)c3sc4ccccc4c23)c2ccoc2c1 ; c1cc(-c2c3oc4ccccc4c3c(-c3cccc4occc34)c3oc4ccccc4c23)c2ccoc2c1]

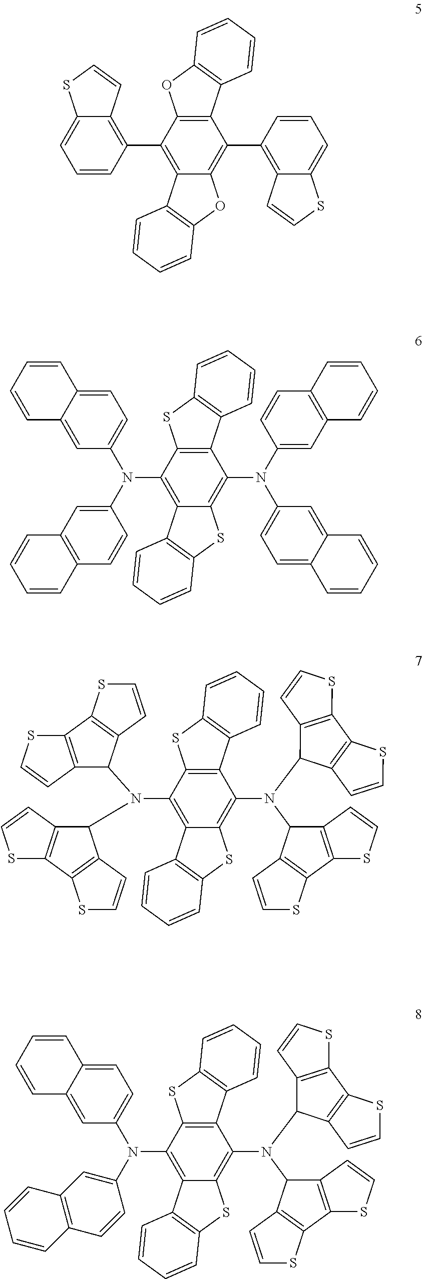 [SMILES: c1ccc2c(c1)oc1c(-c3cccc4sccc34)c3c(oc4ccccc43)c(-c3cccc4sccc34)c12 ; c1ccc2cc(N(c3ccc4ccccc4c3)c3c4sc5ccccc5c4c(N(c4ccc5ccccc5c4)c4ccc5ccccc5c4)c4sc5ccccc5c34)ccc2c1 ; c1ccc2c(c1)sc1c(N(C3c4ccsc4-c4sccc43)C3c4ccsc4-c4sccc43)c3c(sc4ccccc43)c(N(C3c4ccsc4-c4sccc43)C3c4ccsc4-c4sccc43)c12 ; c1ccc2cc(N(c3ccc4ccccc4c3)c3c4sc5ccccc5c4c(N(C4c5ccsc5-c5sccc54)C4c5ccsc5-c5sccc54)c4sc5ccccc5c34)ccc2c1]

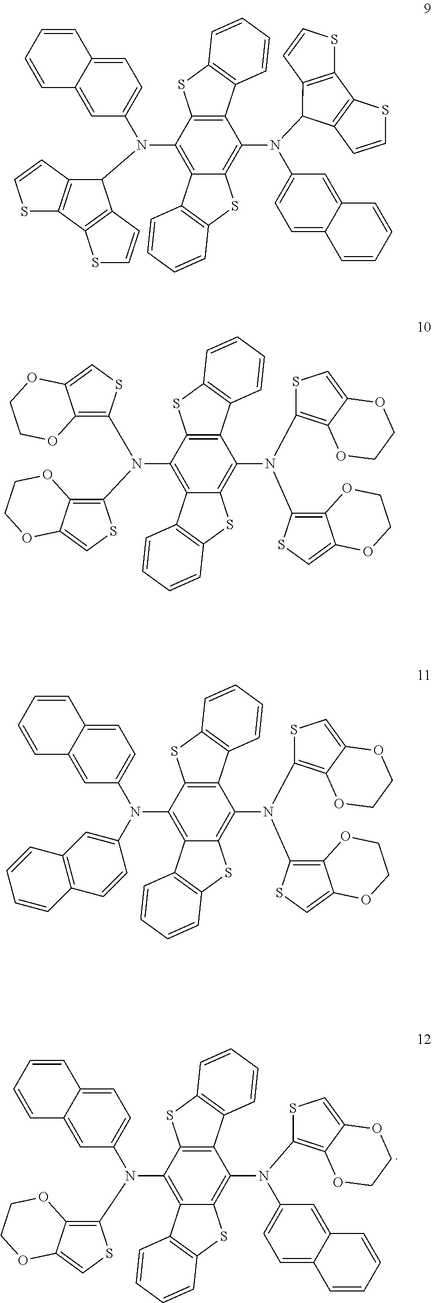 [SMILES: c1ccc2cc(N(c3c4sc5ccccc5c4c(N(c4ccc5ccccc5c4)C4c5ccsc5-c5sccc54)c4sc5ccccc5c34)C3c4ccsc4-c4sccc43)ccc2c1 ; c1ccc2c(c1)sc1c(N(c3scc4c3OCCO4)c3scc4c3OCCO4)c3c(sc4ccccc43)c(N(c3scc4c3OCCO4)c3scc4c3OCCO4)c12 ; c1ccc2cc(N(c3ccc4ccccc4c3)c3c4sc5ccccc5c4c(N(c4scc5c4OCCO5)c4scc5c4OCCO5)c4sc5ccccc5c34)ccc2c1 ; c1ccc2cc(N(c3scc4c3OCCO4)c3c4sc5ccccc5c4c(N(c4ccc5ccccc5c4)c4scc5c4OCCO5)c4sc5ccccc5c34)ccc2c1]

17. The light emitting element of claim 12, wherein the fused compound represented by Formula 3 has a monomolecular refractive index of about 1.7 to about 2.5 with respect to light having a wavelength of about 490 nm to about 570 nm, and
the capping layer has a density of about 1.0 g/cm³ to about 1.3 g/cm³.

18. A light emitting element comprising:
a first electrode;
a second electrode facing the first electrode;
at least one functional layer between the first electrode and the second electrode; and
a capping layer on the second electrode and comprising a fused compound represented by Formula 3,
wherein the at least one functional layer comprises an emission layer, a hole transport region between the first electrode and the emission layer, and an electron transport region between the emission layer and the second electrode,
the emission layer comprising a compound represented by Formula AD: 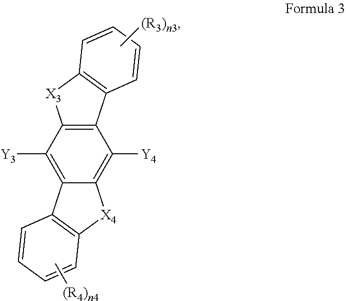
wherein, in Formula 3,
X₃ and X₄ are each independently S or O,
R₃ and R₄ are each independently hydrogen or deuterium,
n3 and n4 are each independently an integer of 0 to 4,
Y₃ and Y₄ are each independently *—NR₅R₆, a substituted or unsubstituted aryl group having 6 to 20 ring-forming carbon atoms, or a substituted or unsubstituted heteroaryl group having 2 to 20 ring-forming carbon atoms, and
R₅ and R₆ are each independently a substituted or unsubstituted aryl group having 6 to 20 ring-forming carbon atoms, or a substituted or unsubstituted heteroaryl group having 2 to 20 ring-forming carbon atoms, 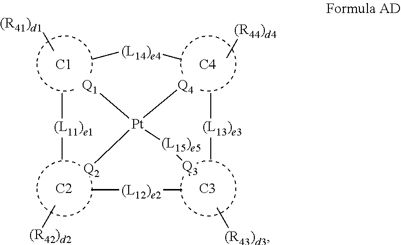
wherein, in Formula AD,
Q₁ to Q₄ are each independently C or N,
C1 to C4 are each independently a substituted or unsubstituted aromatic hydrocarbon ring having 5 to 30 ring-forming carbon atoms, or a substituted or unsubstituted aromatic heterocycle having 2 to 30 ring-forming carbon atoms,
L₁₁ to L₁₄ are each independently a direct linkage, 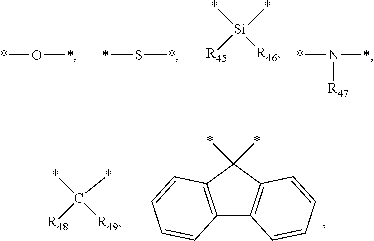
a substituted or unsubstituted alkylene group having 1 to 20 carbon atoms, a substituted or unsubstituted arylene group having 6 to 30 ring-forming carbon atoms, or a substituted or unsubstituted heteroarylene group having 2 to 30 ring-forming carbon atoms, and in L₁₁ to L₁₄, “ [symbol] ” is a site connected to C1 to C4,
L₁₅ is a direct linkage or *—O—*, and in L₁₅, “ [symbol] ” is a site connected to Pt and C3,
e1 to e5 are each independently 0 or 1,
R₄₁ to R₄₉ are each independently hydrogen, deuterium, a halogen, a cyano group, a substituted or unsubstituted silyl group, a substituted or unsubstituted thio group, a substituted or unsubstituted oxy group, a substituted or unsubstituted amine group, a substituted or unsubstituted boron group, a substituted or unsubstituted alkyl group having 1 to 20 carbon atoms, a substituted or unsubstituted aryl group having 6 to 60 ring-forming carbon atoms, or a substituted or unsubstituted heteroaryl group having 2 to 60 ring-forming carbon atoms, and/or bonded to an adjacent group to form a ring, and
d1 to d4 are each independently an integer of 0 to 4.

19. The light emitting element of claim 18, wherein R₃ and R₄ are each hydrogen,
Y₃ and Y₄ are each independently *—NR₅R₆ or represented by any one selected from among Formulas 4-1 to 4-4, and
R₅ and R₆ are each independently represented by any one selected from among Formulas 4-1 to 4-4: 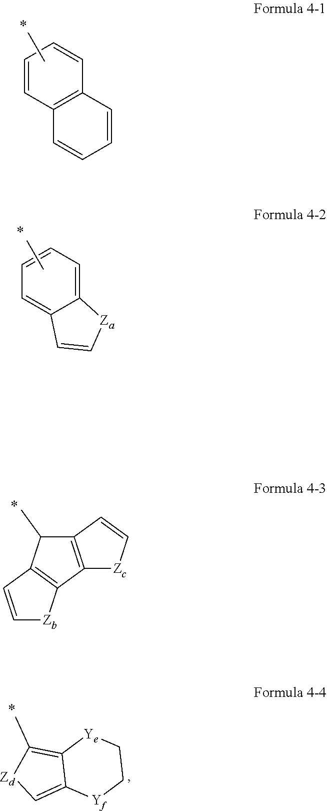
wherein, in Formulas 4-1 to 4-4,
Zₐ to Z_{f} are each independently S or O, and
“ [symbol] ” is a site connected to Formula 3.

20. The light emitting element of claim 18, wherein the fused compound represented by Formula 3 has a monomolecular refractive index of about 1.7 to about 2.5 with respect to light having a wavelength of about 490 nm to about 570 nm, and
the capping layer has a density of about 1.0 g/cm³ to about 1.3 g/cm³.
